(19) United States
(12) Patent Application Publication
(10) Pub. No.: US 2022/0084825 A1
(43) Pub. Date: Mar. 17, 2022

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Tetsuo TAKAHASHI, Tokyo (JP); Hidenori FUJII, Tokyo (JP); Shigeto HONDA, Tokyo (JP)

(73) Assignee: Mitsubishi Electric Corporation, Tokyo (JP)

(21) Appl. No.: 17/373,708

(22) Filed: Jul. 12, 2021

(30) Foreign Application Priority Data
Sep. 14, 2020 (JP) 2020-153851

(51) Int. Cl. H01L 21/22; H01L 27/06; H01L 29/10; H01L 29/32; H01L 29/40; H01L 29/739; H01L 29/861; H01L 21/265; H01L 21/266; H01L 29/66

(52) U.S. Cl. CPC H01L 21/221; H01L 27/0664; H01L 29/1095; H01L 29/32; H01L 29/407; H01L 29/66348; H01L 29/8613; H01L 21/26526; H01L 21/266; H01L 29/66136; H01L 29/7397

(57) ABSTRACT

There is provided a reverse-conducting IGBT having an improved trade-off relationship between recovery losses and a forward voltage drop during diode operation. A first recombination region is provided at least in a region of a sixth semiconductor layer which is at a second main surface side of a seventh semiconductor layer and which overlaps the seventh semiconductor layer as seen in plan view.

### BACKGROUND OF THE INVENTION

### Field of the Invention

The present disclosure relates to a semiconductor device and a method of manufacturing a semiconductor device.

### Description of the Background Art

In general, there have been various needs for power devices, such as the ability to maintain breakdown voltage and the assurance of a safe operating area for prevention of damages to elements during operation. One of the great needs is to achieve low losses. Lowering the losses of power devices has the effects of reducing the size and weight of apparatuses and, in a broad sense, has the effect of leading to consideration for the global environment because of the reduction in energy consumption. Further, there has been another need to achieve these characteristics at the lowest possible costs.

As a means for solving the aforementioned problem, there has been proposed an RC-IGBT (Reverse-Conducting IGBT) in which characteristics of an IGBT (Insulated Gate Bipolar Transistor) and a diode are formed in a single structure.

Such a reverse-conducting IGBT has several technical problems. One of the technical problems is that recovery losses are large during diode operation. Japanese Patent No. 5924420 discloses a configuration in which the area ratio of p⁺ type contact layers in a diode region is reduced for the purpose of improving the recovery losses during the diode operation.

Unfortunately, if the recovery losses during the diode operation are reduced by reducing the area ratio of the p⁺ type contact layers in the diode region, there is a trade-off such that a forward voltage drop is deteriorated instead of the reduction in recovery losses. In improving the performance of the reverse-conducting IGBT, it is important to improve the trade-off relationship between the recovery losses and the forward voltage drop during the diode operation.

### SUMMARY

It is therefore an object of the present disclosure to provide a reverse-conducting IGBT having an improved trade-off relationship between recovery losses and a forward voltage drop during diode operation.

A semiconductor device according to one aspect of the present disclosure is a semiconductor device comprising a transistor and a diode both formed in a common semiconductor base body. The semiconductor base body includes a first main surface and a second main surface as one main surface and the other main surface, respectively, a transistor region in which the transistor is formed, and a diode region in which the diode is formed. The transistor region includes a first semiconductor layer of a first conductivity type formed on the second main surface side of the semiconductor base body, a second semiconductor layer of a second conductivity type provided on the first semiconductor layer, a third semiconductor layer of the first conductivity type provided closer to the first main surface of the semiconductor base body than the second semiconductor layer, a fourth semiconductor layer of the second conductivity type provided on the third semiconductor layer, a second electrode electrically connected to the fourth semiconductor layer, and a first electrode electrically connected to the first semiconductor layer. The diode region includes a fifth semiconductor layer of the second conductivity type provided on the second main surface side of the semiconductor base body, the second semiconductor layer provided on the fifth semiconductor layer, a sixth semiconductor layer of the first conductivity type provided closer to the first main surface of the semiconductor base body than the second semiconductor layer, a seventh semiconductor layer of the first conductivity type provided on the sixth semiconductor layer and having a first conductivity type impurity concentration higher than that of the sixth semiconductor layer, the second electrode electrically connected to the seventh semiconductor layer, and the first electrode electrically connected to the fifth semiconductor layer. A first recombination region is provided at least in a region of the sixth semiconductor layer which is at the second main surface side of the seventh semiconductor layer and which overlaps the seventh semiconductor layer as seen in plan view.

The provision of the first recombination region at least in the region of the sixth semiconductor layer which is at the second main surface side of the seventh semiconductor layer and which overlaps the seventh semiconductor layer as seen in plan view improves the trade-off relationship between the recovery losses and the forward voltage drop during the diode operation.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is an overall plan view of a stripe type semiconductor device according to a first preferred embodiment;

FIG. 2 is an overall plan view of an island type semiconductor device according to the first preferred embodiment;

FIG. 3 is a plan view of a boundary portion between an IGBT region and a diode region of the semiconductor device according to the first preferred embodiment;

FIGS. 4 and 5 are sectional views of the boundary portion between the IGBT region and the diode region of the semiconductor device according to the first preferred embodiment;

FIG. 6 is a sectional view of a boundary portion between the IGBT region and an outer periphery region of the semiconductor device according to the first preferred embodiment;

FIG. 7 is a sectional view of a boundary portion between the diode region and the outer periphery region of the semiconductor device according to the first preferred embodiment;

FIGS. 8 to 22 are sectional views illustrating a method of manufacturing the semiconductor device according to the first preferred embodiment;

FIG. 23 is a graph illustrating a relationship between the area ratio of a defect region and the peak value of a recovery current of the semiconductor device according to the first preferred embodiment;

FIGS. 24 and 25 are sectional views of a boundary portion between an IGBT region and a diode region of a semiconductor device according to a second preferred embodiment;

FIGS. 26 to 29 are sectional views illustrating a method of manufacturing the semiconductor device according to the second preferred embodiment;

FIGS. 30 and 31 are sectional views of a boundary portion between an IGBT region and a diode region of a semiconductor device according to a third preferred embodiment;

FIGS. 32 to 37 are sectional views illustrating a method of manufacturing the semiconductor device according to the third preferred embodiment;

FIGS. 38 and 39 are sectional views of a boundary portion between an IGBT region and a diode region of a semiconductor device according to a fourth preferred embodiment;

FIGS. 40 to 43 are sectional views illustrating a method of manufacturing the semiconductor device according to the fourth preferred embodiment;

FIGS. 44 and 45 are sectional views of a boundary portion between an IGBT region and a diode region of a semiconductor device according to a fifth preferred embodiment;

FIGS. 46 to 49 are sectional views illustrating a method of manufacturing the semiconductor device according to the fifth preferred embodiment;

FIG. 50 is a plan view of a boundary portion between an IGBT region and a diode region of a semiconductor device according to a sixth preferred embodiment;

FIGS. 51 and 52 are sectional views of the boundary portion between the IGBT region and the diode region of the semiconductor device according to the sixth preferred embodiment;

FIG. 53 is a plan view of a boundary portion between an IGBT region and a diode region of a semiconductor device according to a seventh preferred embodiment;

FIGS. 54 and 55 are sectional views of the boundary portion between the IGBT region and the diode region of the semiconductor device according to the seventh preferred embodiment;

FIG. 56 is a plan view of a boundary portion between an IGBT region and a diode region of a semiconductor device according to an eighth preferred embodiment;

FIGS. 57 and 58 are sectional views of the boundary portion between the IGBT region and the diode region of the semiconductor device according to the eighth preferred embodiment;

FIGS. 59 and 60 are sectional views of a boundary portion between an IGBT region and a diode region of a semiconductor device according to a ninth preferred embodiment;

FIGS. 61 and 62 are sectional views of a boundary portion between an IGBT region and a diode region of a semiconductor device according to a tenth preferred embodiment;

FIGS. 63 and 64 are sectional views of a boundary portion between an IGBT region and a diode region of a semiconductor device according to an eleventh preferred embodiment;

FIG. 65 is a plan view of a boundary portion between an IGBT region and a diode region of a semiconductor device according to a twelfth preferred embodiment;

FIGS. 66 and 67 are sectional views of the boundary portion between the IGBT region and the diode region of the semiconductor device according to the twelfth preferred embodiment;

FIG. 68 is a sectional view of a boundary portion between an IGBT region and a diode region of a semiconductor device according to a thirteenth preferred embodiment; and

FIG. 69 is a sectional view of a boundary portion between an IGBT region and a diode region of a semiconductor device according to a comparative example.

### DESCRIPTION OF THE PREFERRED EMBODIMENTS

### Introduction

In the following description, n and p types denote conductivity types of semiconductors. A first conductivity type and a second conductivity type will be taken as the p type and the n type, respectively, in the present disclosure, but may be taken as the n type and the p type, respectively. Also, an n⁻ type indicates that the impurity concentration thereof is lower than that of the n type, and an n⁺ type indicates that the impurity concentration thereof is higher than that of the n type. Similarly, a p⁻ type indicates that the impurity concentration thereof is lower than that of the p type, and a p⁺ type indicates that the impurity concentration thereof is higher than that of the p type.

In the drawings, figures show schematic representations, and the sizes and positions of images shown in different figures are not necessarily in a correct correlation, but may be changed, as appropriate. In the following description, similar components are designated by and shown using the same reference numerals and characters, and shall have similar designations and functions. Thus, these components will not be detailed in some cases.

Also, terms referring to specific positions and directions such as “upper”, “lower”, “side”, “front”, and “back” are used in some cases in the following description. These terms, however, shall be used for the sake of convenience and for the purpose of facilitating the understanding of the details of preferred embodiments, and shall not be related to directions used when the preferred embodiments are actually practiced.

### Comparative Example

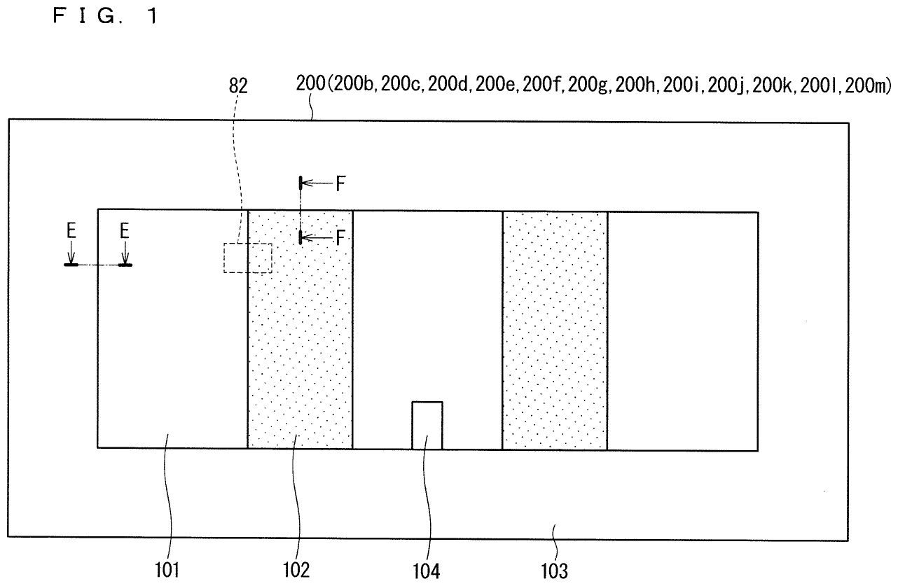

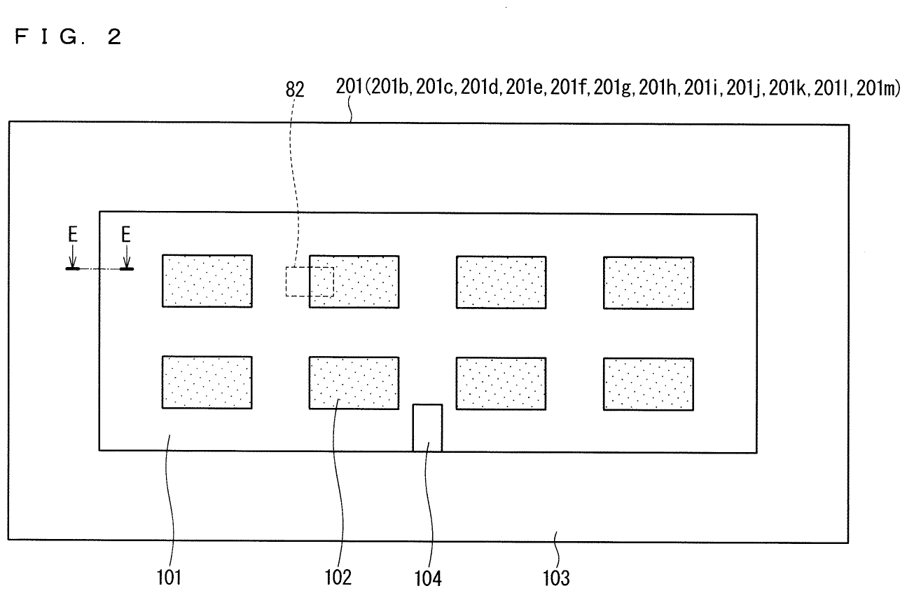

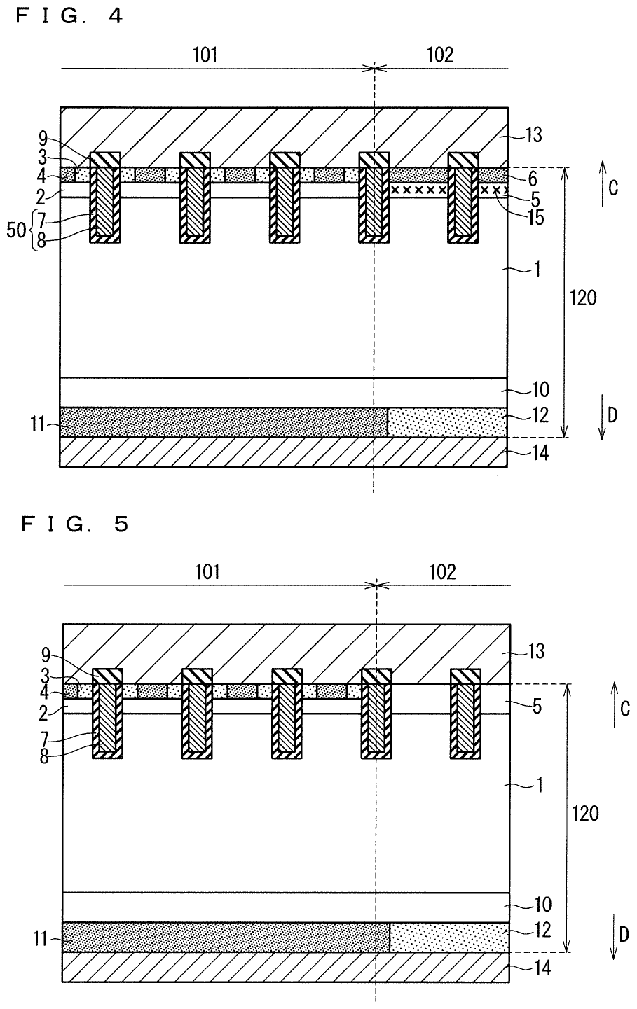

Prior to the description of preferred embodiments, a comparative example is shown in FIG. 69. A semiconductor device 1000 according to the comparative example differs in arrangement of p⁺ type contact layers 6 shown in FIG. 4 from a semiconductor device 200 shown in FIG. 1 or a semiconductor device 201 shown in FIG. 2 which will be described in a first preferred embodiment. The semiconductor device 1000 also differs from the semiconductor device 200 or the semiconductor device 201 in that no defect region 15 is provided. Other parts of the semiconductor device 1000 are similar to those of the semiconductor device 200 or the semiconductor device 201, and will not be described herein.

The configuration of the semiconductor device 1000 is intended to reduce the area ratio of the p⁺ type contact layers 6 to reduce the effective concentration of p type impurities in an anode region formed by p type anode layers 5 and the p⁺ type contact layers 6 in a diode region 102, thereby suppressing diode recovery losses, while suppressing the deterioration of a forward voltage drop by providing the p⁺ type contact layers 6 in the diode region 102.

However, if the area ratio of the p⁺ type contact layers 6 is too high, the diode recovery losses cannot be reduced sufficiently. When the area ratio of the p⁺ type contact layers 6 is lowered, a forward voltage drop (VI) becomes greater because the ohmic resistance with an emitter electrode 13 increases as the area ratio decreases. In this manner, there is a trade-off between the forward voltage drop (VI) and the recovery losses.

Even when the area ratio of the p⁺ type contact layers 6 is lowered, the recovery losses cannot be reduced below those obtained in a state in which the area ratio is zero. Thus, there is a limit to the reduction in recovery losses, and the use of another technique is required for further improvements in recovery losses.

### A. First Preferred Embodiment

<A-1. Configuration>

FIG. 1 is a plan view showing the semiconductor device 200 that is an RC-IGBT according to the first preferred embodiment. FIG. 2 is a plan view showing the semiconductor device 201 that is an RC-IGBT of another configuration according to the first preferred embodiment. The semiconductor device 200 shown in FIG. 1 includes IGBT regions 101 and diode regions 102 which are arranged in a striped pattern, and may be referred to simply as a “stripe type”. The semiconductor device 201 shown in FIG. 2 includes a plurality of diode regions 102 arranged in vertical and horizontal directions and an IGBT region 101 provided around the diode regions 102, and may be referred to simply as an “island type”. The detailed planar structures of the stripe type and the island type will be described later.

As shown in FIG. 1, the stripe type semiconductor device 200 includes the IGBT regions 101 and the diode regions 102 in the single semiconductor device. The IGBT regions 101 and the diode regions 102 extend from a first end side to a second end side of the semiconductor device 200, and are disposed alternately in a striped pattern in a direction orthogonal to the direction of extension of the IGBT regions 101 and the diode regions 102. Three IGBT regions 101 and two diode regions 102 are shown in FIG. 1 in such a configuration that all of the diode regions 102 are sandwiched between the IGBT regions 101. However, the number of IGBT regions 101 and the number of diode regions 102 are not limited to these. The number of IGBT regions 101 may be either not less than three or not greater than three. The number of diode regions 102 may be either not less than two or not greater than two. Also, the locations of the IGBT regions 101 and the diode regions 102 of FIG. 1 may be exchanged, so that all of the IGBT regions 101 are sandwiched between the diode regions 102. Alternatively, one IGBT region 101 and one diode region 102 may be disposed adjacent to each other.

As shown in FIG. 2, the island type semiconductor device 201 includes the IGBT region 101 and the diode regions 102 in the single semiconductor device. The plurality of diode regions 102 are arranged in a vertical direction and in a horizontal direction as seen in plan view in the semiconductor device 201. The diode regions 102 are surrounded by the IGBT region 101. In other words, the plurality of diode regions 102 are provided in the form of islands within the IGBT region 101. The diode regions 102 are shown in FIG. 2 as disposed in a matrix with four columns arranged in a horizontal direction as seen in the figure and two rows arranged in a vertical direction as seen in the figure. However, the number and arrangement of the diode regions 102 are not limited to these. It is only necessary that one or more diode regions 102 are scattered within the IGBT region 101 and are each surrounded by the IGBT region 101.

As shown in FIG. 1 or 2, a gate pad region 104 is disposed adjacent to one of the IGBT regions 101 in the semiconductor device 200 or adjacent to the IGBT region 101 in the semiconductor device 201. The gate pad region 104 is a region in which a gate pad (referred to hereinafter as a gate pad 104a) is provided. The gate pad 104a is a control pad to which a gate drive voltage for effecting the on/off control of the semiconductor device 200 or the semiconductor device 201 is applied. The gate pad 104a is electrically connected to buried gate electrodes 8 of the IGBT regions 101 to be described later. Also, the semiconductor device 200 or the semiconductor device 201 may further include a current sense pad that is a control pad for sensing a current flowing through a cell region of the semiconductor device 200 or the semiconductor device 201, a Kelvin emitter pad which is electrically connected to p type channel dope layers 2 of the IGBT regions 101 to be described later and to which a gate drive voltage for effecting the on/off control of the semiconductor device 200 or the semiconductor device 201 is applied, a temperature sense diode pad for measuring the temperature of the semiconductor device 200 or the semiconductor device 201, and the like, in addition to the gate pad 104a.

In the semiconductor device 200 or the semiconductor device 201, the IGBT regions 101 and the diode regions 102 are collectively referred to as a cell region. An outer periphery region 103 is provided around a combination of the cell region and the gate pad region 104 to maintain the breakdown voltage of the semiconductor device 200 or the semiconductor device 201. A known breakdown voltage maintaining structure may be selectively provided, as appropriate, for the outer periphery region 103. The breakdown voltage maintaining structure may be formed, for example, by providing an FLR (Field Limiting Ring) including p type termination well layers made of a p type semiconductor and surrounding the cell region and a VLD (Variation of Lateral Doping) including a p type well layer having a concentration gradient and surrounding the cell region on a first main surface side that is a front surface side of the semiconductor device 200 or the semiconductor device 201. The number of p type termination well layers having a ring-shaped configuration used for the FLR and the concentration gradient used for the VLD may be selected, as appropriate, depending on the design of the breakdown voltage of the semiconductor device 200 or the semiconductor device 201. The first main surface side of the semiconductor device 200 or the semiconductor device 201 corresponds to the direction indicated by an arrow C in FIGS. 4 and 5, and a second main surface side thereof corresponds to the direction indicated by an arrow D in FIGS. 4 and 5.

<A-1-1. Partial Planar Configuration>

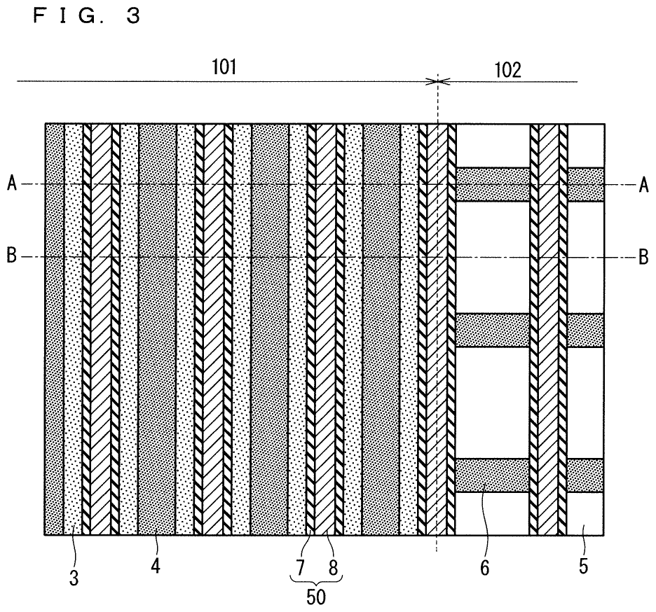

FIG. 3 is an enlarged plan view showing the configuration of an IGBT region 101 and a diode region 102 of the semiconductor device of the present preferred embodiment, which is an RC-IGBT, and is an enlarged view of a region enclosed by broken lines 82 in the semiconductor device 200 shown in FIG. 1 or the semiconductor device 201 shown in FIG. 2. FIG. 3 also shows a configuration on the first main surface of a semiconductor base body 120.

As shown in FIG. 3, trench gates 50 are disposed in a striped pattern in the IGBT region 101 and the diode region 102. In the semiconductor device 200, the trench gates 50 extend in the longitudinal directions of the IGBT region 101 and the diode region 102, and the longitudinal directions of the IGBT region 101 and the diode region 102 are the longitudinal direction of the trench gates 50. In the semiconductor device 201, on the other hand, no particular distinction is made between the longitudinal direction and the transverse direction in the IGBT region 101 and the diode region 102. In FIG. 2, the horizontal direction as seen in the figure may be taken as the longitudinal direction of the trench gates 50 or the vertical direction as seen in the figure may be taken as the longitudinal direction of the trench gates 50. In the following, the trench gates 50 shall extend in a direction perpendicular to a line E-E hereinafter.

Each of the trench gates 50 is configured such that a buried gate electrode 8 is provided in a trench formed in a semiconductor substrate, with a gate insulation film 7 therebetween. The buried gate electrode 8 in each of the trench gates 50 is electrically connected to the gate pad 104a.

N⁺ type emitter layers 3 and a p⁺ type contact layer 4 are provided in each region lying between adjacent two of the trench gates 50 in the IGBT region 101. The n⁺ type emitter layers 3 and the p⁺ type contact layers 4 extend in the same direction as the direction of extension of the trench gates 50. The n⁺ type emitter layers 3 are provided in contact with the gate insulation films 7 of the trench gates 50, and the p⁺ type contact layers 4 are provided in spaced apart relation to the gate insulation films 7 of the trench gates 50. The n⁺ type emitter layers 3 are semiconductor layers having, for example, As (arsenic) or P (phosphorus) as n type impurities, and have an n type impurity concentration of 1.0E+17/cm³ to 1.0E+20/cm³. The p⁺ type contact layers 4 are semiconductor layers having, for example, B (boron) or Al (aluminum) as p type impurities, and have a p type impurity concentration of 5.0E+18/cm³ to 1.0E+20/cm³.

The p type anode layers 5 and the p⁺ type contact layers 6 are provided in each region lying between adjacent two of the trench gates 50 in the diode region 102. The p type anode layers 5 and the p⁺ type contact layers 6 are disposed alternately in the longitudinal direction of the trench gates 50. The p type anode layers 5 are semiconductor layers having, for example, boron or aluminum as p type impurities, and have a p type impurity concentration of 1.0E+12/cm³ to 5.0E+18/cm³. The p⁺ type contact layers 6 are semiconductor layers having, for example, boron or aluminum as p type impurities, and have a p type impurity concentration of 5.0E+18/cm³ to 1.0E+20/cm³.

<A-1-2. Cross-Sectional Configuration>

FIG. 4 is a sectional view of the semiconductor device 200 or the semiconductor device 201 taken along a line A-A shown in FIG. 3. FIG. 5 is a sectional view of the semiconductor device 200 or the semiconductor device 201 taken along a line B-B shown in FIG. 3.

The semiconductor device 200 or the semiconductor device 201 includes an n⁻ type drift layer 1 (a second semiconductor layer). The n⁻ type drift layer 1 is a semiconductor layer having, for example, arsenic or phosphorus as n type impurities, and has an n type impurity concentration of 1.0E+12/cm³ to 1.0E+15/cm³. The n⁻ type drift layer 1 in the diode region 102 and the n⁻ type drift layer 1 in the IGBT region 101 are formed integrally in continuous fashion, and are formed from the same semiconductor substrate.

P type or n type semiconductor layers in the semiconductor base body 120, which ranges from the type emitter layers 3 (a fourth semiconductor layer) and the p⁺ type contact layers 4 (a ninth semiconductor layer) to a p type collector layer 11 (a first semiconductor layer) in the IGBT region 101 of FIGS. 4 and 5, which ranges from the p⁴ type contact layers 6 (a seventh semiconductor layer) to an n⁺ type cathode layer 12 (a fifth semiconductor layer) in the diode region 102 of FIG. 4, and which ranges from the p type anode layers 5 (a sixth semiconductor layer) to the n⁺ type cathode layer 12 in the diode region 102 of FIG. 5, are formed by introducing impurity ions into the semiconductor substrate and then performing heat treatment and the like to diffuse the impurity ions in the semiconductor substrate.

With reference to FIG. 4, the ends of the n⁺ type emitter layers 3, the p⁺ type contact layers 4, and the p⁺ type contact layers 6 on the emitter electrode 13 side are referred to as a first main surface of the semiconductor base body 120, and the ends of the p type collector layer 11 and the n⁺ type cathode layer 12 on a collector electrode 14 side are referred to as a second main surface of the semiconductor base body 120. With reference to FIG. 5, the ends of the n⁺ type emitter layers 3, the p⁺ type contact layers 4, and the p type anode layers 5 on the emitter electrode 13 side are referred to as the first main surface of the semiconductor base body 120, and the ends of the p type collector layer 11 and the n⁺ type cathode layer 12 on the collector electrode 14 side are referred to as the second main surface of the semiconductor base body 120. The first main surface of the semiconductor base body 120 is a main surface at the front surface side of the semiconductor device 200 or the semiconductor device 201, and the second main surface of the semiconductor base body 120 is a main surface at the back surface side of the semiconductor device 200 or the semiconductor device 201. In the description of a manufacturing method or the description from a manufacturing method viewpoint, a main surface of a semiconductor substrate for use in the formation of the semiconductor base body 120 which corresponds to the first main surface side of the semiconductor base body 120 is referred to a first main surface of the semiconductor substrate, and a main surface thereof which corresponds to the second main surface side of the semiconductor base body 120 is referred to a second main surface of the semiconductor substrate. The semiconductor device 200 or the semiconductor device 201 includes the n⁻ type drift layer 1 between the first main surface and the second main surface opposed to the first main surface in the IGBT region 101 and the diode region 102.

<A-1-2-1. Cross-Sectional Configuration of IGBT Region>

As shown in FIGS. 4 and 5, the p type channel dope layers 2 (a third semiconductor layer) are provided on the first main surface side of the n⁻ type drift layer 1 in the IGBT region 101. The p type channel dope layers 2 are semiconductor layers having, for example, boron or aluminum as p type impurities, and have a p type impurity concentration of 1.0E+12/cm³ to 5.0E+18/cm³. The p type channel dope layers 2 are in contact with the gate insulation films 7 of the trench gates 50. The n⁺ type emitter layers 3 in contact with the gate insulation films 7 of the trench gates 50 are provided on the first main surface side of the p type channel dope layers 2, and the p⁺ type contact layers 4 are provided in the remaining regions on the first main surface side of the p type channel dope layers 2. The n⁺ type emitter layers 3 and the p⁺ type contact layers 4 constitute part of the first main surface of the semiconductor base body 120.

As shown in FIGS. 4 and 5, an n type buffer layer 10 having an n type impurity concentration higher than that of the n⁻ type drift layer 1 is provided on the second main surface side of the n⁻ type drift layer 1 in the IGBT region 101 of the semiconductor device 200 or the semiconductor device 201. The n type buffer layer 10 is provided to suppress the punch through of a depletion layer extending from the p type channel dope layers 2 toward the second main surface side when the semiconductor device 200 or the semiconductor device 201 is in an off state. The n type buffer layer 10 may be formed, for example, by implanting phosphorus or protons or by implanting both phosphorus and protons. The n type buffer layer 10 has an n type impurity concentration of 1.0E+12/cm³ to 1.0E+18/cm³.

The semiconductor device 200 or the semiconductor device 201 may be configured not to include the n type buffer layer 10 but to include the n⁻ type drift layer 1 provided also in the region of the n type buffer layer 10 shown in FIGS. 4 and 5. The n type buffer layer 10 and the n⁻ type drift layer 1 together may be referred to as a drift layer (the second semiconductor layer).

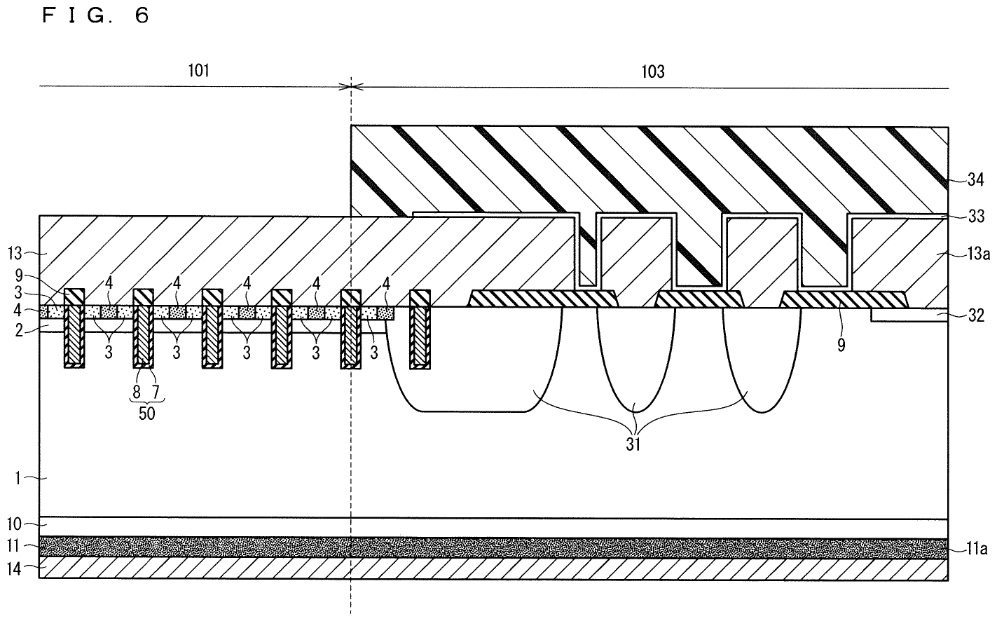

The semiconductor device 200 or the semiconductor device 201 includes the p type collector layer 11 provided on the second main surface side of the n type buffer layer 10 in the IGBT region 101. That is, the p type collector layer 11 is provided between the n⁻ type drift layer 1 and the second main surface. The p type collector layer 11 is a semiconductor layer having, for example, boron or aluminum as p type impurities, and has a p type impurity concentration of 1.0E+16/cm³ to 1.0E+20/cm³. The p type collector layer 11 constitutes part of the second main surface of the semiconductor base body 120. The p type collector layer 11 is provided not only in the IGBT region 101 but also in the outer periphery region 103. Part of the p type collector layer 11 provided in the outer periphery region 103 constitutes a p type termination collector layer 11a (with reference to FIGS. 6 and 7). The p type collector layer 11 may be provided with a portion protruding from the IGBT region 101 to the diode region 102.

As shown in FIGS. 4 and 5, the semiconductor device 200 or the semiconductor device 201 includes trenches extending from the first main surface of the semiconductor base body 120 through the p type channel dope layers 2 to the n⁻ type drift layer 1 in the IGBT region 101. The trench gates 50 are formed by providing the buried gate electrodes 8 in the respective trenches, with the gate insulation films 7 therebetween. The buried gate electrodes 8 are opposed to the n⁻ type drift layer 1, with the gate insulation films 7 therebetween. The gate insulation films 7 of the trench gates 50 in the IGBT region 101 are in contact with the p type channel dope layers 2 and the n⁺ type emitter layers 3. When a gate drive voltage is applied to the buried gate electrodes 8, a channel is formed in the p type channel dope layers 2 in contact with the gate insulation films 7 of the trench gates 50.

As shown in FIGS. 4 and 5, interlayer insulation films 9 are provided on the buried gate electrodes 8 of the trench gates 50 in the IGBT region 101. The emitter electrode 13 is formed on regions of the first main surface of the semiconductor base body 120 where the interlayer insulation films 9 are not formed and on the interlayer insulation films 9. The emitter electrode 13 in the IGBT region 101 is in ohmic contact with the n⁺ type emitter layers 3 and the p⁺ type contact layers 4, and is electrically connected to the n⁺ type emitter layers 3 and the p⁺ type contact layers 4. The emitter electrode 13 may be made of an aluminum alloy such as an aluminum-silicon alloy (Al—Si alloy), for example. The emitter electrode 13 may be an electrode comprised of a plurality of metal films obtained by forming plating films by electroless plating or electroplating on an electrode made of an aluminum alloy. The plating films formed by electroless plating or electroplating may be nickel (Ni) plating films, for example. If there are small regions, such as regions between adjacent ones of the interlayer insulation films 9, where the emitter electrode 13 cannot be embedded therein well, tungsten having better embeddability than the emitter electrode 13 may be placed in the small regions and the emitter electrode 13 may be provided on the tungsten.

A barrier metal may be formed on the regions of the first main surface of the semiconductor base body 120 where the interlayer insulation films 9 are not formed and on the interlayer insulation films 9, and the emitter electrode 13 may be formed on the barrier metal (referred to as a barrier metal 27). The barrier metal 27 may be an electric conductor containing titanium (Ti), for example. Examples of the electric conductor may include titanium nitride and TiSi obtained by alloying titanium and silicon (Si). When the barrier metal 27 is formed, the barrier metal 27 is in ohmic contact with the n⁺ type emitter layers 3 and the p⁺ type contact layers 4, and is electrically connected to the n⁺ type emitter layers 3 and the p⁺ type contact layers 4. The barrier metal 27 and the emitter electrode 13 together may be referred to as an emitter electrode. Also, the barrier metal 27 may be provided only on n type semiconductor layers such as the n⁺ type emitter layers 3.

The collector electrode 14 is provided on the second main surface side of the p type collector layer 11. Like the emitter electrode 13, the collector electrode 14 may be made of an aluminum alloy or formed by an aluminum alloy and a plating film. The collector electrode 14 may be different in configuration from the emitter electrode 13. The collector electrode 14 is in ohmic contact with the p type collector layer 11 and is electrically connected to the p type collector layer 11.

<A-1-2-2. Cross-Sectional Configuration of Diode Region>

In the diode region 102, the n type buffer layer 10 is also provided on the second main surface side of the n⁻ type drift layer 1 in the same manner as in the IGBT region 101, as shown in FIGS. 4 and 5. The n type buffer layer 10 provided in the diode region 102 is identical in configuration with the n type buffer layer 10 provided in the IGBT region 101. The n⁻ type drift layer 1 and the n type buffer layer 10 together may be referred to as a drift layer, as in the IGBT region 101.

In the diode region 102, the p type anode layers 5 are provided on the first main surface side of the n⁻ type drift layer 1. The p type anode layers 5 are provided between the n⁻ type drift layer 1 and the first main surface. The p type anode layers 5 may have the same p type impurity concentration as the p type channel dope layers 2 in the IGBT region 101, and the p type anode layers 5 and the p type channel dope layers 2 may be formed at the same time. Alternatively, the p type anode layers 5 may have a p type impurity concentration lower than that of the p type channel dope layers 2 in the IGBT region 101, so that the amounts of holes flowing into the n⁻ type drift layer 1 are reduced during the diode operation. The reduction in the amounts of holes flowing into the n⁻ type drift layer 1 during the diode operation reduces recovery losses during the diode operation.

In the diode region 102 having a cross-section shown in FIG. 4, the p⁺ type contact layers 6 are provided at the first main surface side of the p type anode layers 5. The p⁺ type contact layers 6 may have the same p type impurity concentration as the p⁺ type contact layers 4 in the IGBT region 101 or a p type impurity concentration different from that of the p⁺ type contact layers 4. The p⁺ type contact layers 6 constitute part of the first main surface of the semiconductor base body 120. The p⁺ type contact layers 6 are regions having a p type impurity concentration higher than that of the p type anode layers 5, and are regions having a p type impurity concentration of not less than 5.0E+18/cm³ in the anode region. The p type anode Layers 5 are regions having a p type impurity concentration of less than 5.0E+18/cm³.

As shown in FIG. 4, defect regions 15 (a first crystal defect region) are formed in the p type anode layers 5. The defect regions 15 are provided at least in regions of the p type anode layers 5 which are at the second main surface side of the p⁺ type contact layers 6 and which overlap the p⁺ type contact layers 6 as seen in plan view. The defect regions 15 may be provided in regions of the p type anode layers 5 which are in contact with the surface of the p⁺ type contact layers 6 on the second main surface side or provided so as to extend from the p type anode layers 5 to the p⁺ type contact layers 6, including the surface of the p⁺ type contact layers 6 on the second main surface side which is in contact with the p type anode layers 5. The defect regions 15 may be provided in spaced apart relation to the p⁺ type contact layers 6. However, the defect regions 15 provided in the regions in contact with the surface of the p⁺ type contact layers 6 on the second main surface side or provided so as to extend to the p⁺ type contact layers 6 effectively suppress the amounts of holes flowing into the n⁻ type drift layer 1. In particular, an instance in which the defect regions 15 and the p⁺ type contact layers 6 are formed by ion implantation using the same mask and formed in the same regions as seen in plan view will be described in the present preferred embodiment. The fact that the defect regions 15 and the p⁺ type contact layers 6 are formed in the same regions as seen in plan view means that the defect regions 15 and the p⁺ type contact layers 6 are in the same regions to a degree achievable by ion implantation using the same mask and subsequent heat treatment which will be described later in <A-2. Manufacturing Method>. If there is a misalignment normally assumable by these processes, the defect regions 15 and the p⁺ type contact layers 6 shall be treated as being in the same regions as seen in plan view.

The n⁺ type cathode layer 12 is provided on the second main surface side of the n type buffer layer 10 in the diode region 102. The n⁺ type cathode layer 12 is provided between the n⁻ type drift layer 1 and the second main surface. The n⁺ type cathode layer 12 is a semiconductor layer having, for example, arsenic or phosphorus as n type impurities, and has an n type impurity concentration of 1.0E+16/cm³ to 1.0E+21/cm³. As shown in FIGS. 4 and 5, the n⁺ type cathode layer 12 is provided partially or wholly in the diode region 102. The n⁺ type cathode layer 12 constitutes part of the second main surface of the semiconductor base body 120. Although not shown, p type impurities may be further selectively implanted in the region where the n⁺ type cathode layer 12 is formed as mentioned above to provide a p type cathode layer so that part of the region where the n⁺ type cathode layer 12 becomes a p type semiconductor.

With reference to FIGS. 4 and 5, the diode region 102 of the semiconductor device 200 or the semiconductor device 201 includes trenches extending from the first main surface of the semiconductor base body 120 through the p type anode layers 5 to the n⁻ type drift layer 1. In the diode region 102, the trench gates 50 are also formed by providing the buried gate electrodes 8 in the respective trenches, with the gate insulation films 7 therebetween, in the same manner as in the IGBT region 101. The buried gate electrodes 8 in the diode region 102 are opposed to the n⁻ type drift layer 1, with the gate insulation films 7 therebetween.

As shown in FIG. 4, the interlayer insulation films 9 are provided on the buried gate electrodes 8 of the trench gates 50 in the diode region 102. The emitter electrode 13 is formed on regions of the first main surface of the semiconductor base body 120 where the interlayer insulation films 9 are not formed and on the interlayer insulation films 9. The emitter electrode 13 is in ohmic contact with the p⁺ type contact layers 6, and is electrically connected to the p⁺ type contact layers 6. The buried gate electrodes 8 of the trench gates 50 in the diode region 102 and the emitter electrode 13 are electrically connected in a cross-section different from that shown in FIG. 4. The emitter electrode 13 provided in the diode region 102 is formed continuously with the emitter electrode 13 provided in the IGBT region 101. Although the interlayer insulation films 9 are shown as provided on the buried gate electrodes 8 of the trench gates 50 in the diode region 102 in FIG. 4, the interlayer insulation films 9 need not be provided on the buried gate electrodes 8 of the trench gates 50 in the diode region 102.

In the diode region 102, the barrier metal 27 may be also formed on the regions of the first main surface of the semiconductor base body 120 where the interlayer insulation films 9 are not formed and on the interlayer insulation films 9, and the emitter electrode 13 may be formed on the barrier metal 27 in the same manner as in the IGBT region 101. When the barrier metal 27 is provided in the diode region 102, this barrier metal 27 may be identical in configuration with the barrier metal 27 that may be provided in the IGBT region 101. When the barrier metal 27 is provided in the diode region 102, the barrier metal 27 is in ohmic contact with the p⁺ type contact layers 6, and is electrically connected to the p⁺ type contact layers 6. The barrier metal 27 and the emitter electrode 13 together may be referred to as an emitter electrode.

The collector electrode 14 is provided on the second main surface side of the n⁺ type cathode layer 12. Like the emitter electrode 13, the collector electrode 14 provided in the diode region 102 is formed continuously with the collector electrode 14 provided in the IGBT region 101. The collector electrode 14 is in ohmic contact with the n⁺ type cathode layer 12 and is electrically connected to the n⁺ type cathode layer 12.

The diode region 102 of FIG. 5 differs from the diode region 102 of FIG. 4 in that the p⁺ type contact layers 6 are not provided, so that the p type anode layers 5 constitute part of the first main surface of the semiconductor base body 120. In other words, the p⁺ type contact layers 6 shown in FIG. 4 are selectively provided on the first main surface side of the p type anode layers 5. The cross-section of FIG. 5 is similar in other respects to the cross-section of FIG. 4.

<A-1-3. Structure of Outer Periphery Region>

FIGS. 6 and 7 are sectional views showing configurations of the outer periphery region of the semiconductor device of the present preferred embodiment, which is an RC-IGBT. FIG. 6 is a sectional view taken along the dash-dot line E-E in FIG. 1 or 2, and is a sectional view from the IGBT region 101 to the outer periphery region 103. FIG. 7 is a sectional view taken along a dash-dot line F-F in FIG. 1, and is a sectional view from the diode region 102 to the outer periphery region 103.

As shown in FIGS. 6 and 7, the outer periphery region 103 of the semiconductor device 200 or the semiconductor device 201 includes the n⁻ type drift layer 1 between the first main surface of the semiconductor base body 120 and the second main surface thereof. The first and second main surfaces in the outer periphery region 103 are the same as those in the IGBT region 101 and the diode region 102. The n⁻ type drift layer 1 in the outer periphery region 103 is identical in configuration with that in the IGBT region 101 and the diode region 102, and is formed integrally with that in the IGBT region 101 and the diode region 102 in continuous fashion.

P type termination well layers 31 are provided on the first main surface side of the n⁻ type drift layer 1, that is, between the first main surface of the semiconductor base body 120 and the n⁻ type drift layer 1. The p type termination well layers 31 are semiconductor layers having, for example, boron or aluminum as p type impurities, and have a p type impurity concentration of 1.0E+14/cm³ to 1.0E+19/cm³. The p type termination well layers 31 are provided so as to surround the cell region including the IGBT regions 101 and the diode regions 102. The p type termination well layers 31 are in the form of a plurality of rings. The number of p type termination well layers 31 is selected, as appropriate, depending on the design of the breakdown voltage of the semiconductor device 200 or the semiconductor device 201. An n⁺ type channel stopper layer 32 is provided on the outside of the p type termination well layers 31. The n⁺ type channel stopper layer 32 surrounds the p type termination well layers 31.

The p type termination collector layer 11a is provided between the n⁻ type drift layer 1 and the second main surface of the semiconductor base body 120. The p type termination collector layer 11a is formed integrally with the p type collector layer 11 provided in the cell region in continuous fashion. Thus, the p type collector layer 11, including the p type termination collector layer 11a, may be referred to as the p type collector layer 11. In a configuration in which the diode region 102 is disposed adjacent to the outer periphery region 103 as in the semiconductor device 200 shown in FIG. 1, an end portion of the p type termination collector layer 11a which is on the diode region 102 side protrudes a distance U2 toward the diode region 102, as shown in FIG. 7. The provision of the p type termination collector layer 11a protruding toward the diode region 102 in this manner increases the distance between the n⁺ type cathode layer 12 in the diode region 102 and the p type termination well layers 31 to restrain the p type termination well layers 31 from operating as the anode of the diode. The distance U2 may be, for example, 100 μm.

The collector electrode 14 is provided on the second main surface of the semiconductor base body 120. The collector electrode 14 is formed integrally in continuous fashion from the cell region including the IGBT regions 101 and the diode regions 102 to the outer periphery region 103. The emitter electrode 13 continuous from the cell region and termination electrodes 13a separated from the emitter electrode 13 are provided on the first main surface of the semiconductor base body 120 in the outer periphery region 103.

The emitter electrode 13 and the termination electrodes 13a are electrically connected through a semi-insulating film 33. The semi-insulating film 33 may be a film of sinSiN (semi-insulating Silicon Nitride), for example. The termination electrodes 13a are electrically connected to the p type termination well layers 31 and the n⁺ type channel stopper layer 32 through contact holes formed in the interlayer insulation films 9 provided on the first main surface in the outer periphery region 103. A termination protective film 34 is provided in the outer periphery region 103 so as to cover the emitter electrode 13, the termination electrodes 13a, and the semi-insulating film 33. The termination protective film 34 may be made of polyimide, for example.

<A-1-4. Summary of Configuration>

The semiconductor device 200 or the semiconductor device 201 is a semiconductor device in which an IGBT and a diode are formed in the common semiconductor base body 120. The semiconductor base body 120 includes the first and second main surfaces as one and the other main surfaces, the IGBT region 101 in which the IGBT is formed, and the diode region 102 in which the diode is formed. The IGBT region 101 includes: the p type collector layer 11 provided on the second main surface side of the semiconductor base body 120; the n⁻ type drift layer 1 provided on the p type collector layer 11; the p type channel dope layers 2 provided closer to the first main surface of the semiconductor base body 120 than the n⁻ type drift layer 1; the n⁺ type emitter layers 3 provided on the p type channel dope layers 2; the emitter electrode 13 electrically connected to the n⁺ type emitter layers 3; and the collector electrode 14 electrically connected to the p type collector layer 11. The diode region 102 includes: the n⁺ type cathode layer 12 provided on the second main surface side of the semiconductor base body 120; the n⁻ type drift layer 1 provided on the n⁺ type cathode layer 12; the p type anode layers 5 provided closer to the first main surface of the semiconductor base body 120 than the n⁻ type drift layer 1; the p⁺ type contact layers 6 provided on the p type anode layers 5 and having a p type impurity concentration higher than that of the p type anode layers 5; the emitter electrode 13 electrically connected to the p⁺ type contact layers 6; and the collector electrode 14 electrically connected to the n⁺ type cathode layer 12. In addition, the defect regions 15 are provided at least in regions of the p type anode layers 5 which are at the second main surface side of the p⁺ type contact layers 6 and which overlap the p⁺ type contact layers 6 as seen in plan view.

In the semiconductor device 200 or the semiconductor device 201, an n-channel MOSFET (Metal-Oxide-Semiconductor Field Effect Transistor) structure formed by the n⁻ type drift layer 1, the p type channel dope layers 2, the n⁺ type emitter layers 3, the gate insulation films 7, and the buried gate electrodes 8 is formed in the IGBT region 101. Further, an IGBT structure is formed by including the p type collector layer 11 in the MOSFET structure.

In the semiconductor device 200 or the semiconductor device 201, a diode structure is formed by the p type anode layers 5, the p⁺ type contact layers 6, the n⁻ type drift layer 1, and the n⁺ type cathode layer 12 in the diode region 102.

The semiconductor device 200 or the semiconductor device 201 has features to be described below.

A first feature is that the defect regions 15 are provided in regions of the p type anode layers 5 formed in the diode region 102 which are at the second main surface side of the p⁺ type contact layers 6 and which overlap the p⁺ type contact layers 6 as seen in plan view. Further, the defect regions 15 and the p⁺ type contact layers 6 are formed in the same regions as seen in plan view. The presence of the defect regions 15 is confirmable by a cathodoluminescence method that evaluates physical properties from cathodoluminescence which is the emission of light generated when a sample is irradiated with accelerated electrons.

A second feature is that the defect regions 15 are crystal defect regions containing light ions of Ar (argon), N (nitrogen), H (hydrogen), or He (helium) and formed by ion implantation of argon, nitrogen hydrogen, or helium.

A third feature is that the defect regions 15 are formed using the same mask in the step of selectively forming the p⁺ type contact layers 6 on the surface thereof.

A fourth feature is that the defect regions 15 are formed in regions having a p type impurity concentration of not less than 1.0E+16/cm³ in the p⁺ type contact layers 6 or the p type anode layers 5.

A fifth feature is that the p type anode layers 5 and the p⁺ type contact layers 6 at the first main surface are disposed alternately in the longitudinal direction of the trench gates 50, and the ratio of the area of the p⁺ type contact layers 6 as seen in plan view (that is, the area of the defect regions 15) to the area of a combination of the p type anode layers 5 and the p⁺ type contact layers 6 as seen in plan view is set to not less than 20%.

A sixth feature is that the defect regions 15 are formed so as to include at least part of the diode region 102 which is in contact with the IGBT region 101. For example, the defect regions 15 are formed at least in part of the diode region 102 where the distance from the IGBT region 101 as seen in plan view is less than the thickness of the semiconductor base body 120.

<A-2. Manufacturing Method>

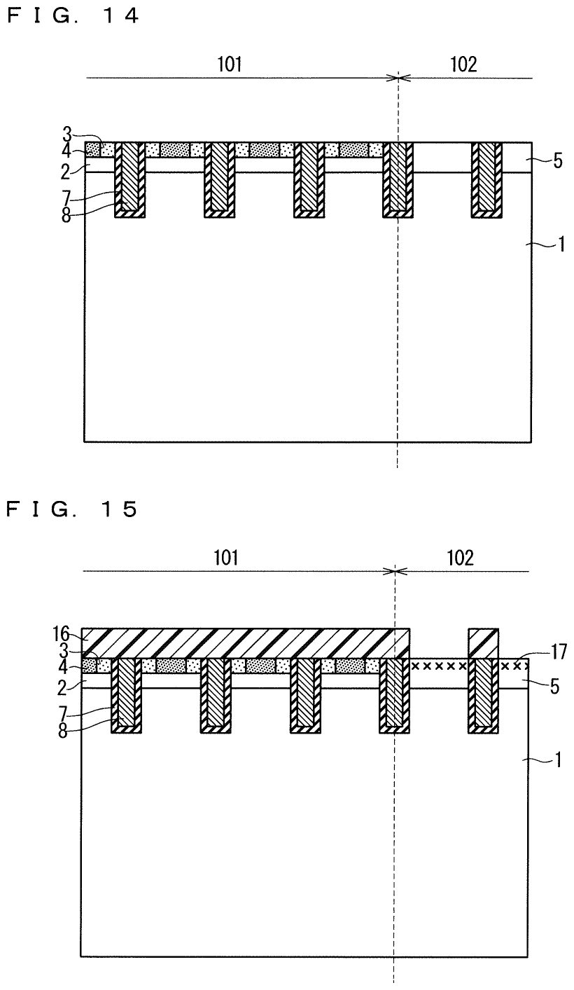

An example of a method of manufacturing the semiconductor device 200 or the semiconductor device 201 will be described. The cross-section (FIG. 4) taken along the line A-A shown in FIG. 3 is assumed in the following description. The structure of the cross-section (FIG. 5) taken along the line B-B shown in FIG. 3 is formed in a manner similar to the cross-section taken along the line A-A shown in FIG. 3 except that the defect regions 15 and the p⁺ type contact layers 6 are not formed therein in the step of FIGS. 15 to 17.

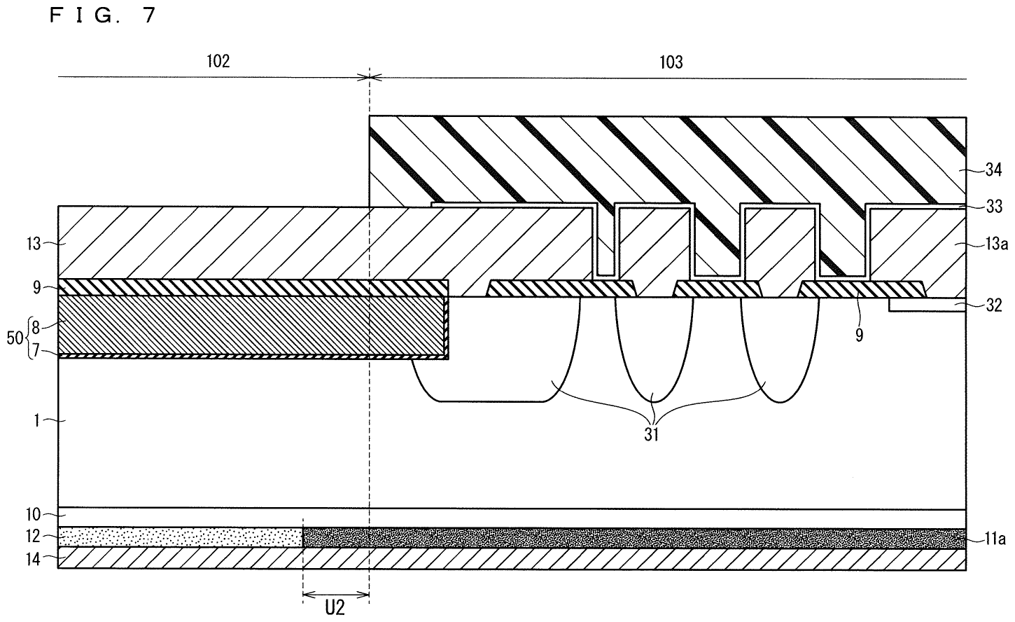

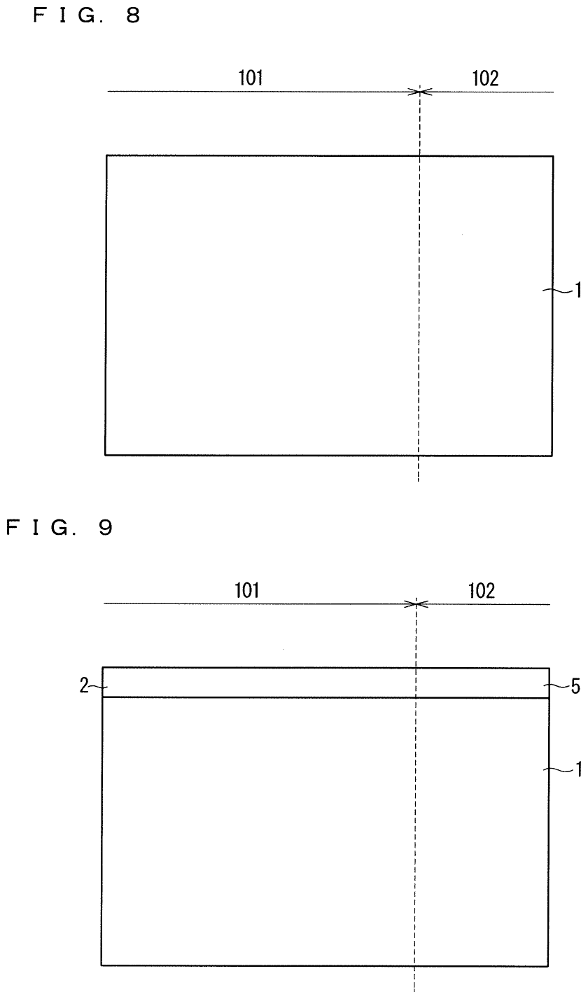

First, a semiconductor substrate constituting the n⁻ type drift layer 1 is prepared, as shown in FIG. 8. Although it is assumed that the semiconductor substrate is a silicon substrate in the following description, the semiconductor substrate may be a SiC substrate or the like. A wafer known as an FZ wafer produced by an FZ (Floating Zone) method or a wafer known as an MCZ wafer produced by an MCZ (Magnetic field applied Czochralski) method, for example, may be used for the semiconductor substrate. An n type wafer containing n type impurities may be used for the semiconductor substrate. The concentration of the n type impurities contained in the semiconductor substrate is selected, as appropriate, depending on the breakdown voltage of the semiconductor device to be produced. For a semiconductor device with a breakdown voltage of 1200 V, the n type impurity concentration is adjusted so that the resistivity of the n⁻ type drift layer 1 constituting the semiconductor substrate is on the order of 40 to 120 Ω·cm. As shown in FIG. 8, the entire semiconductor substrate is the n⁻ type drift layer 1 in the step of preparing the semiconductor substrate. P type or n type impurity ions are implanted from the first main surface side or the second main surface side of such a semiconductor substrate and are then diffused in the semiconductor substrate by heat treatment and the like to form p type or n type semiconductor layers, whereby the semiconductor device 200 or the semiconductor device 201 is manufactured.

As shown in FIG. 8, the semiconductor substrate constituting the n⁻ type drift layer 1 includes regions that become the IGBT region 101 and the diode region 102. Although not shown, the semiconductor substrate further includes a region that becomes the outer periphery region 103 around the regions that become the IGBT region 101 and the diode region 102. A method of manufacturing the configuration of the IGBT region 101 and the diode region 102 of the semiconductor device 200 or the semiconductor device 201 will be mainly described below. The outer periphery region 103 of the semiconductor device 200 or the semiconductor device 201 may be produced by a known manufacturing method. For the formation of the FLR having the p type termination well layers 31 as a breakdown voltage maintaining structure in the outer periphery region 103 as an example, p type impurity ions may be implanted before the processing of the IGBT region 101 and the diode region 102 of the semiconductor device 200 or the semiconductor device 201 or p type impurity ions may be implanted at the same time that ions of p type impurity are implanted into the IGBT region 101 and the diode region 102 of the semiconductor device 200 or the semiconductor device 201.

Next, as shown in FIG. 9, p type impurities such as boron are implanted from the first main surface side of the semiconductor substrate to form a p type channel dope layer 2 and a p type anode layer 5. The p type channel dope layer 2 and the p type anode layer 5 are formed by implanting impurity ions into the semiconductor substrate and then diffusing the impurity ions by heat treatment. The p type channel dope layer 2 and the p type anode layer 5 are selectively formed on the first main surface side of the semiconductor substrate because p type impurity ions are implanted after a mask process is performed on the first main surface of the semiconductor substrate. The p type channel dope layer 2 and the p type anode layer 5 are formed in the IGBT region 101 and the diode region 102, and are connected to the p type termination well layers 31 in the outer periphery region 103. The mask process refers to the process of forming a mask on the semiconductor substrate by applying a resist on the semiconductor substrate, forming an opening in a predetermined region of the resist by photolithography, for the purposes of implanting ions through the opening into the predetermined region of the semiconductor substrate or performing etching in the predetermined region.

The p type channel dope layer 2 and the p type anode layer 5 may be formed by implanting ions of p type impurity at the same time. In this case, the p type channel dope layer 2 and the p type anode layer 5 are identical in depth, in p type impurity concentration, and in configuration. Alternatively, the p type channel dope layer 2 and the p type anode layer 5 may be made different from each other in depth and in p type impurity concentration by implanting ions of p type impurities at different times between the p type channel dope layer 2 and the p type anode layer 5 by means of the mask process.

The p type termination well layers 31 to be formed in a different cross-section may be formed by implanting ions of p type impurities at the same time as the p type anode layer 5. In this case, the p type termination well layers 31 and the p type anode layer 5 can be identical in depth, in p type impurity concentration, and in configuration. Alternatively, the p type termination well layers 31 and the p type anode layer 5 can be made different from each other in p type impurity concentration by implanting ions of p type impurities at the same time to form the p type termination well layers 31 and the p type anode layer 5. In this case, an aperture ratio may be changed by using a mesh mask as one or both masks.

Also, the p type termination well layers 31 and the p type anode layer 5 may be made different from each other in depth and in p type impurity concentration by implanting ions of p type impurities at different times between the p type termination well layers 31 and the p type anode layer 5 by means of the mask process.

The p type termination well layers 31, p type channel dope layer 2, and the p type anode layer 5 may be formed by implanting ions of p type impurity at the same time.

Next, as shown in FIG. 10, n type impurities are selectively implanted into the first main surface side of the p type channel dope layer 2 in the IGBT region 101 by means of the mask process to form the n⁺ type emitter layers 3. The n type impurities to be implanted may be arsenic or phosphorus, for example.

Next, as shown in FIG. 11, trenches 51 extending from the first main surface side of the semiconductor substrate through the n⁺ type emitter layers 3, the p type channel dope layer 2, and the p type anode layer 5 to the n⁻ type drift layer 1 are formed. In the IGBT region 101, the trenches 51 extending through the n⁺ type emitter layers 3 have side walls constituting part of the n⁺ type emitter layers 3. The trenches 51 may be formed by depositing an oxide film of SiO₂ and the like on the semiconductor substrate, forming openings in part of the oxide film where the trenches 51 are to be formed by means of the mask process, and etching the semiconductor substrate using the oxide film having the openings as a mask. The trenches 51 in the IGBT region 101 and the trenches 51 in the diode region 102 are shown as disposed at the same spacing in FIG. 11. However, the IGBT region 101 and the diode region 102 may be different in spacing between the trenches 51. The spacing between the trenches 51 and the pattern of the trenches 51 as seen in plan view may be changed, as appropriate, depending on the mask pattern of the mask process.

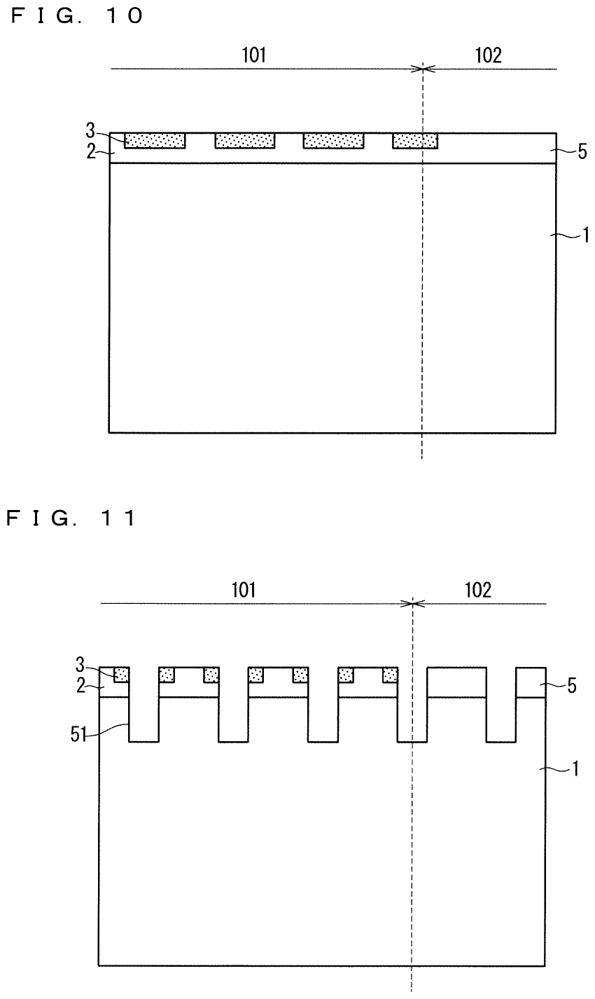

Next, as shown in FIG. 12, the semiconductor substrate is heated in an oxygen-containing atmosphere, so that oxide films are formed on inner walls of the trenches 51 and on the first main surface of the semiconductor substrate. The oxide films formed on the inner walls of the trenches 51 are the gate insulation films 7 of the trench gates 50, and the oxide films formed on the first main surface of the semiconductor substrate are oxide films 90. The oxide films 90 are removed in a subsequent step.

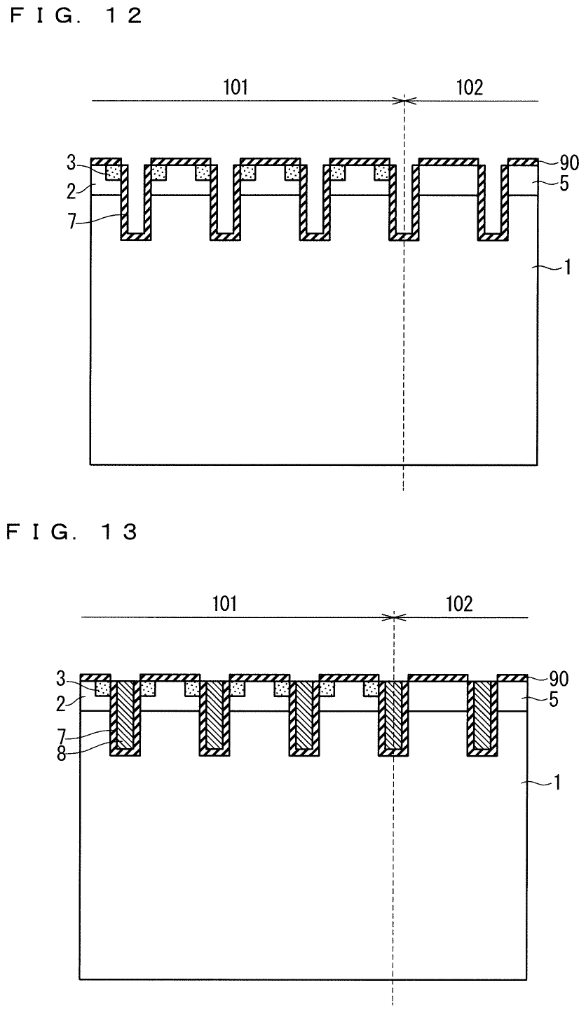

Next, as shown in FIG. 13, polysilicon doped with n type or p type impurities is deposited by a CVD (chemical vapor deposition) process and the like into the trenches 51 with the gate insulation films 7 formed on the inner walls thereof to form the buried gate electrodes 8.

Next, the oxide films 90 formed on the first main surface of the semiconductor substrate are removed.

Next, as shown in FIG. 14, impurity ions are selectively implanted into the IGBT region 101 and are then diffused by heat treatment to form the p⁺ type contact layers 4. Before the implantation of the impurity ions, a mask is formed by the mask process except regions corresponding to the p⁺ type contact layers 4.

Next, the mask used for the formation of the p⁺ type contact layers 4 is removed. Thereafter, a photoresist 16 covering other than regions corresponding to the p⁺ type contact layers 6 of the diode region 102 is formed by the mask process.

Next, as shown in FIG. 15, ion implantation is performed using the photoresist 16 as a mask to introduce p type impurities into the regions corresponding to the p′ type contact layers 6 of the diode region 102, thereby forming p type impurity-introduced regions 17.

Next, as shown in FIG. 16, using the same photoresist 16 as that used for the formation of the p type impurity-introduced regions 17, an element selected from the group consisting of argon, nitrogen, helium, and hydrogen is introduced into a position deeper than the p type impurity-introduced regions 17 to form crystal defect-introduced regions 18. In a material such as SiC, nitrogen is used to form an n type semiconductor layer. However, in a semiconductor substrate made of a silicon material assumed herein, nitrogen is used to form a crystal defect layer.

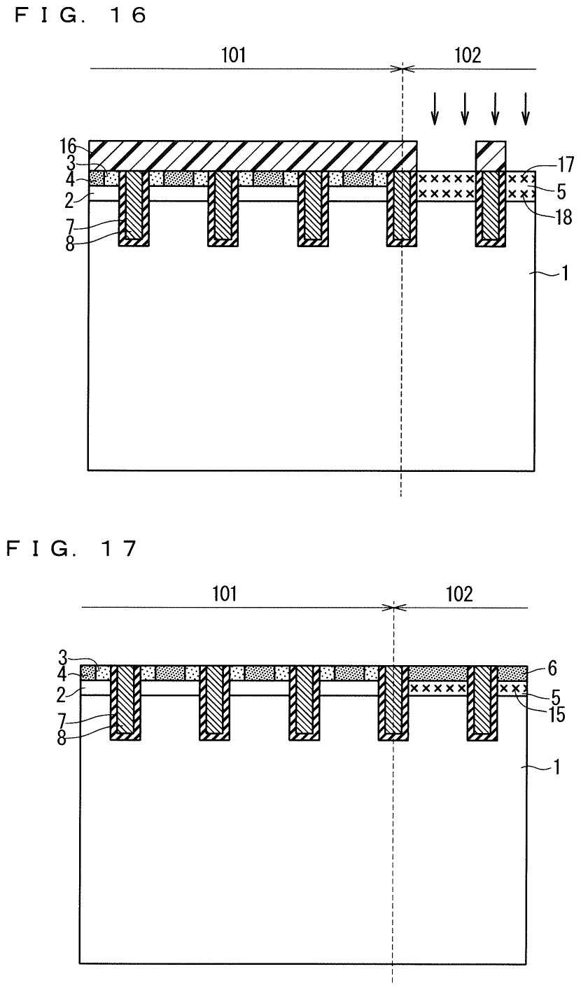

Next, as shown in FIG. 17, the photoresist 16 is removed, and a structure of an anode region in the diode region 102 is formed by heat treatment.

In the present preferred embodiment, an element selected from the group consisting of argon, nitrogen, helium, and hydrogen is used to form the defect regions 15. These elements can be implanted using typical ion implanters. The use of these elements allows the formation of the defect regions 15 at low costs.

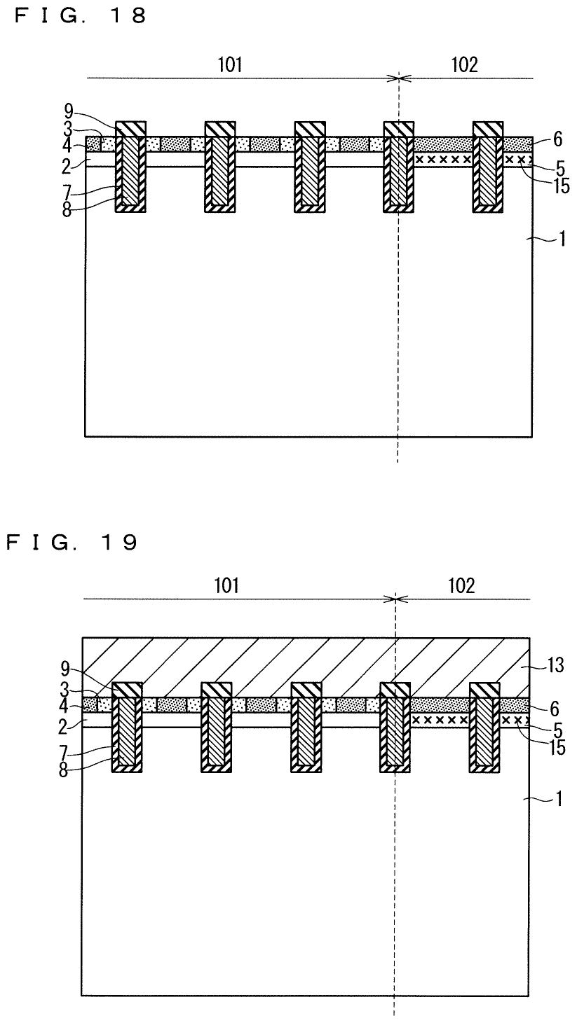

Next, as shown in FIG. 18, the interlayer insulation films 9 are formed on the buried gate electrodes 8 of the trench gates 50. The interlayer insulation films 9 may be made of SiO₂, for example. The interlayer insulation films 9 are deposited on the semiconductor substrate, including other than the buried gate electrodes 8. Thereafter, the mask process is performed to remove unnecessary parts of the interlayer insulation films 9, thereby forming the contact holes.

Next, as shown in FIG. 19, the emitter electrode 13 is formed on the first main surface of the semiconductor substrate and on the interlayer insulation films 9. A barrier metal may be formed on the first main surface of the semiconductor substrate and on the interlayer insulation films 9, and the emitter electrode 13 may be further formed on the barrier metal. The barrier metal is formed by making titanium nitride into a film by a PDV(physical vapor deposition) or CVD process.

The emitter electrode 13 may be formed by depositing an aluminum-silicon alloy (Al—Si alloy) on the first main surface of the semiconductor substrate and on the interlayer insulation films 9 by a PVD process such as sputtering or vapor deposition, for example. Also, a nickel alloy (Ni alloy) may be further formed on the formed aluminum-silicon alloy by electroless plating or electroplating, whereby the emitter electrode 13 is formed. The formation of the emitter electrode 13 by plating facilitates the formation of a thick metal film as the emitter electrode 13. This increases the heat capacity of the emitter electrode 13 to improve the heat resistance thereof. For the further formation of the nickel alloy by the plating process after the formation of the emitter electrode 13 made of the aluminum-silicon alloy by the PVD process, the plating process for the formation of the nickel alloy may be performed after the processing on the second main surface side of the semiconductor substrate.

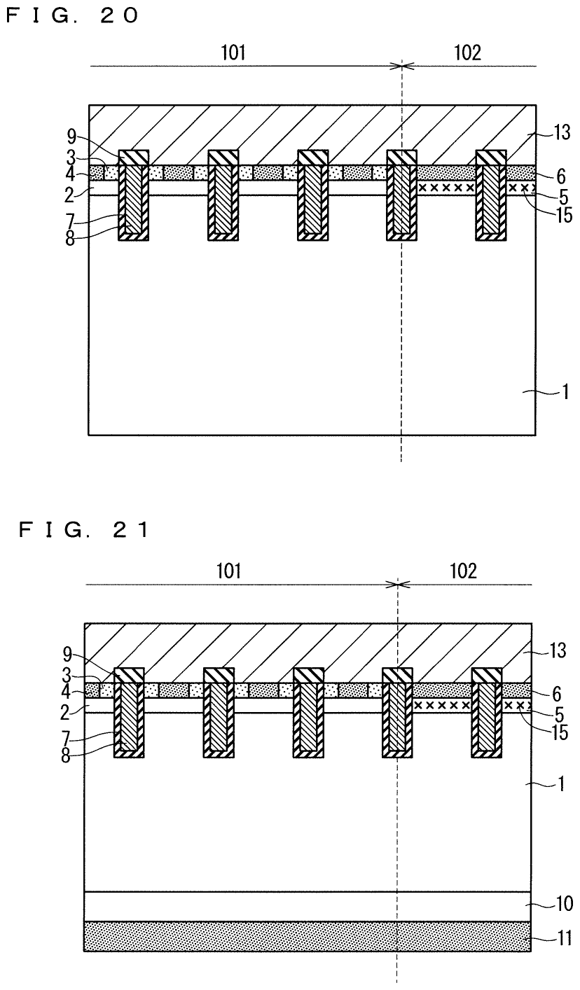

Next, as shown in FIG. 20, the second main surface side of the semiconductor substrate is ground until the semiconductor substrate is thinned to a designed thickness. In FIG. 20, the n⁻ type drift layer 1 constituting the semiconductor substrate is thinned. The thickness of the semiconductor substrate after the grinding may be 80 to 200 μm, for example.

Next, as shown in FIG. 21, n type impurities are implanted from the second main surface side of the semiconductor substrate to form the n type buffer layer 10. Further, p type impurities are implanted from the second main surface side of the semiconductor substrate to form the p type collector layer 11. The n type buffer layer 10 may be formed in the IGBT region 101, the diode region 102, and the outer periphery region 103. Alternatively, the n type buffer layer 10 may be formed only in the IGBT region 101 and the diode region 102.

The n type buffer layer 10 may be formed, for example, by implanting phosphorus ions. Alternatively, the n type buffer layer 10 may be formed by implanting protons. Further, the n type buffer layer 10 may be formed by implanting both protons and phosphorus. The protons are implanted to a deep position from the second main surface of the semiconductor substrate at a relatively low acceleration energy. The depth to which protons are implanted is changed relatively easily by changing the acceleration energy. Thus, implanting protons a plurality of times at different acceleration energies for the formation of the n type buffer layer 10 allows the formation of the n type buffer layer 10 wider in the thickness direction of the semiconductor substrate than implanting phosphorus.

The formation of the n type buffer layer 10 made of phosphorus suppresses the punch through of a depletion layer with higher reliability even in the thinned semiconductor substrate because phosphorus is capable of having a higher activation rate as n type impurities than protons. To make the semiconductor substrate further thinner, it is preferable that both protons and phosphorus are implanted to form the n type buffer layer 10. In this case, protons are implanted into a position deeper from the second main surface than phosphorus.

The p type collector layer 11 may be formed, for example, by implanting boron. The p type collector layer 11 is formed also in the outer periphery region 103. The p type collector layer 11 in the outer periphery region 103 becomes the p type termination collector layer 11a. Ions are implanted from the second main surface side of the semiconductor substrate, and laser annealing is thereafter performed by irradiating the second main surface with a laser. This activates the implanted boron to form the p type collector layer 11. At this time, phosphorus implanted in a relatively shallow position from the second main surface of the semiconductor substrate for the formation of the n type buffer layer 10 is activated at the same time. On the other hand, it is necessary to prevent the temperature of the entire semiconductor substrate from increasing to a temperature higher than 380° to 420° C. except in the step for activation of protons after the implantation of protons because protons are activated at a relatively low annealing temperature of 380° to 420° C. Laser annealing, which is capable of increasing the temperature of only the vicinity of the second main surface of the semiconductor substrate, may be used for the activation of n type impurities and p type impurities even after the implantation of protons.

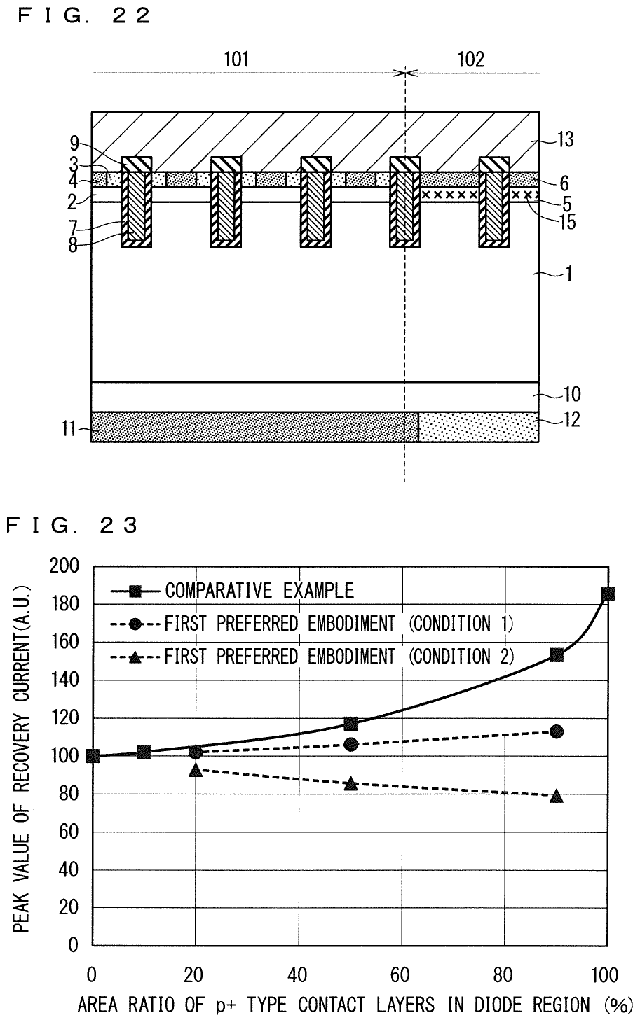

Next, as shown in FIG. 22, the n⁺ type cathode layer 12 is formed in the diode region 102. The n⁺ type cathode layer 12 may be formed, for example, by implanting phosphorus. The amounts of n type impurities implanted for the formation of the n⁺ type cathode layer 12 are greater than the amounts of p type impurities implanted for the formation of the p type collector layer 11. Although the p type collector layer 11 and the n⁺ type cathode layer 12 are shown in FIG. 22 as having the same depth from the second main surface, the depth of the n⁺ type cathode layer 12 is not less than that of the p type collector layer 11. The region where the n⁺ type cathode layer 12 is to be formed is required to become an n type semiconductor by implanting n type impurities into a region implanted with p type impurities. For this reason, the concentration of the implanted n type impurities is made higher than that of p type impurities in the entire region where the n⁺ type cathode layer 12 is to be formed.

Next, as shown in FIG. 4, the collector electrode 14 is formed on the second main surface of the semiconductor substrate. The collector electrode 14 is formed on the entire second main surface throughout the IGBT region 101, the diode region 102, and the outer periphery region 103. The collector electrode 14 may be formed on the entire second main surface of the n type wafer that is the semiconductor substrate. The collector electrode 14 may be formed by depositing an aluminum-silicon alloy (Al—Si alloy) or titanium (Ti) by a PVD process such as sputtering or vapor deposition. The collector electrode 14 may be formed by laminating a plurality of layers of metals such as an aluminum-silicon alloy, titanium, nickel, and gold. Further, a metal film may be formed on the metal film formed by the PVD process by electroless plating or electroplating to form the collector electrode 14.

The semiconductor device 200 or the semiconductor device 201 is produced by the aforementioned steps. A plurality of semiconductor devices 200 or semiconductor devices 201 are produced in the form of a matrix in a single n type wafer. Laser dicing or blade dicing is performed to cut the wafer into the individual semiconductor devices 200 or semiconductor devices 201, whereby each of the semiconductor devices 200 or semiconductor devices 201 is completed.

<A-3. Operation>

In the semiconductor device 200 or the semiconductor device 201 according to the present preferred embodiment, a diode is formed by the p type anode layers 5, the p⁺ type contact layers 6, the n⁻ type drift layer 1, and the n⁻ type cathode layer 12. The on state of the diode is a state in which an IGBT paired therewith is in an off state and the emitter electrode 13 is at a higher potential than the collector electrode 14. In the on state of the diode, holes flow from an anode region formed by the p type anode layers 5 and the p⁺ type contact layers 6 into the n⁻ type drift layer 1, and electrons flow from a cathode region formed by the n⁺ type cathode layer 12 into the n⁻ type drift layer 1. This causes conductivity modulation to occur, thereby bringing the diode into a conducting state.

In the present preferred embodiment, the defect regions 15 are formed in part of the p type anode layers 5 which lies under the p⁺ type contact layers 6. For this reason, the holes flowing from the p⁺ type contact layers 6 into the n⁻ type drift layer 1 pass through the defect regions 15. A smaller number of holes flow into the n⁻ type drift layer 1 because the recombination of holes occurs in the defect regions 15. This decreases the degree of conductivity modulation, so that the carrier concentration near the anode region in the conducting state of the diode is lowered as compared with that in the absence of the defect regions 15.

Next, the operation of the diode making a transition from this state through a recovery state to a cutoff state will be described. When, with the diode in an on state, the potential of the emitter electrode 13 becomes lower than that of the collector electrode 14 and the IGBT paired therewith is turned on, holes in the n⁻ type drift layer 1 come out from the p type anode layers 5 and the p⁺ type contact layers 6 into the emitter electrode 13, and electrons comes out from the n⁺ type cathode layer 12 into the collector electrode 14. It is necessary to discharge excess carriers in order to bring the diode into the cutoff state. If there are a large number of excess carriers, the increase in the number of discharged excess carriers accordingly increases reverse recovery current and also increases reverse recovery peak current (Irr) and recovery losses (Err).

In the present preferred embodiment, the carrier concentration near the anode region in the on state of the diode is lower than that in the absence of the defect regions 15, as mentioned above. Thus, the present preferred embodiment is capable of lowering the reverse recovery peak current (Irr) and the recovery losses (Err) during the diode operation than background techniques.

Next, the operation of the IGBT will be described. When the IGBT is in an on state, the buried gate electrodes 8 and the collector electrode 14 are at a higher potential than the emitter electrode 13, and the diode paired therewith is in the cutoff state. In the on state of the IGBT, holes flow from p type collector layer 11 into the n⁻ type drift layer 1, and electrons flow from the n⁺ type emitter layers 3 into the n⁻ type drift layer 1, whereby conductivity modulation occurs. When the collector electrode 14 remains at a higher potential than the emitter electrode 13 and the buried gate electrodes 8 are at a lower potential than the emitter electrode 13, a MOS channel formed by the n⁺ type emitter layers 3, the p type channel dope layers 2, and the n⁻ type drift layer 1 is closed, and excess carriers in the n⁻ type drift layer 1 are discharged in such a manner that holes are discharged from the emitter electrode 13 and electrons are discharged from the collector electrode 14, whereby the IGBT makes a transition to an off state.

The IGBT region 101 and the diode region 102 are formed adjacent to each other in the semiconductor device 200 or the semiconductor device 201 of the present preferred embodiment which is an RC-IGBT. For this reason, the current from the p type collector layer 11 corresponding to the IGBT region 101 formed near the diode region 102 includes a component partially flowing through the n⁻ type drift layer 1 within the diode region 102 into the emitter electrode 13 in addition to a component flowing through the n⁻ type drift layer 1 in the IGBT region 101 into the emitter electrode 13. When the conductivity modulation occurs during the IGBT operation, excess carriers are present also within the diode region 102.

The IGBT cannot make a transition to the off state unless the excess carriers in the diode region 102 are discharged. Thus, the excess carriers in the diode region 102 cause the problems of the deterioration of turn-off losses during the IGBT operation and the deterioration of an RBSOA (Reverse Bias Safe Operating Area) resulting from the concentration of current in part of the IGBT region 101 near the diode region 102.

In the present preferred embodiment, excess carriers easily flow to the diode region 102 because the defect regions 15 are formed in part of the diode region 102 which is in contact with the IGBT region 101, as described in the sixth feature of <A-1-4> mentioned above. Thus, the present preferred embodiment is capable of distributing current to suppress the concentration of current in part of the IGBT region 101 near the diode region 102, thereby suppressing the problems of the deterioration of the turn-off losses during the IGBT operation and the deterioration of the RBSOA.

It is effective to form the defect regions 15 in locations where the concentration of p type impurities is generally not less than 1.0E+16/cm³ in the p type anode layers 5 and the p⁺ type contact layers 6.

The defect regions 15, which serve as a recombination center of minority carriers, are preferably formed in a current path. However, the problem of an increase in leakage current arises if a depletion layer reaches the defect regions 15 when the diode is off (when the breakdown voltage is maintained). For this reason, it is effective that the defect regions 15 are formed in a region that the depletion layer does not reach when the breakdown voltage is maintained. The region that the depletion layer does not reach when the breakdown voltage is maintained depends on the depth and concentration distribution of the anode region. Forming the defect regions 15 so as not to include a region having a p type impurity concentration of not more than 1.0E+16/cm³ restrains the depletion layer from reaching the defect regions 15 when the breakdown voltage is maintained. This suppresses the leakage current when the breakdown voltage is maintained, and effectively reduces the recovery current.

Results of the verification of a relationship between the area ratio of the p⁺ type contact layers 6 in the diode region 102 and the recovery peak current (Irr) during the diode operation through simulation in the present preferred embodiment are shown in FIG. 23, The area ratio of the p⁺ type contact layers 6 in the diode region 102 is the ratio of the area of the p⁺ type contact layers 6 in the diode region 102 as seen in plan view to the area of a combination of the p type anode layers 5 and the p⁺ type contact layers 6 in the diode region 102 as seen in plan view.

Conditions 1 and 2 in FIG. 23 differ from each other in defect density of the defect regions 15 in the present preferred embodiment. Condition 2 is higher in defect density than Condition 1, and higher in probability of recombination in the defect regions 15 than Condition 1. In Conditions 1 and 2, the defect regions 15 are not provided in the p⁺ type contact layers 6 but are provided in regions of the p type anode layers 5 which are at the second surface side of the p⁺ type contact layers 6 and which are the same regions as the p⁺ type contact layers 6 as seen in plan view, so as to be provided in contact with the surface of the p⁺ type contact layers 6 on the second main surface side. Comparative Example in FIG. 23 is obtained by eliminating the defect regions 15 from Conditions 1 and 2. Specifically, Conditions 1 and 2 and Comparative Example have the same configuration except the defect regions 15 if having the same area ratio of the p⁺ type contact layers 6, and in particular have the same arrangement of the p type anode layers 5 and the p⁺ type contact layers 6. In the simulation shown in FIG. 23, the p⁺ type contact layers 6 are configured to extend in the direction of extension of the trench gates 50. In Conditions 1 and 2, the area ratio of the p⁺ type contact layers 6 is changed by changing a dimension of the p⁺ type contact layers 6 as measured in a direction perpendicular to the direction of extension of the trench gates 50, as in Comparative Example shown in FIG. 69. However, similar results are expected if a dimension of the p⁺ type contact layers 6 as measured in the direction of extension of the trench gates 50 is changed.

As mentioned above, the defect regions 15 are formed in the same regions as the type contact layers 6 as seen in plan view in the present preferred embodiment. That is, the defect regions 15 are formed ideally only in regions overlapping the p⁺ type contact layers 6 as seen in plan view. This efficiently suppresses the inflow of holes from portions with high inflow efficiency. Since the defect regions 15 are not formed in portions not overlapping the p⁺ type contact layers 6 but overlapping only the p type anode layers 5 as seen in plan view, the in-plane uniformity of the flowability of current is increased while the increase in forward voltage drop Vf is suppressed.

As can be seen from FIG. 23, regardless of the difference between Conditions 1 and 2, the defect regions 15 in the configuration of the present preferred embodiment are capable of lowering the recovery peak current (Irr) as compared with Comparative Example having the same area ratio of the p⁺ type contact layers 6 to thereby reduce the recovery losses. If the area ratio of the p⁺ type contact layers 6 (the area ratio of the defect regions 15) is not less than 20%, the results show the effects of reducing the recovery peak current (Irr) by not less than 5% as compared with Comparative Example having approximately the same area ratio.

Further, the results in Condition 2 show that the recovery peak current (Irr) and the recovery losses (Err) are reduced as the area ratio of the p⁺ type contact layers 6 (the area ratio of the defect regions 15) increases. It is found that Condition 2 is capable of making the losses lower than the lowest loss attainable in the absence of the defect regions 15 (the loss obtained when the area ratio of the p⁺ type contact layers 6 is 0% in FIG. 23).

When the defect regions 15 are absent, the reduction in the area of the p⁺ type contact layers 6 for purposes of reduction in recovery losses produces a side effect of increasing the forward voltage drop due to an increase in ohmic resistance. The defect regions 15 in the present preferred embodiment, however, are capable of achieving the reduction in recovery losses without the increase in ohmic resistance to improve the trade-off relationship between the recovery losses and the forward voltage drop.

Further, if the defect density of the defect regions 15 is increased as in Condition 2, the increases of area ratio of the p type contact layers 6 and the defect regions 15 lead to the reduction in ohmic resistance and to the reductions in recovery current and recovery losses.

<A-4. Effects>

In the semiconductor device 200 or the semiconductor device 201 according to the present preferred embodiment as described above, the defect regions 15 are formed in regions of the p type anode layers 5 which overlap the p⁺ type contact layers 6 as seen in plan view. The regions where the defect regions 15 are formed correspond to a current-carrying path in the on state of the diode. The formation of the defect regions 15 reduces the amounts of holes flowing from the p⁺ type contact layers 6 into the n⁻ type drift layer 1 in the on state of the diode to achieve the reductions in recovery current and recovery losses of the diode.

The defect regions 15 contain an element selected from the group consisting of argon, nitrogen, helium, and hydrogen. This allows the manufacture of the semiconductor device 200 or the semiconductor device 201 at low costs through the use of a typical ion implanter.

Further, the ion implantation for the formation of the defect regions 15 may use the same mask as is used in the ion implantation for the formation of the p⁺ type contact layers 6. This allows the formation of the defect regions 15 while minimizing the increase in the number of process steps.

The defect regions 15 are formed so as not to include a region of the p type anode layers 5 which has a p type impurity concentration of not more than 1.0E+16/cm³. Since the defect regions 15 are formed in the current path in the on state of the diode and in the region that the depletion layer does not reach in the cutoff state of the diode, the recovery losses are reduced while the increase in leakage current in the cutoff state of the diode is suppressed.

Further, the ratio of the area of the p⁺ type contact layers 6 and the defect regions 15 as seen in plan view to the area of a combination of the p type anode layers 5 and the p⁺ type contact layers 6 as seen in plan view is set to not less than 20%. This achieves the reduction in recovery losses of the diode below those obtained in the absence of the defect regions 15 while reducing the ohmic resistance between the anode region and the emitter electrode 13.

### B. Second Preferred Embodiment

<B-1. Configuration>

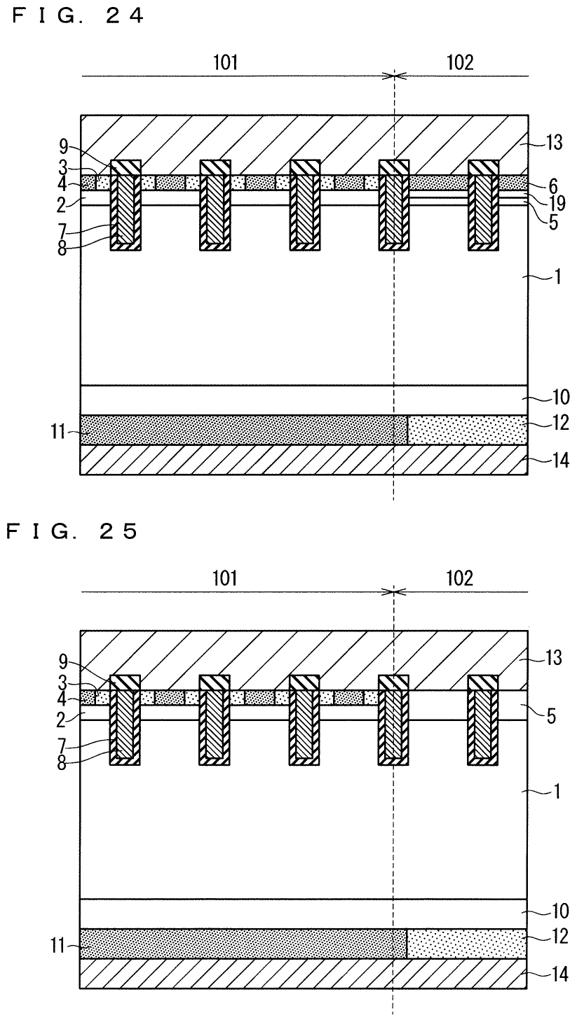

A plan view of a semiconductor device 200b that is a stripe type RC-IGBT according to a second preferred embodiment is shown in FIG. 1. A plan view of a semiconductor device 201b that is an island type RC-IGBT according to the second preferred embodiment is shown in FIG. 2. An enlarged plan view showing a region enclosed by the broken lines 82 in the semiconductor device 200b of FIG. 1 or the semiconductor device 201b of FIG. 2 on an enlarged scale is shown in FIG. 3. FIG. 24 is a sectional view of the semiconductor device 200b or the semiconductor device 201b taken along the line A-A of FIG. 3. FIG. 25 is a sectional view of the semiconductor device 200b or the semiconductor device 201b taken along the line B-B of FIG. 3.

As compared with the semiconductor device 200 or the semiconductor device 201, the present preferred embodiment does not include the defect regions 15 but includes n type semiconductor layers 19 (an eighth semiconductor layer) formed on the second main surface side of the p⁺ type contact layers 6 instead, as shown in FIG. 24. Specifically, the n type semiconductor layers 19 are selectively formed on the surface of the p type anode layers 5 on the first main surface side, and the p⁺ type contact layers 6 are formed on the surface of the n type semiconductor layers 19 on the first main surface side. The n type semiconductor layers 19 and the p⁺ type contact layers 6 are formed in the same regions as seen in plan view. Except for these respects, the semiconductor device 200b or the semiconductor device 201b is similar in configuration to the semiconductor device 200 or the semiconductor device 201, respectively. In the present preferred embodiment, however, if the p type impurity concentration in the anode region is higher at the first main surface side of the n type semiconductor layers 19 than at the second main surface side of the n type semiconductor layers 19, the first main surface side of the n type semiconductor layers 19 may be regarded as the p⁺ type contact layers 6, and the second main surface side of the n type semiconductor layers 19 may be regarded as the p type anode layers 5.

In the present preferred embodiment, the n type semiconductor layers 19 are formed by introducing n type impurities into a p type region to provide an n type region as a whole, which will be described in <B-2. Manufacturing Method>. The fact that the n type semiconductor layers 19 are of the n type as a whole is determined by SCM (Scanning Capacitance Microscopy) or SRP (Spreading Resistance Profiler).

<B-2. Manufacturing Method>

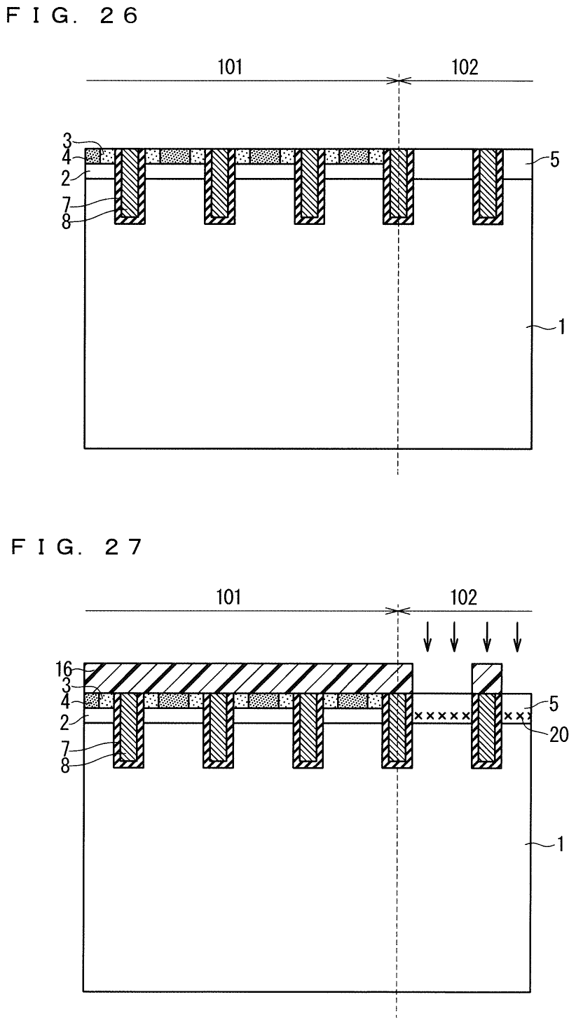

An example of the manufacturing method according to the present preferred embodiment is shown in FIGS. 26 to 29.

FIG. 26 is a view showing a manufacturing step of a cross section corresponding to FIG. 24, and is the same as FIG. 14 of the first preferred embodiment.

The structure of FIG. 26 except part of the diode region 102 is covered with the photoresist 16 by means of a mask process, and n type impurities are introduced into the part of the diode region 102 (FIG. 27). In the present preferred embodiment, phosphorus or arsenic is introduced to form n type impurity-introduced regions 20.

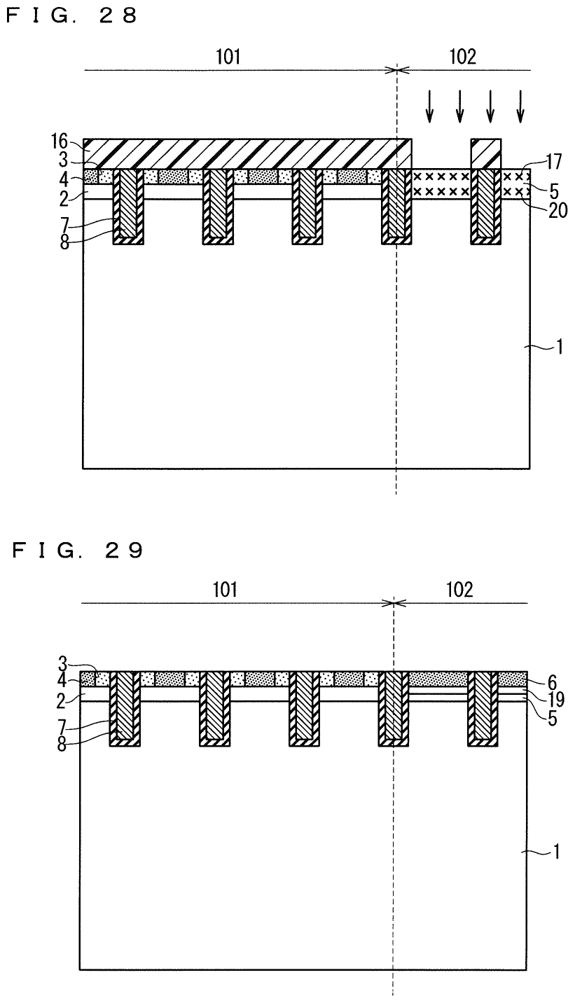

In the next step, with the semiconductor substrate partially covered with the same photoresist 16, p type impurities are further introduced into a position shallower than the n type impurity-introduced regions 20 to form the p type impurity-introduced regions 17 (FIG. 28).

In the next step, the photoresist 16 is removed, and heat treatment is performed to cause the p type impurity-introduced regions 17 to become the p⁺ type contact layers 6 and to cause the n type impurity-introduced regions 20 to become the n type semiconductor layers 19. Thus, the structure of the diode region 102 is formed (FIG. 29).

The formation of the p type impurity-introduced regions 17 and the n type impurity-introduced regions 20 in the method of manufacturing the semiconductor device according to the present preferred embodiment is achieved by ion implantation using typical ion implanters. This allows the formation of the p type impurity-introduced regions 17 and the n type impurity-introduced regions 20 at low costs.

In addition, the same mask may be used for the formation of the p type impurity-introduced regions 17 and for the formation of the n type impurity-introduced regions 20. This suppresses an increase in costs due to the formation of the n type impurity-introduced regions 20.

The subsequent steps of FIG. 29 are similar to the subsequent steps of FIG. 17 of the first preferred embodiment, and will not be described.

<B-3. Operation>

In the semiconductor device 200b or the semiconductor device 201b according to the present preferred embodiment, a diode structure is formed by the p type anode layers 5, the p⁺ type contact layers 6, the n⁻ type drift layer 1, and the n⁺ type cathode layer 12. In the conducting state of the diode, holes flow from the p type anode layers 5 and the p⁺ type contact layers 6 into the n⁻ type drift layer 1.

The n type semiconductor layers 19 are formed on the path of current flowing from the p⁺ type contact layers 6 to the n⁻ type drift layer 1. The n type semiconductor layers 19 function as a potential barrier layer to the holes flowing from the p⁺ type contact layers 6 to the n⁻ type drift layer 1, and the holes recombine in the n type semiconductor layers 19. Thus, a smaller number of holes flow into the n⁻ type drift layer 1. This decreases the degree of conductivity modulation, so that the carrier concentration near the anode region in the conducting state of the diode is lowered as compared with that in the absence of the n type semiconductor layers 19.

In the present preferred embodiment, the carrier concentration near the anode region in the conducting state of the diode is designed to be lower than that in the absence of the n type semiconductor layers 19, as mentioned above. For this reason, the effects of reducing the recovery peak current during the recovery operation and reducing the recovery losses are obtained without the reduction in area ratio of the p⁺ type contact layers 6 as compared with those in the absence of the n type semiconductor layers 19. In this manner, the n type semiconductor layers 19 are capable of improving the trade-off relationship between the recovery losses and the forward voltage drop.

To prevent an increase in leakage current in the cutoff state of the diode, it is desirable that the n type semiconductor layers 19 are in a region that a depletion layer does not reach when the breakdown voltage is maintained. It is only necessary to form the n type semiconductor layers 19 so that the n type semiconductor layers 19 do not include a region of the p type anode layers 5 which has a p type impurity concentration of not more than 1.0E+16/cm³.

The recovery losses are sufficiently reduced by setting the area of the p⁺ type contact layers 6 as seen in plan view (i.e., the area of the n type semiconductor layers 19) to not less than 20%.

### C. Third Preferred Embodiment

<C-1. Configuration>

A plan view of a semiconductor device 200c that is a stripe type RC-IGBT according to a third preferred embodiment is shown in FIG. 1. A plan view of a semiconductor device 201c that is an island type RC-IGBT according to the third preferred embodiment is shown in FIG. 2. An enlarged plan view showing a region enclosed by the broken lines 82 in the semiconductor device 200c of FIG. 1 or the semiconductor device 201c of FIG. 2 on an enlarged scale is shown in FIG. 3.

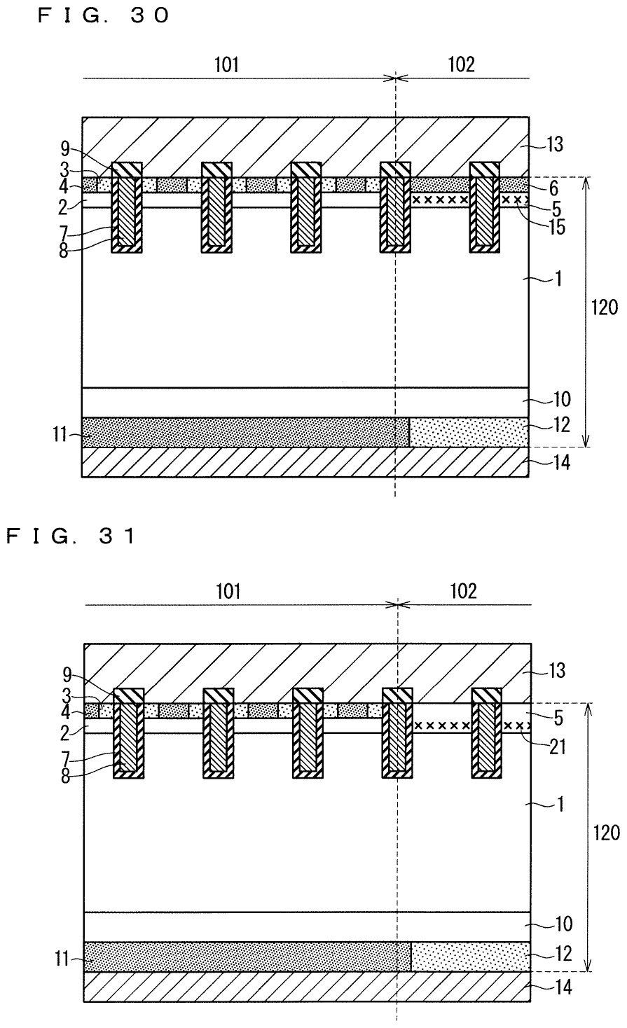

FIG. 30 is a sectional view of the semiconductor device 200c or the semiconductor device 201c taken along the line A-A of FIG. 3. FIG. 31 is a sectional view of the semiconductor device 200c or the semiconductor device 201c taken along the line B-B of FIG. 3.

In the semiconductor device 200c or the semiconductor device 201c according to the present preferred embodiment, the defect regions 15 are formed in part of the anode region which overlaps the p⁺ type contact layers 6 as seen in plan view, and defect regions 21 are further formed in part of the anode region which does not overlap the p⁺ type contact layers 6 as seen in plan view. The semiconductor device 200c or the semiconductor device 201c is similar in configuration to the semiconductor device 200 or the semiconductor device 201, respectively, except that the defect regions 21 are formed.

In the following description, it is assumed that a combination (the first crystal defect region) of the defect regions 15 and the defect regions 21 occupies the entire p type anode layers 5 as seen in plan view. However, the combination (the first crystal defect region) of the defect regions 15 and the defect regions 21 may occupy a partial region of the p type anode layers 5 as seen in plan view. For example, the defect regions 21 may partially occupy part of the p type anode region which does not overlap the p⁺ type contact layers 6 as seen in plan view.

<C-2. Manufacturing Method>

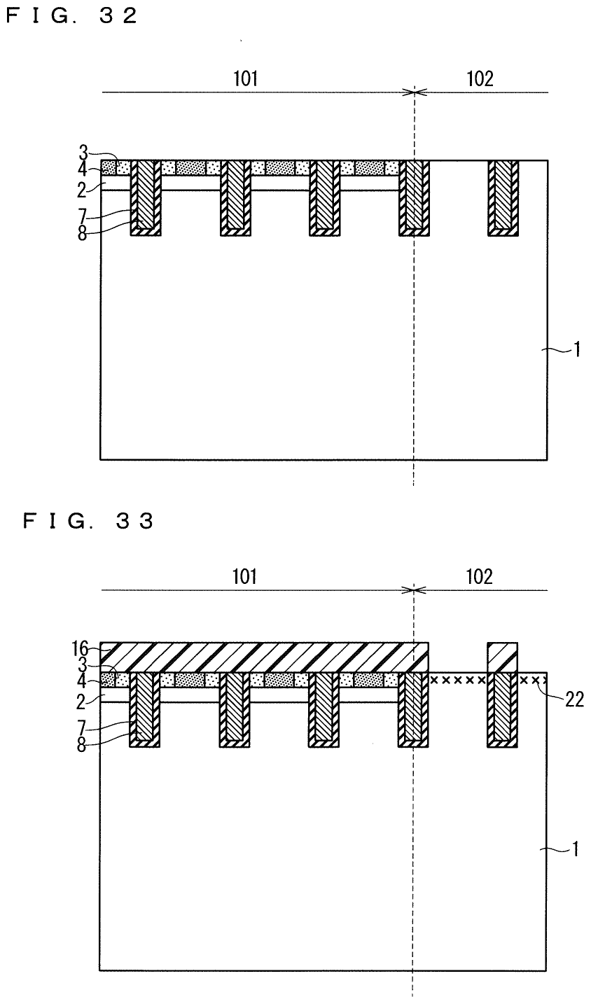

An example of the method of manufacturing a semiconductor device according to the present preferred embodiment will be described with reference to FIGS. 32 to 37.

FIGS. 32 to 34 are common to the cross section taken along the line A-A and the cross section taken along the line B-B.

The manufacturing steps until the formation of the structure of FIG. 32 differs from those until the formation of the structure of FIG. 14 of the first preferred embodiment in that the p type anode layers 5 are not formed. This difference is provided by a mask process. Other manufacturing steps are similar to those until the formation of the structure of FIG. 14 of the first preferred embodiment.

The structure of FIG. 32 except part of the diode region 102 is covered with the photoresist 16 by means of a mask process, and p type impurities are introduced into the part of the diode region 102 to form p type impurity-introduced regions 22 (FIG. 33).

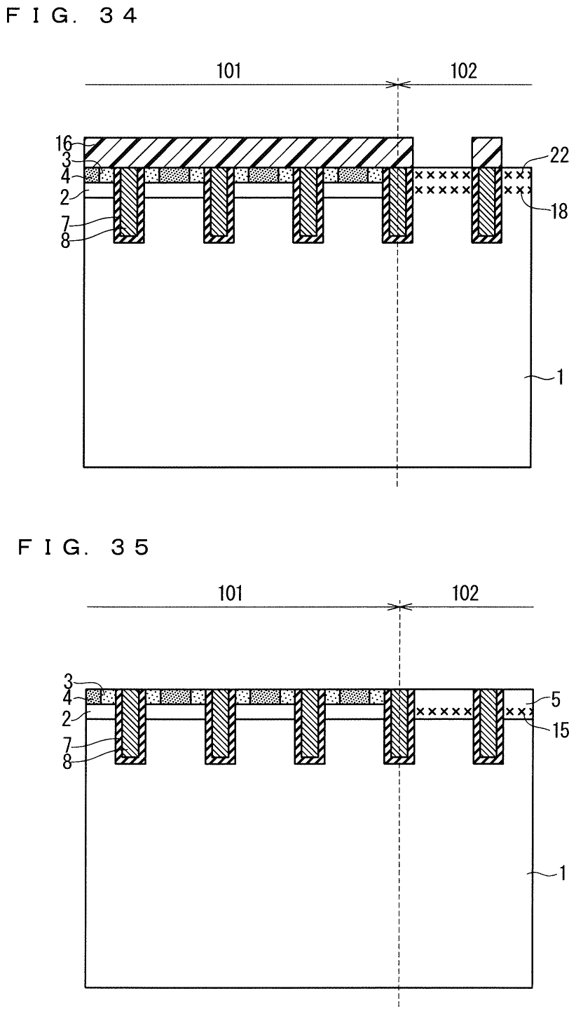

Next, with the semiconductor substrate partially covered with the same photoresist 16, an element selected from the group consisting of argon, nitrogen, helium, and hydrogen is introduced into a position deeper than the p type impurity-introduced regions 22 to form the crystal defect-introduced regions 18 (FIG. 34).

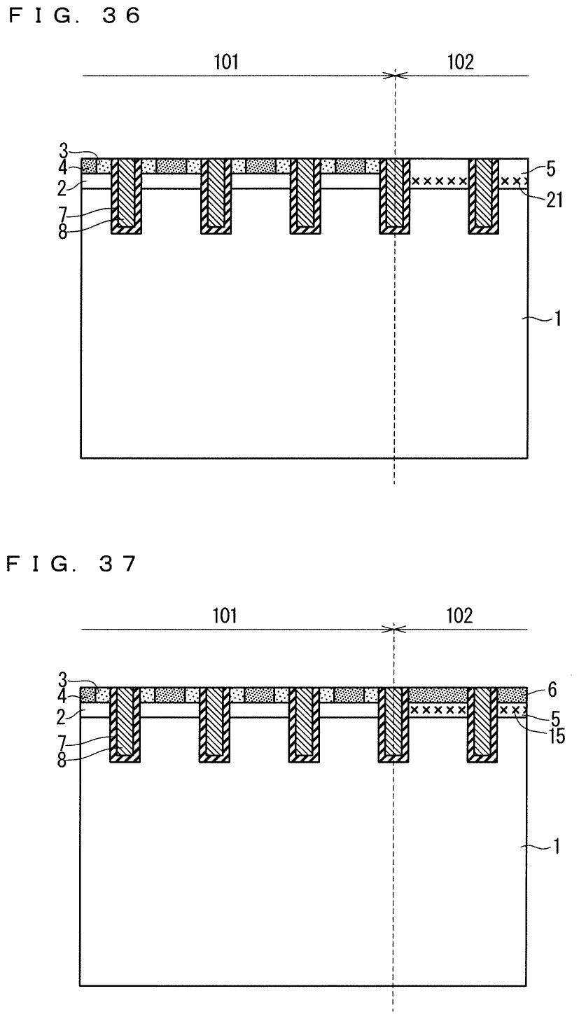

In the next step, the photoresist 16 is removed, and heat treatment is performed to diffuse the impurities in the p type impurity-introduced regions 22, thereby forming the p type anode layers 5 (the cross section along the line A-A is shown in FIG. 35; and the cross section along the line B-B is shown in FIG. 36).

Thereafter, a typical mask process, an ion implantation technique, and a diffusion technique are used to selectively form the p⁺ type contact layers 6 in the diode region 102. This provides the cross section along the line A-A as shown in FIG. 37, and the cross section along the line B-B remains as shown in FIG. 36.

The subsequent steps of FIG. 36 are similar to the subsequent steps of FIG. 17 of the first preferred embodiment, and will not be described.

<C-3. Operation>

The operation of the semiconductor device 200c or the semiconductor device 201c according to the present preferred embodiment is similar to that of the semiconductor device 200 or the semiconductor device 201 according to the first preferred embodiment. Specifically, in the semiconductor device 200c or the semiconductor device 201c, the defect regions 15 and the defect regions 21 reduce the amounts of holes flowing into the n⁻ type drift layer 1 in the on state of the diode to achieve the reductions in reverse recovery peak current (Irr) and recovery losses (Err) during the diode operation without an increase in ohmic resistance, thereby improving the trade-off between the recovery losses and the forward voltage drop.

In the present preferred embodiment, all current paths between the emitter electrode 13 and the n⁻ type drift layer 1 in the diode region 102 pass through the defect regions 15 or the defect regions 21. This reduces the recovery losses while the forward voltage drop (Vf) in the on state of the diode is higher in the present preferred embodiment than in the first preferred embodiment. This allows the appropriate use of the first and present preferred embodiments, depending on application purposes.

Forming the defect regions 15 and the defect regions 21 so as not to include a region having a p type impurity concentration of not more than 1.0E+16/cm³ restrains the depletion layer from reaching the defect regions 15 and the defect regions 21 when the breakdown voltage is maintained. This suppresses the leakage current when the breakdown voltage is maintained, and reduces the recovery current.

In the present preferred embodiment, the defect regions 21 are newly formed as compared with the first preferred embodiment, and all current paths between the emitter electrode 13 and the n⁻ type drift layer 1 in the diode region 102 pass through the defect regions 15 or the defect regions 21. Thus, if the defect density of the defect regions 15 is set to the defect density of the defect regions 15 in Condition 1 or 2 in FIG. 23 and the area ratio of the p⁺ type contact layers 6 is set to not less than 20%, the recovery losses are reduced by not less than 5% as compared with those in the absence of the defect regions 15 and the defect regions 21. Further, the increase in ohmic resistance in the anode region in the diode region 102 is prevented by appropriately setting the area ratio of the p⁺ type contact layers 6.

### D. Fourth Preferred Embodiment

<D-1. Configuration>

A plan view of a semiconductor device 200d that is a stripe type RC-IGBT according to a fourth preferred embodiment is shown in FIG. 1. A plan view of a semiconductor device 201d that is an island type RC-IGBT according to the fourth preferred embodiment is shown in FIG. 2. An enlarged plan view showing a region enclosed by the broken lines 82 in the semiconductor device 200d of FIG. 1 or the semiconductor device 201d of FIG. 2 on an enlarged scale is shown in FIG. 3.

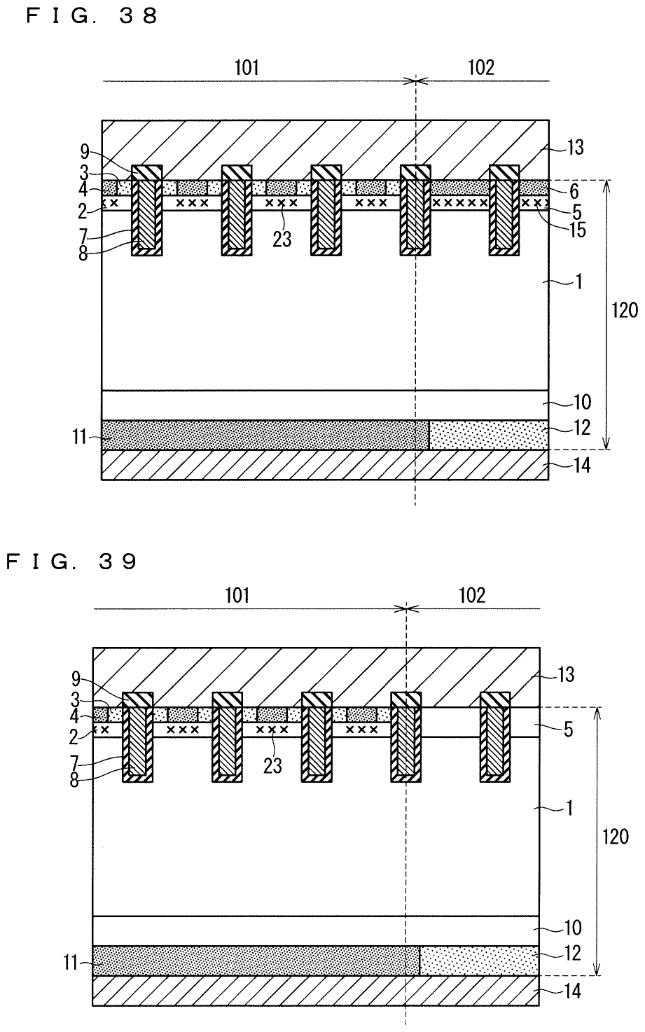

FIG. 38 is a sectional view of the semiconductor device 200d or the semiconductor device 201d taken along the line A-A of FIG. 3. FIG. 39 is a sectional view of the semiconductor device 200d or the semiconductor device 201d taken along the line B-B of FIG. 3.

The present preferred embodiment differs from the first preferred embodiment in that defect regions 23 (a second crystal defect region) are formed in part of the p type channel dope layers 2 in the IGBT region 101 which is at the second main surface side of the p⁺ type contact layers 4. Other parts of the present preferred embodiment are similar to those of the first preferred embodiment. For example, the arrangement of the defect regions 15 in the present preferred embodiment is the same as that of the defect regions 15 in the first preferred embodiment.

The defect regions 23 are formed at least in regions of the p type channel dope layers 2 which are at the second main surface side of the p⁺ type contact layers 4 and which overlap the p⁺ type contact layers 4 as seen in plan view. The defect regions 23 may be provided partially in the p type channel dope layers 2 and provided in spaced apart relation to the p⁺ type contact layers 4. Alternatively, the defect regions 23 may be provided in regions of the p type channel dope layers 2 which are in contact with the surface of the p⁺ type contact layers 4 on the second main surface side or provided so as to extend from the p type channel dope layers 2 to the p⁺ type contact layers 4, including the surface of the p⁺ type contact layers 4 on the second main surface side which is in contact with the p type channel dope layers 2. In the present preferred embodiment, the defect regions 23 and the p⁺ type contact layers 4 are formed in the same regions as seen in plan view.

<D-2. Manufacturing Method>

An example of the method of manufacturing a semiconductor device according to the present preferred embodiment will be described.

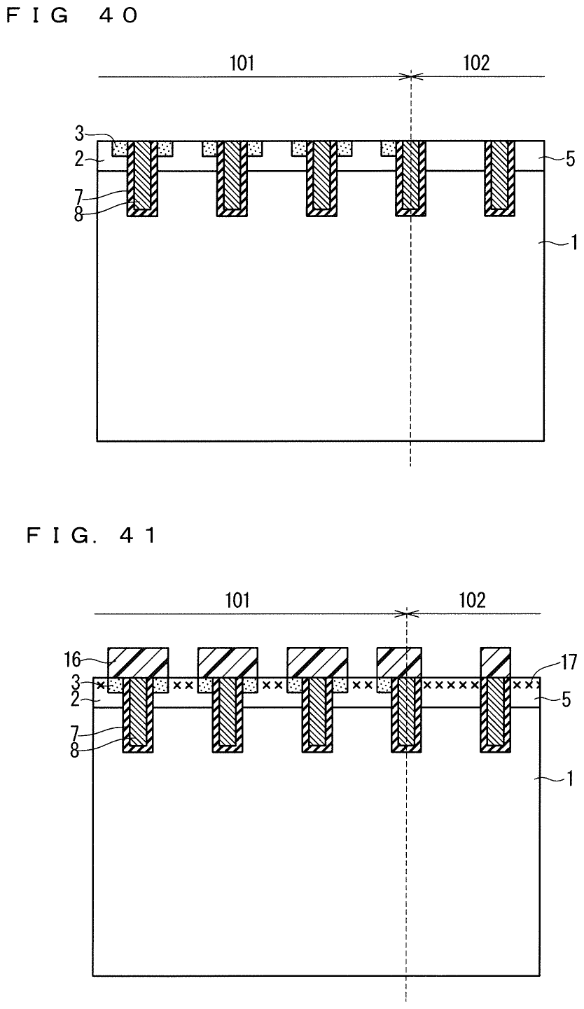

FIG. 40 is a view showing a manufacturing step of a cross section taken along the line A-A in the IGBT region 101 and the diode region 102. The structure of FIG. 40 is obtained by performing the process steps until the formation of the structure of FIG. 13 as in the first preferred embodiment and then removing the oxide films 90.

The structure of FIG. 40 except a region where the p⁺ type contact layers 4 are to be formed in the IGBT region 101 and a region where the p⁺ type contact layers 6 are to be formed in the diode region 102 is covered with the photoresist 16 by means of a mask process, and p type impurities are introduced into part of the IGBT region 101 and part of the diode region 102 to form the p type impurity-introduced regions 17 (FIG. 41).

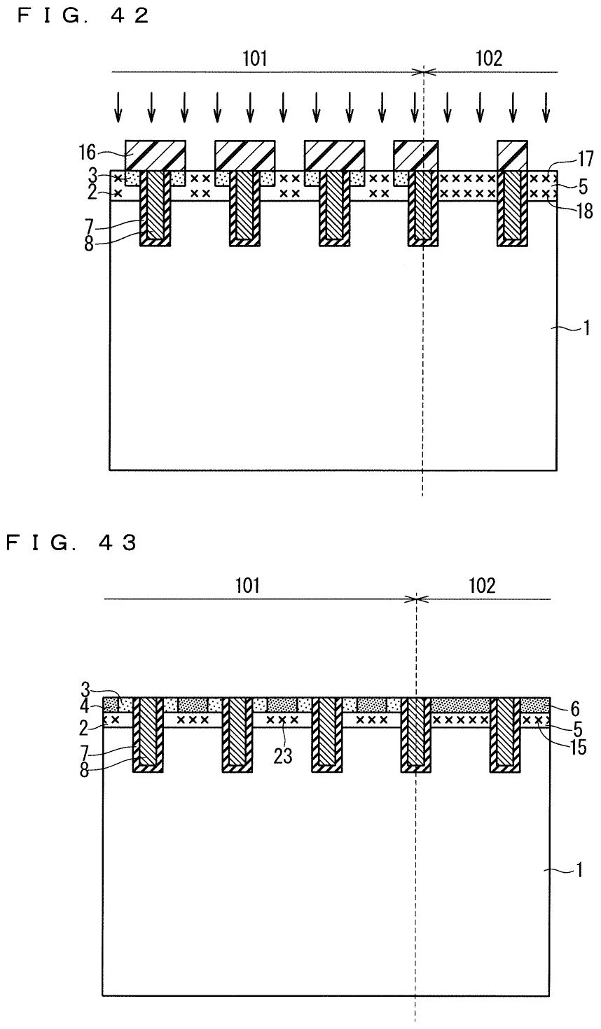

Next, with the semiconductor substrate partially covered with the same photoresist 16, an element selected from the group consisting of argon, nitrogen, helium, and hydrogen is introduced into a position deeper than the p type impurity-introduced regions 17 to form the crystal defect-introduced regions 18 (FIG. 42).

In the next step, the photoresist 16 is removed, and heat treatment is performed to cause the p type impurity-introduced regions 17 to become the p⁺ type contact layers 4 or the p⁺ type contact layers 6. Thus, the structure of the anode region in the IGBT region 101 and in the diode region 102 is formed (FIG. 43).

The subsequent steps of FIG. 43 are similar to the subsequent steps of FIG. 17 of the first preferred embodiment, and will not be described.

In the present preferred embodiment, an element selected from the group consisting of argon, nitrogen, helium, and hydrogen is used to form the defect regions 15 and the defect regions 23. These elements can be implanted using typical ion implanters. The use of these elements allows the formation of the defect regions at low costs.

Further, in the present preferred embodiment, the p⁺ type contact layers 4 and the p⁺ type contact layers 6 are formed through the same ion implantation process, and the defect regions 15 and the defect regions 23 are formed through the same ion implantation process. Also, the ion implantation for the formation of the p⁺ type contact layers 4 and the p⁺ type contact layers 6 and the ion implantation for the formation of the defect regions 15 and the defect regions 23 use the same photoresist 16. Thus, the present preferred embodiment is capable of achieving necessary functions while suppressing an increase in costs.

<D-3. Operation>

The operation focusing on the diode region 102 will not be described but the operation related to the IGBT region 101 will be described because the structure of the diode region 102 in the present preferred embodiment is the same as that in the first preferred embodiment.

A parasitic diode is formed by the p type channel dope layers 2, the p⁺ type contact layers 4, the n⁻ type drift layer 1, and the n⁺ type cathode layer 12 because the IGBT region 101 is connected to the emitter electrode 13 and the collector electrode 14. For this reason, holes flowing from the p type channel dope layers 2 and the p⁺ type contact layers 4 into the n type drift layer 1 in the on state of the diode become one factor responsible for the increase in recovery losses of the entire device during the diode operation.

In the present preferred embodiment, the defect regions 23 are formed at least in regions of the p type channel dope layers 2 which are at the second main surface side of the p⁺ type contact layers 4 and which overlap the p⁺ type contact layers 4 as seen in plan view. The defect regions 23 have the effect of reducing the carrier concentration in the n⁻ type drift layer 1 near the p type channel dope layers 2 in the IGBT region 101 in the on state during the diode operation because the defect regions 23 are positioned on the path of holes flowing from the p⁺ type contact layers 4 that are high-concentration impurity layers into the n⁻ type drift layer 1. This reduces the recovery losses of the parasitic diode formed by the p type channel dope layers 2, the p⁺ type contact layers 4, the n⁻ type drift layer 1, and the n⁺ type cathode layer 12 in the same manner as described that the recovery losses during the diode operation are reduced in the first preferred embodiment. As a result, the recovery losses of the semiconductor device 200d or the semiconductor device 201d during the diode operation are reduced in a comprehensive manner.

To suppress the leakage current, it is effective hat the defect regions 15 and the defect regions 23 are formed so as not to include a region having a p type impurity concentration of not more than 1.0E+16/cm³ as in the first preferred embodiment.

The details of the relationship between the area ratio of the p⁺ type contact layers 6 and the defect regions 15 and the reduction in recovery losses and the like will not be described because the present preferred embodiment produces the same effects as or better effects than the first preferred embodiment under the same conditions as the first preferred embodiment.

In the present preferred embodiment as described above, the defect regions 15 in the diode region 102 are provided in regions of the p type anode layers 5 which are at the second main surface side of the p⁺ type contact layers 6 and which overlap the p⁺ type contact layers 6 as seen in plan view. The defect regions 15 formed in this manner reduces the amounts of holes flowing into the n⁻ type drift layer 1 without an increase in ohmic resistance between the anode region and the emitter electrode 13 to thereby achieve the reduction in recovery losses. Also, the trade-off relationship between the recovery losses and the forward voltage drop during the diode operation is improved.

Similarly, the defect regions 23 are further formed in part of the p type channel dope layers 2 which is at the second main surface side of the p⁺ type contact layers 4. This suppresses the recovery losses resulting from the parasitic diode formed across the IGBT region 101 and the diode region 102 to improve the trade-off relationship between the recovery losses and the forward voltage drop during the diode operation. To suppress the recovery losses resulting from the parasitic diode more efficiently, it is desirable that the defect regions 23 are formed in regions where the distance from the diode region 102 as seen in plan view is less than the thickness of the semiconductor base body.

If the defect regions 23 are formed only in the regions overlapping the p⁺ type contact layers 4 as seen in plan view, the recovery losses resulting from the parasitic diode are suppressed while the influence on the on-state characteristics of the IGBT is reduced.

### E. Fifth Preferred Embodiment

<E-1. Configuration>

A plan view of a semiconductor device 200e that is a stripe type RC-IGBT according to a fifth preferred embodiment is shown in FIG. 1. A plan view of a semiconductor device 201e that is an island type RC-IGBT according to the fifth preferred embodiment is shown in FIG. 2. An enlarged plan view showing a region enclosed by the broken lines 82 in the semiconductor device 200e of FIG. 1 or the semiconductor device 201e of FIG. 2 on an enlarged scale is shown in FIG. 3.

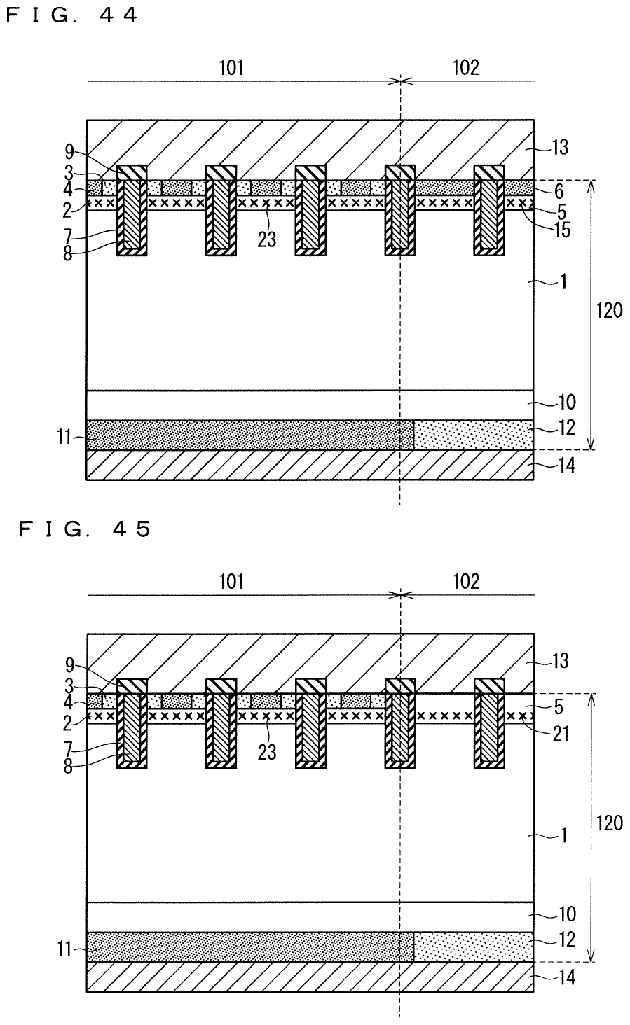

FIG. 44 is a sectional view of the semiconductor device 200e or the semiconductor device 201e taken along the line A-A of FIG. 3. FIG. 45 is a sectional view of the semiconductor device 200e or the semiconductor device 201e taken along the line B-B of FIG. 3.

In the semiconductor device 200e or the semiconductor device 201e according to the present preferred embodiment, a region of the p type channel dope layers 2 in the IGBT region 101 where the defect regions 23 are formed is the entire region overlapping the p⁺ type contact layers 4 and the n⁺ type emitter layers 3 as seen in plan view, that is, extends entirely in the in-plane direction of the p type channel dope layers 2. Also, the defect regions 23 are formed so as to extend from the p type channel dope layers 2 to the p⁺ type contact layers 4, including the surface of the p⁺ type contact layers 4 on the second main surface side which is in contact with the p type channel dope layers 2. Other parts of the present preferred embodiment are similar to those of the semiconductor device 200c or the semiconductor device 201c of the third preferred embodiment. That is, a combination of the defect regions 23, the defect regions 15, and the defect regions 21 in the present preferred embodiment overlaps the entire p type channel dope layers 2 and the entire p type anode layers 5 as seen in plan view.

<E-2. Manufacturing Method>

An example of the method of manufacturing a semiconductor device according to the present preferred embodiment will be described.

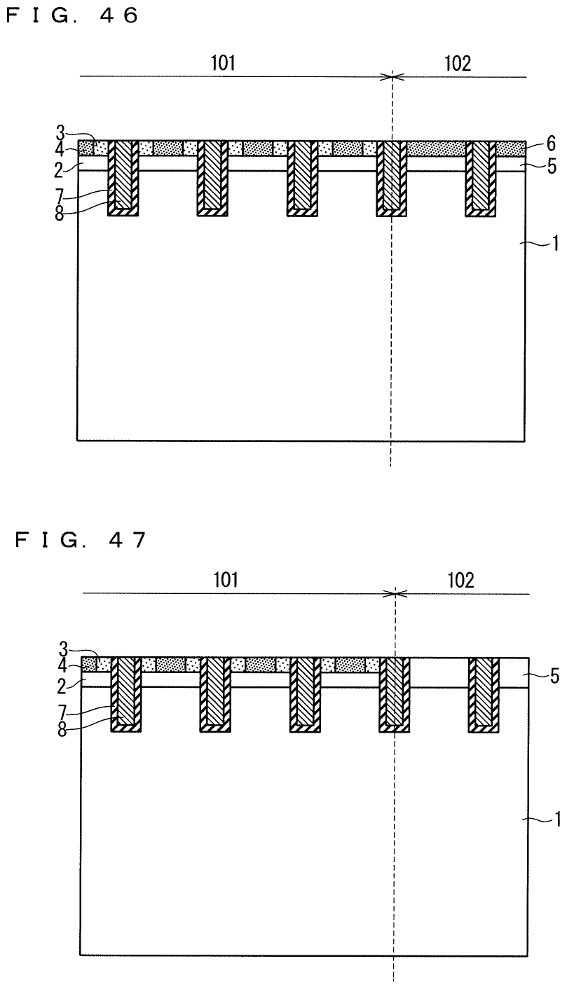

FIG. 46 is a view showing a manufacturing step of a cross section taken along the line A-A in the IGBT region 101 and the diode region 102. FIG. 47 is a view showing a manufacturing step of a cross section taken along the line B-B in the IGBT region 101 and the diode region 102. The structures of FIGS. 46 and 47 are obtained by performing the process steps until the formation of the structure of FIG. 13 as in the first preferred embodiment and then forming the p⁺ type contact layers 6 having the cross section taken along the line A-A at the same time that the p⁺ type contact layers 4 are formed.

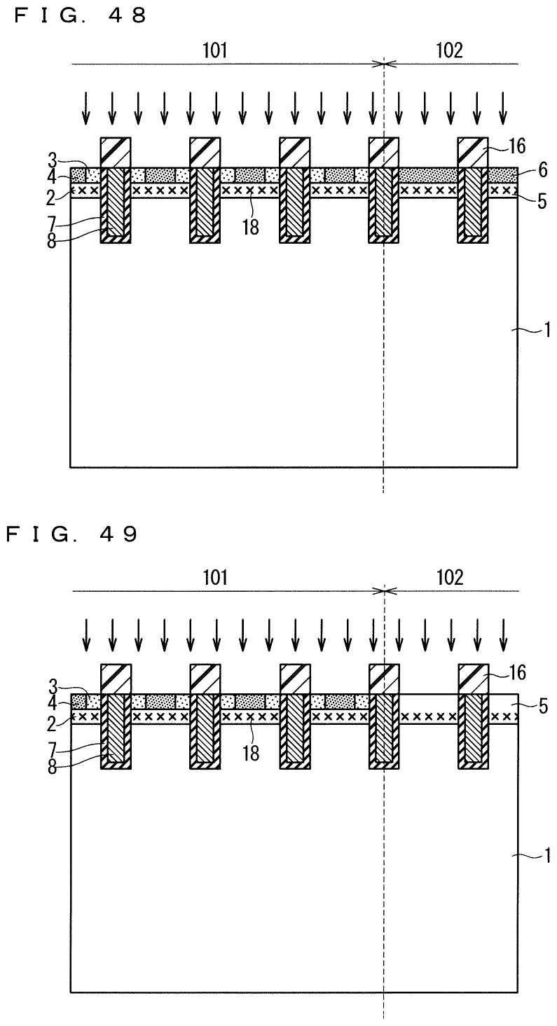

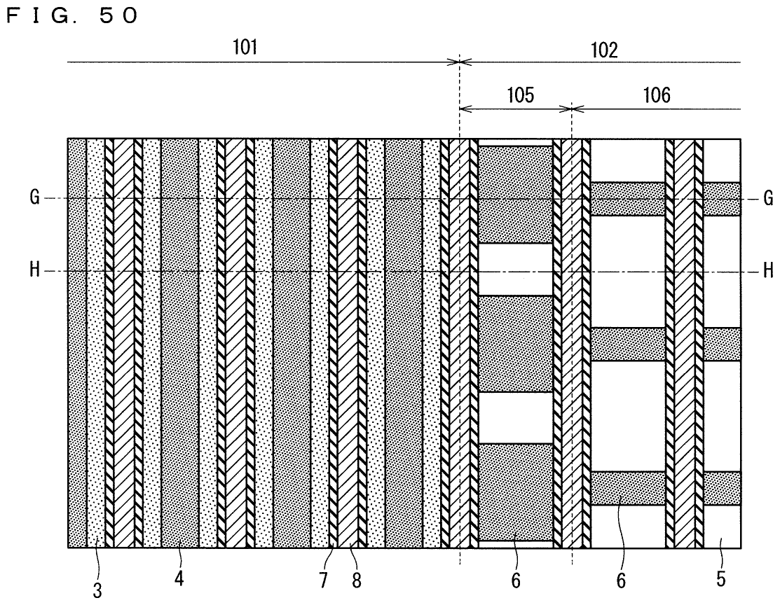

Next, the photoresist 16 covering the trench gates 50 is formed by a mask process, and an element selected from the group consisting of argon, nitrogen, helium, and hydrogen is introduced by ion implantation to form the defect regions 23, the defect regions 15, and the defect regions 21 (the cross section along the line A-A is shown in FIG. 48; and the cross section along the line B-B is shown in FIG. 49).

The subsequent steps of FIGS. 48 and 49 are similar to the subsequent steps of FIG. 17 of the first preferred embodiment, and will not be described.

<E-3. Operation>

The configuration of the semiconductor device 200e or the semiconductor device 201e according to the present preferred embodiment is the configuration of a combination of the first, third, and fourth preferred embodiments. During the diode operation, the current path of the diode in the diode region 102 and the current path of the parasitic diode present across the IGBT region 101 and the diode region 102 pass through the defect regions 23, the defect regions 15, or the defect regions 21. Thus, the reduction in recovery losses during the diode operation is achieved without an increase in ohmic resistance. This also improves the trade-off between the forward voltage drop Vf and the recovery losses.

### F. Sixth Preferred Embodiment

<F-1. Configuration>

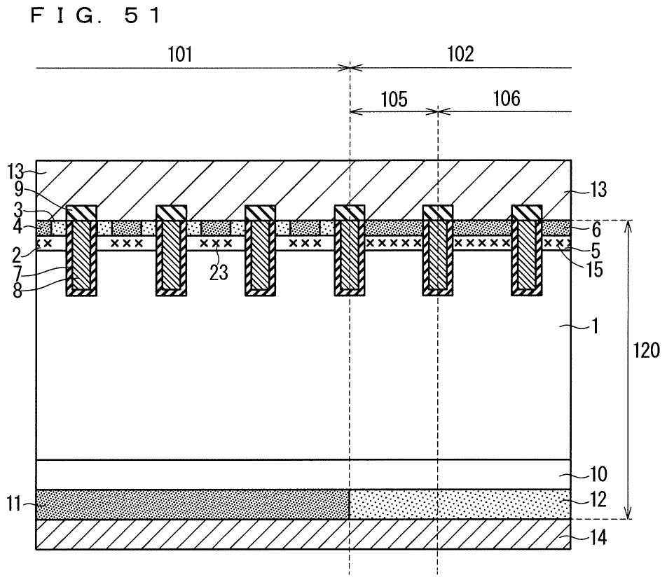

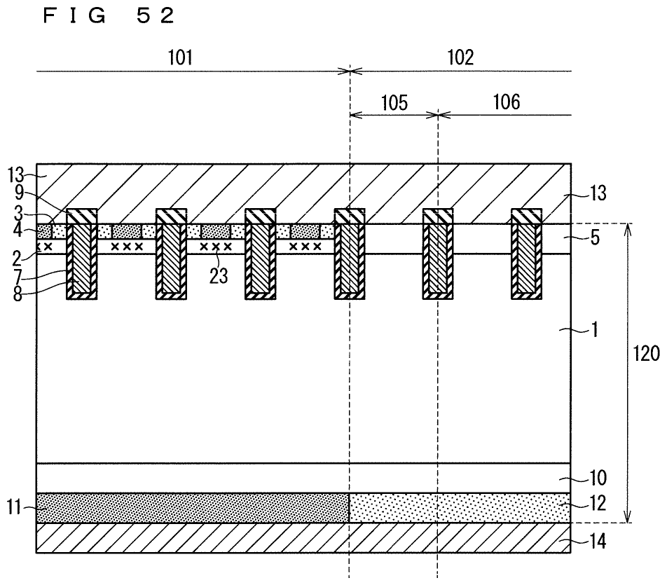

A plan view of a semiconductor device 200f that is a stripe type RC-IGBT according to a sixth preferred embodiment is shown in FIG. 1. A plan view of a semiconductor device 201f that is an island type RC-IGBT according to the sixth preferred embodiment is shown in FIG. 2. An enlarged plan view showing a region enclosed by the broken lines 82 in the semiconductor device 200f of FIG. 1 or the semiconductor device 201f of FIG. 2 on an enlarged scale is shown in FIG. 50. FIG. 51 is a sectional view of the semiconductor device 200f or the semiconductor device 201f taken along a line G-G shown in FIG. 50. FIG. 52 is a sectional view of the semiconductor device 200f or the semiconductor device 201f taken along a line H-H shown in FIG. 50.

With reference to FIGS. 50, 51, and 52, a boundary cell region 105 is a region of a unit cell of part of the diode region 102 which is in contact with the IGBT region 101. A standard cell region 106 is a region of the diode region 102 which is other than the boundary cell region 105. A unit cell refers to each of the regions separated by the trench gates 50.

In the present preferred embodiment, the defect regions 23 are formed in the same region as the p⁺ type contact layers 4 as seen in plan view so as to extend from the p⁺ type contact layers 4 to the p type channel dope layers 2. Also, the defect regions 15 are formed in the same region as the p⁺ type contact layers 6 as seen in plan view so as to extend from the p⁺ type contact layers 6 to the p type anode layers 5.

In the present preferred embodiment, the area ratio of the p⁺ type contact layers 6 in the boundary cell region 105 is higher than that of the p⁺ type contact layers 6 in the standard cell region 106, as shown in FIG. 50.

The area ratio of the p⁺ type contact layers 6 in a certain region of the diode region is the ratio of the area of the p⁺ type contact layers 6 in the certain region as seen in plan view to the area of a combination of the p type anode layers 5 and the p⁺ type contact layers 6 in the certain region as seen in plan view. Likewise, the area ratio of the defect regions 15 in a certain region of the diode region is the ratio of the area of the defect regions 15 in the certain region as seen in plan view to the area of a combination of the p type anode layers 5 and the p⁺ type contact layers 6 in the certain region as seen in plan view.

In the present preferred embodiment, the area ratio of the p⁺ type contact layers 6 in a certain region of the diode region may be regarded as the area ratio of the defect regions 15 in the certain region because it is assumed that the defect regions 15 are formed in the same region as the p⁺ type contact layers 6 as seen in plan view. That is, the area ratio of the defect regions 15 in the boundary cell region 105 is higher than that of the defect regions 15 in the standard cell region 106 in the present preferred embodiment, as shown in FIG. 50.

Further, the conditions for the defect regions 15 in the boundary cell region 105 are set so that the recovery peak current decreases as the area of the p⁺ type contact layers 6 and the defect regions 15 increases, as in Condition 2 of the first preferred embodiment shown in FIG. 23. As an example, both of the defect densities of the defect regions 15 in the boundary cell region 105 and in the standard cell region 106 are set as in Condition 2 shown in FIG. 23. As another example, the defect density of the defect regions 15 in the standard cell region 106 is set as in Condition 1 shown in FIG. 23 whereas the defect density of the defect regions 15 in the boundary cell region 105 is set as in Condition 2 of FIG. 23, so that the defect density of the defect regions 15 in the boundary cell region 105 is higher than that of the defect regions 15 in the standard cell region 106.

The configuration of the semiconductor device 200f or the semiconductor device 201f according to the present preferred embodiment is similar to that of the semiconductor device 200d or the semiconductor device 201d according to the fourth preferred embodiment except the arrangement of the p⁺ type contact layers 6 and the defect regions 15 as seen in plan view and the condition of the defect density of the defect regions 15 as described above.

<F-2. Manufacturing Method>

A method of manufacturing the semiconductor device 200f or the semiconductor device 201f is similar to the method of manufacturing the semiconductor device 200d or the semiconductor device 201d. The arrangement of the p⁺ type contact layers 6 and the defect regions 15 according to the present preferred embodiment is achieved by changing the patterning position in the photolithographic step of the mask process.

<F-3. Operation>

The boundary cell region 105 is set to be higher in the area ratio of the defect regions 15 and lower in diode recovery losses than the standard cell region 106 adjacent thereto.

Further, the boundary cell region 105 and its neighboring IGBT region 101 have a smaller number of excess carriers near the p type anode layers 5 in the on state of the diode than the standard cell region 106. This accordingly suppresses the recovery current flowing in the path of the parasitic diode provided across the IGBT region 101 and the diode region 102. Although the excess carriers are not necessarily injected by the parasitic diode, the losses resulting from the recovery current flowing in the path of the parasitic diode are simply referred to as the recovery losses of the parasitic diode. The parasitic diode is long in path and high in losses. Thus, the recovery losses of the entire device are effectively suppressed by suppressing the recovery losses of the parasitic diode.

In the present preferred embodiment, the boundary cell region 105 is formed by a single unit cell. However, the boundary cell region 105 may be formed by a plurality of unit cells on the side close to the IGBT region 101, so that the area ratio of the defect regions 15 in the boundary cell region 105 is increased. In this case, the recovery current flowing in the path of the parasitic diode is more effectively suppressed, so that the recovery losses are more effectively suppressed.

### G. Seventh Preferred Embodiment

<G-1. Configuration>

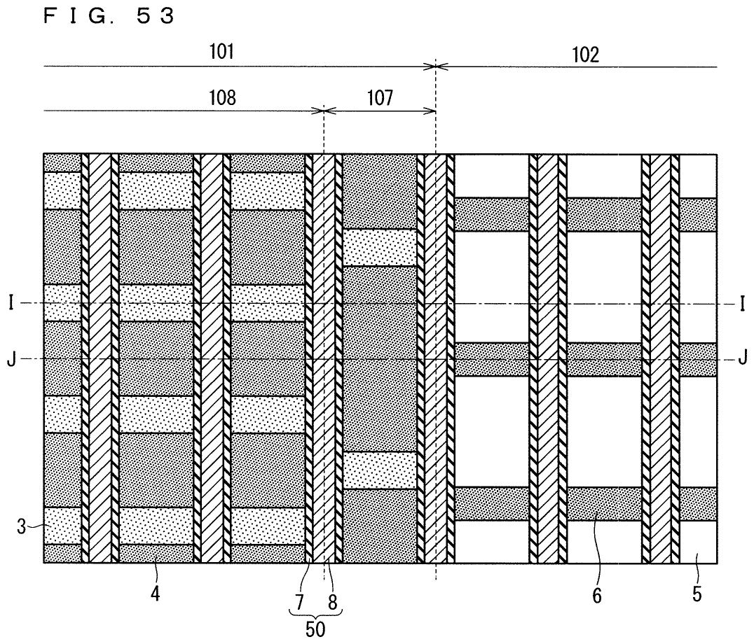

A plan view of a semiconductor device 200g that is a stripe type RC-IGBT according to a seventh preferred embodiment is shown in FIG. 1. A plan view of a semiconductor device 201g that is an island type RC-IGBT according to the seventh preferred embodiment is shown in FIG. 2. An enlarged plan view showing a region enclosed by the broken lines 82 in the semiconductor device 200g of FIG. 1 or the semiconductor device 201g of FIG. 2 on an enlarged scale is shown in FIG. 53.

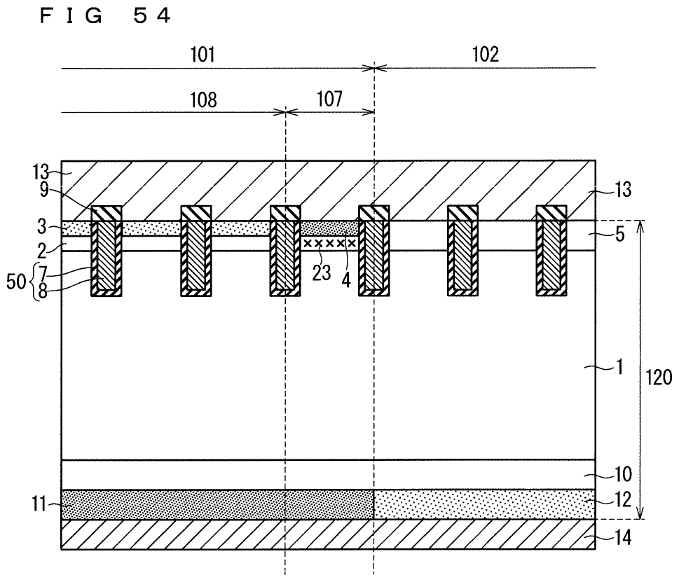

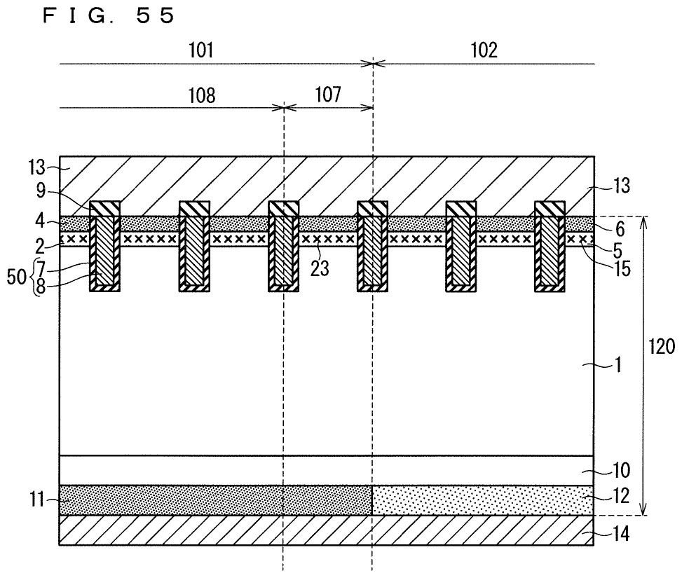

FIG. 54 is a sectional view of the semiconductor device 200g or the semiconductor device 201g taken along a line I-I shown in FIG. 53. FIG. 55 is a sectional view of the semiconductor device 200g or the semiconductor device 201g taken along a line J-J shown in FIG. 53.

With reference to FIGS. 53, 54, and 55, a boundary cell region 107 is a region of one of the unit cells in the IGBT region 101 which is at a boundary with the diode region 102. A standard cell region 108 is a region of the IGBT region 101 which is other than the boundary cell region 107.

In the present preferred embodiment, the defect regions 23 are formed in the same region as the p⁺ type contact layers 4 as seen in plan view so as to extend from the p⁺ type contact layers 4 to the p type channel dope layers 2. Also, the defect regions 15 are formed in the same region as the p⁺ type contact layers 6 as seen in plan view so as to extend from the p⁺ type contact layers 6 to the p type anode layers 5.

In the IGBT region 101 of the semiconductor device 200g or the semiconductor device 201g, the n⁺ type emitter layers 3 and the p⁺ type contact layers 4 at the first main surface are disposed alternately in the direction of extension of the trench gates 50, as shown in FIG. 53. The n⁺ type emitter layers 3 and the p⁺ type contact layers 4 in the present preferred embodiment may be disposed in the same manner as in the first to sixth preferred embodiments. Specifically, the n⁺ type emitter layers 3 and the p⁺ type contact layers 4 may extend in the direction of extension of the trench gates 50. In addition, the n⁺ type emitter layers 3 may be provided in contact with the gate insulation films 7 of the trench gates 50, and the p⁺ type contact layers 4 may be provided in spaced apart relation to the gate insulation films 7 of the trench gates 50. Alternatively, the n⁺ type emitter layers 3 and the p⁺ type contact layers 4 in the first to sixth preferred embodiments may be disposed alternately in the direction of extension of the trench gates 50, as in the present preferred embodiment.

In the semiconductor device 200g or the semiconductor device 201g according to the present preferred embodiment, the area ratio of the p⁺ type contact layers 4 in the boundary cell region 107 is higher than that of the p⁺ type contact layers 4 in the standard cell region 108, as shown in FIG. 53. Also, the area ratio of the defect regions 23 in the boundary cell region 107 is higher than that of the defect regions 23 in the standard cell region 108.

The area ratio of the p⁺ type contact layers 4 in a certain region of the IGBT region is the ratio of the area of the p⁺ type contact layers 4 in the certain region as seen in plan view to the area of a combination of the n⁺ type emitter layers 3 and the p⁺ type contact layers 4 in the certain region as seen in plan view.

The area ratio of the defect regions 23 in a certain region of the IGBT region is the ratio of the area of the defect regions 23 in the certain region as seen in plan view to the area of a combination of the n⁺ type emitter layers 3 and the p⁺ type contact layers 4 in the certain region as seen in plan view.

<G-2. Manufacturing Method>

The semiconductor device 200g or the semiconductor device 201g is manufactured in the same manner as the semiconductor device 200f or the semiconductor device 201f of the sixth preferred embodiment. The difference from the sixth preferred embodiment is achieved by changing the patterning position in the photolithographic step of the mask process, and will not be described in detail.

<G-3. Operation>

A parasitic diode formed within the boundary cell region 107 is close to the n⁺ type cathode layer 12 and hence has a stronger influence upon the deterioration of the recovery losses in the entire device than a parasitic diode formed within the standard cell region 108.

In the present preferred embodiment, the boundary cell region 107 having a stronger influence upon the deterioration of the recovery losses is set to be higher in the area ratio of the defect regions 23 than the standard cell region 108, so that the recovery losses are easily suppressed in the boundary cell region 107. This effectively suppresses the recovery losses resulting from the parasitic diode and, as a result, effectively reduces the recovery losses in the entire device.

In the present preferred embodiment, the boundary cell region 107 is formed by a single unit cell. However, the boundary cell region 107 may be formed by a plurality of unit cells on the side close to the diode region 102, so that the area ratio of the defect regions 23 in the boundary cell region 107 is increased. In this case, the recovery losses resulting from the parasitic diode are more effectively reduced.

### H. Eighth Preferred Embodiment

<H-1. Configuration>

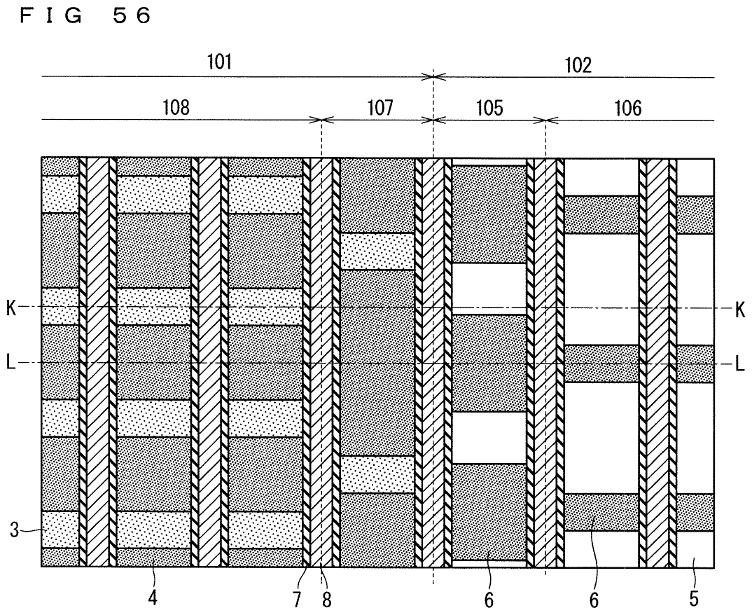

A plan view of a semiconductor device 200h that is a stripe type RC-IGBT according to an eighth preferred embodiment is shown in FIG. 1. A plan view of a semiconductor device 201h that is an island type RC-IGBT according to the eighth preferred embodiment is shown in FIG. 2. An enlarged plan view showing a region enclosed by the broken lines 82 in the semiconductor device 200h of FIG. 1 or the semiconductor device 201h of FIG. 2 on an enlarged scale is shown in FIG. 56.

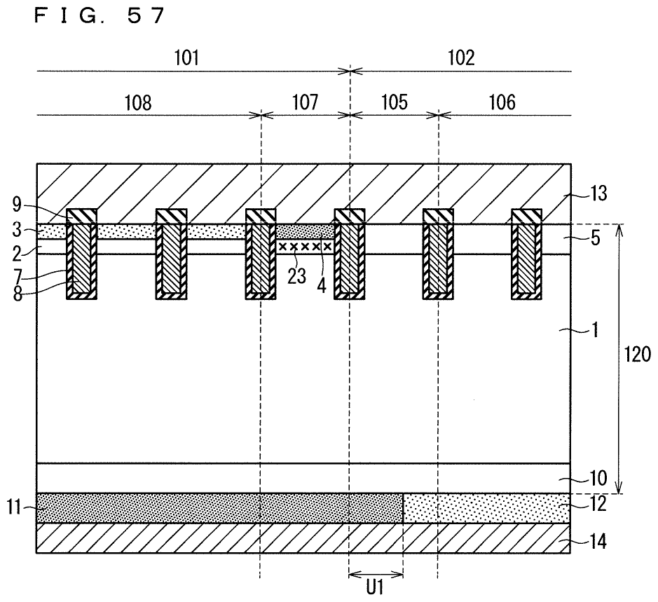

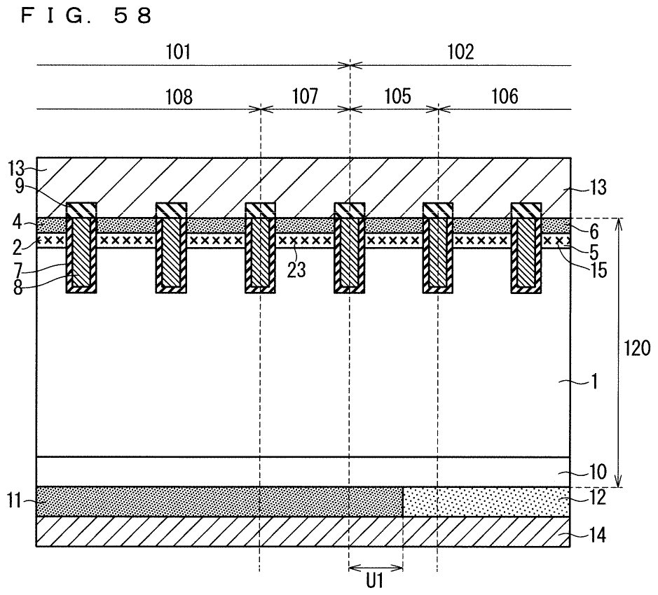

FIG. 57 is a sectional view of the semiconductor device 200h or the semiconductor device 201h taken along a line K-K shown in FIG. 56. FIG. 58 is a sectional view of the semiconductor device 200h or the semiconductor device 201h taken along a line L-L shown in FIG. 56.

One feature of the present preferred embodiment is a combination of the features of the sixth and seventh preferred embodiments, in which the area ratio of the defect regions 15 in the boundary cell region 105 is higher than that of the defect regions 15 in the standard cell region 106 and in which the area ratio of the defect regions 23 in the boundary cell region 107 is higher than that of the defect regions 23 in the standard cell region 108.

Another feature of the present preferred embodiment is that the boundary between the p type collector layer 11 and the n⁺ type cathode layer 12 is disposed at a distance U1 from the boundary between the IGBT region 101 and the diode region 102 toward the diode region 102. The provision of the p type collector layer 11 protruding toward the diode region 102 in this manner increases the distance between the n⁺ type cathode layer 12 in the diode region 102 and the trench gates 50 in the IGBT region 101. This suppresses the flow of current from a channel formed adjacent to the trench gates 50 in the IGBT region 101 to the n⁺ type cathode layer 12 even if the gate drive voltage is applied to the buried gate electrodes 8 in the IGBT region 101 when the diode turns on. The distance U1 may be, for example, 100 μm. The distance U1 may be zero or less than 100 μm, depending on application purposes of the semiconductor device 200h or the semiconductor device 201h that is an RC-IGBT. In other preferred embodiments, the distance U1 may be also set depending on application purposes.

<H-2. Manufacturing Method>

The semiconductor device 200h or the semiconductor device 201h is manufactured in the same manner as the semiconductor device 200f or the semiconductor device 201f of the sixth preferred embodiment or as the semiconductor device 200g or the semiconductor device 201g of the seventh preferred embodiment. The difference from the sixth or seventh preferred embodiment is achieved by changing the patterning position in the photolithographic step during the formation of the front and back surfaces, and will not be described in detail.

<H-3. Operation>

In the present preferred embodiment, the area ratio of the defect regions 15 in the boundary cell region 105 is higher than that of the defect regions 15 in the standard cell region 106, and the area ratio of the defect regions 23 in the boundary cell region 107 is higher than that of the defect regions 23 in the standard cell region 108. Thus, the excess carrier density of the entire boundary cell regions 105 and 107 is significantly reduced during the diode operation of the device. This accordingly reduces the recovery losses of the parasitic diode formed across the IGBT region 101 and the diode region 102, especially across the boundary cell region 105 and the diode region 102, to thereby reduce the recovery losses of the entire device.

Further, the boundary between the p type collector layer 11 and the n⁺ type cathode layer 12 is disposed at some distance from the boundary between the IGBT region 101 and the diode region 102 toward the diode region 102. For this reason, the distance between the anode region (the p type channel dope layers 2) of the parasitic diode in the IGBT region 101 and the type cathode layer 12 is increased. This produces the same effect as a practical increase in the thickness of the n⁻ type drift layer 1 to reduce the excess carrier concentration near the region of the parasitic diode across the IGBT region 101 and the diode region 102. Therefore, the recovery losses of the parasitic diode are further reduced.

### I. Ninth Preferred Embodiment

A plan view of a semiconductor device 200i that is a stripe type RC-IGBT according to a ninth preferred embodiment is shown in FIG. 1. A plan view of a semiconductor device 201i that is an island type RC-IGBT according to the ninth preferred embodiment is shown in FIG. 2. An enlarged plan view showing a region enclosed by the broken lines 82 in the semiconductor device 200i of FIG. 1 or the semiconductor device 201i of FIG. 2 on an enlarged scale is shown in FIG. 3.

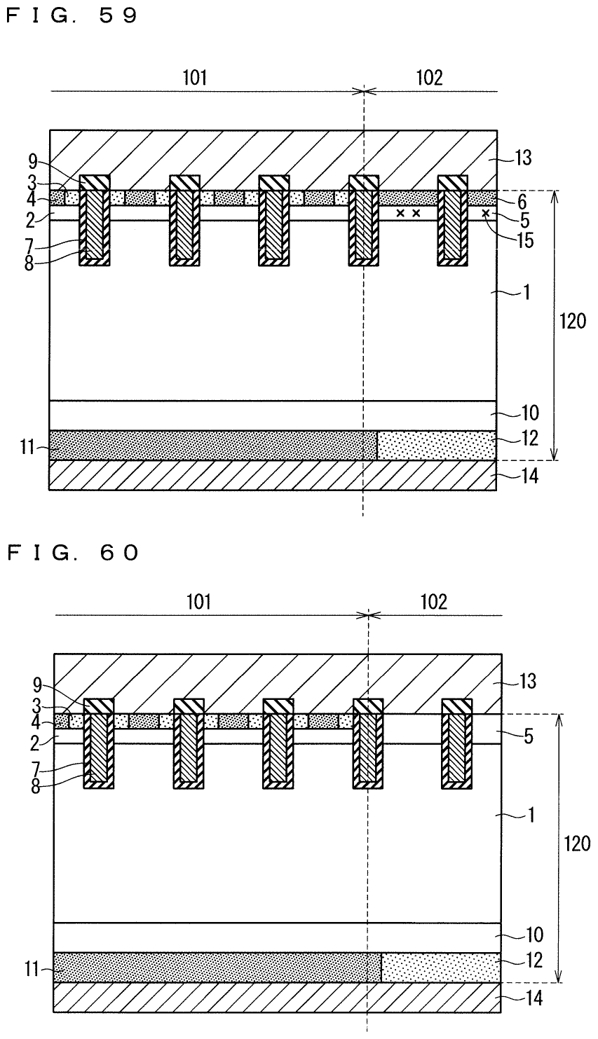

FIG. 59 is a sectional view of the semiconductor device 200i or the semiconductor device 201i taken along the line A-A of FIG. 3. FIG. 60 is a sectional view of the semiconductor device 200i or the semiconductor device 201i taken along the line B-B of FIG. 3.

The semiconductor device 200i or the semiconductor device 201i is similar to the semiconductor device 200 or the semiconductor device 201 of the first preferred embodiment in that the defect regions 15 are provided in the regions of the p type anode layers 5 which are at the second main surface side of the p⁺ type contact layers 6 and which overlap the p⁺ type contact layers 6 as seen in plan view. On the other hand, the regions where the defect regions 15 are provided in the semiconductor device 200i or the semiconductor device 201i are not the whole but part of the regions overlapping the p⁺ type contact layers 6 as seen in plan view. Also, the defect regions 15 are formed only in the regions overlapping the p⁺ type contact layers 6 as seen in plan view. Other parts of the semiconductor device 200i or the semiconductor device 201i are similar to those of the semiconductor device 200 or the semiconductor device 201.

In the semiconductor device 200i or the semiconductor device 201i, holes recombine in the defect regions 15. Thus, the number of holes flowing into the n⁻ type drift layer 1 becomes smaller in the on state during the diode operation, as compared with that in the absence of the defect regions 15, whereby the recovery losses are reduced.

### J. Tenth Preferred Embodiment

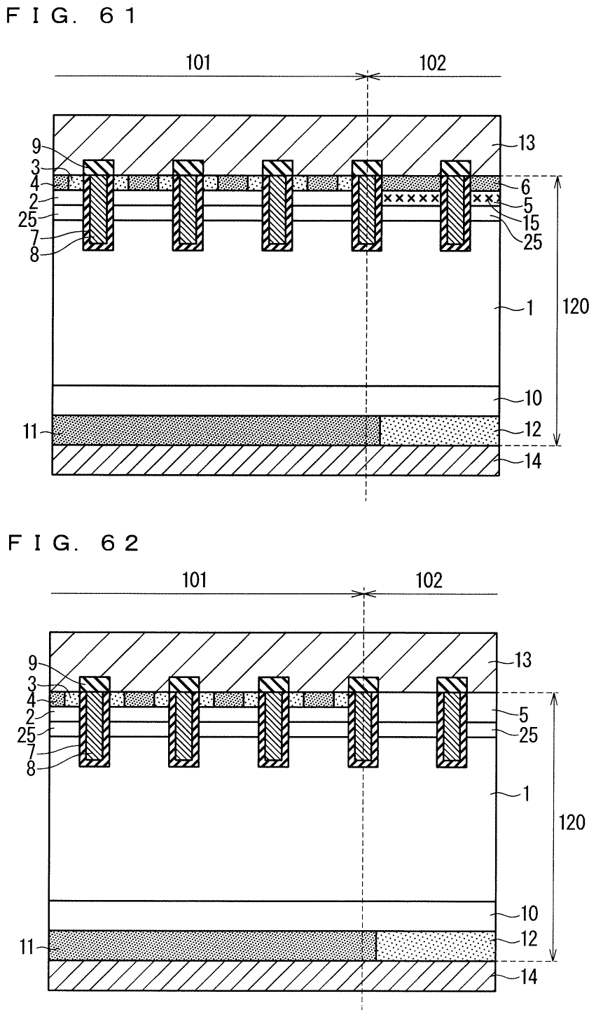

A plan view of a semiconductor device 200j that is a stripe type RC-IGBT according to a tenth preferred embodiment is shown in FIG. 1. A plan view of a semiconductor device 201j that is an island type RC-IGBT according to the tenth preferred embodiment is shown in FIG. 2. An enlarged plan view showing a region enclosed by the broken lines 82 in the semiconductor device 200j of FIG. 1 or the semiconductor device 201j of FIG. 2 on an enlarged scale is shown in FIG. 3, FIG. 61 is a sectional view of the semiconductor device 200j or the semiconductor device 201j taken along the line A-A of FIG. 3. FIG. 62 is a sectional view of the semiconductor device 200j or the semiconductor device 201j taken along the line B-B of FIG. 3.

The present preferred embodiment is provided by combining the configuration of the first preferred embodiment with a device known as a CSTBT® (Carrier Stored Trench-Gate Bipolar Transistor).

In the CSTBT, n type carrier storage layers 25 are formed on the second main surface side of the p type channel dope layers 2 and between the p type channel dope layers 2 and the n⁻ type drift layer 1. The CSTBT is a device structured to have the n type carrier storage layers 25, thereby lowering steady-state losses in the on state of the IGBT.

The semiconductor device 200j or the semiconductor device 201j has the same structure as the semiconductor device 200 or the semiconductor device 201 of the first preferred embodiment except including the n type carrier storage layers 25.

In the present preferred embodiment, the defect regions 15 are provided at least in the regions of the p type anode layers 5 which are at the second main surface side of the p⁺ type contact layers 6 and which overlap the p⁺ type contact layers 6 as seen in plan view. Thus, the recovery characteristics of the diode are improved as in the first preferred embodiment. This achieves the reduction in recovery losses without an increase in ohmic resistance to improve the trade-off relationship between the recovery losses and the forward voltage drop.

### K. Eleventh Preferred Embodiment

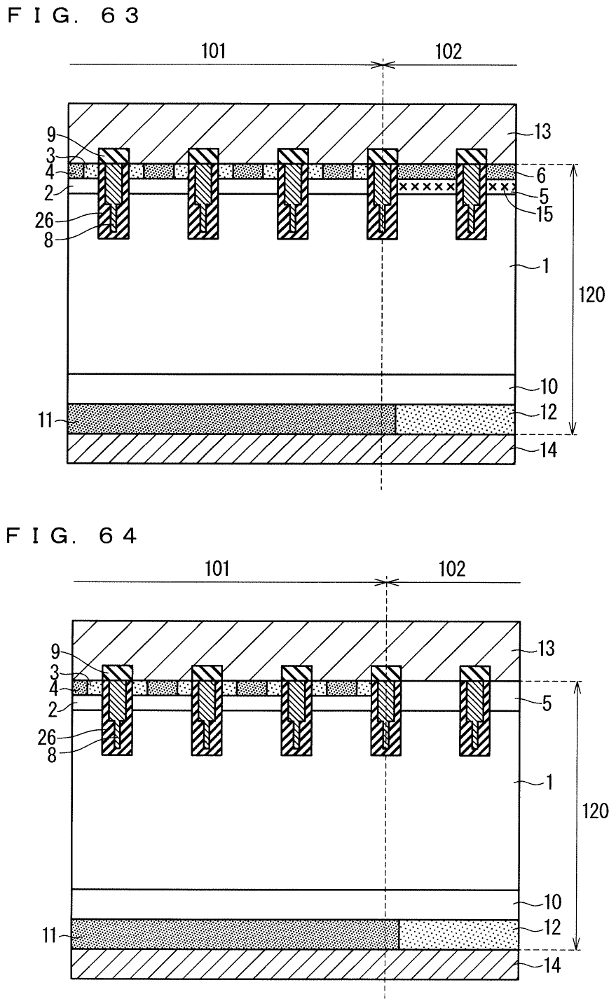

A plan view of a semiconductor device 200k that is a stripe type RC-IGBT according to an eleventh preferred embodiment is shown in FIG. 1. A plan view of a semiconductor device 201k that is an island type RC-IGBT according to the eleventh preferred embodiment is shown in FIG. 2. An enlarged plan view showing a region enclosed by the broken lines 82 in the semiconductor device 200k of FIG. 1 or the semiconductor device 201k of FIG. 2 on an enlarged scale is shown in FIG. 3. FIG. 63 is a sectional view of the semiconductor device 200k or the semiconductor device 201k taken along the line A-A of FIG. 3. FIG. 64 is a sectional view of the semiconductor device 200k or the semiconductor device 201k taken along the line B-B of FIG. 3.

As shown in FIGS. 63 and 64, the gate insulation films 7 in the first preferred embodiment are replaced with thick film gate insulation films 26 in the present preferred embodiment. Also, the shape of the buried gate electrodes 8 is correspondingly changed. The thick film gate insulation films 26 have portions on the second main surface side thicker than portions on the first main surface side. The thicker portions on the second main surface side allow a reduction in gate capacitance to achieve a high-speed operation. The combination of the effect of such thick film gate insulation films 26 and the effect of the defect regions 15 reducing the excess carriers during the diode operation to reduce the recovery losses allows even higher speeds.

### L. Twelfth Preferred Embodiment

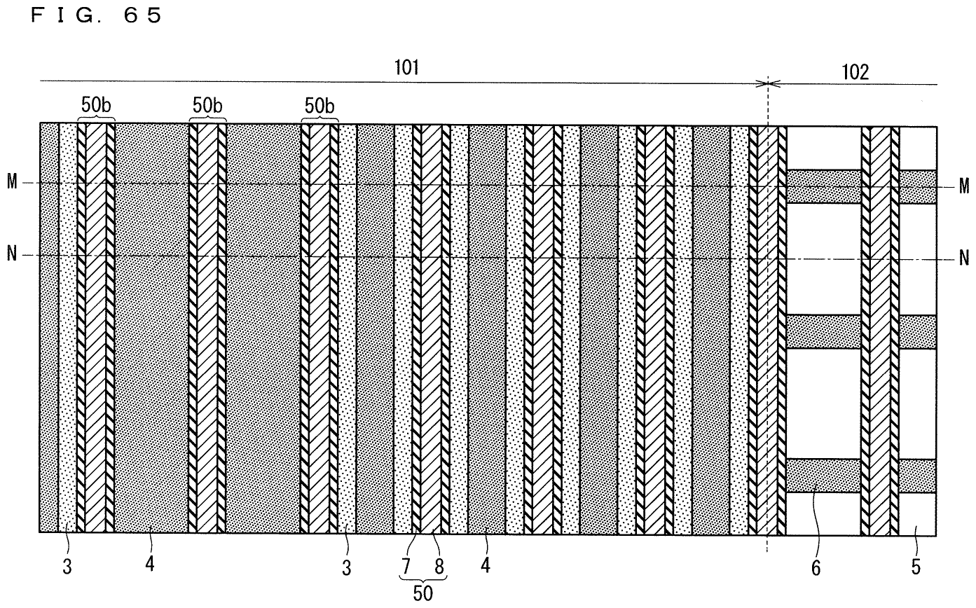

A plan view of a semiconductor device 200l that is a stripe type RC-IGBT according to a twelfth preferred embodiment is shown in FIG. 1. A plan view of a semiconductor device 201l that is an island type RC-IGBT according to the twelfth preferred embodiment is shown in FIG. 2. An enlarged plan view showing a region enclosed by the broken lines 82 in the semiconductor device 200l of FIG. 1 or the semiconductor device 201l of FIG. 2 on an enlarged scale is shown in FIG. 65.

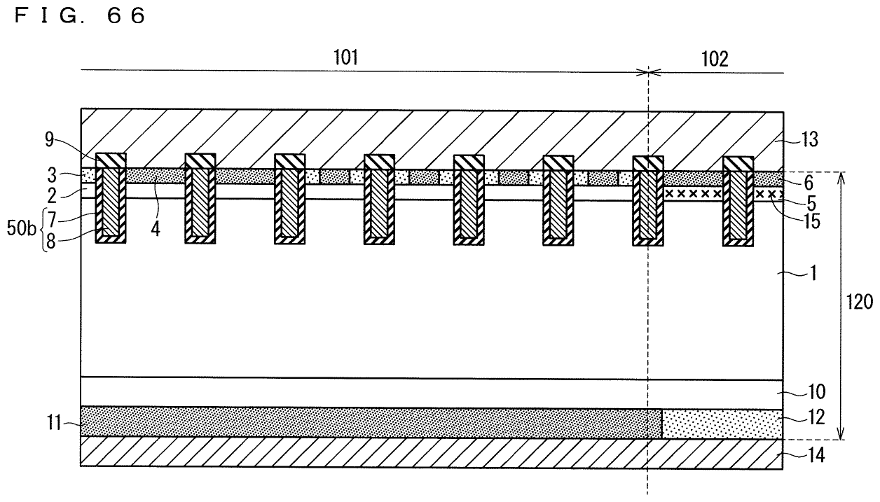

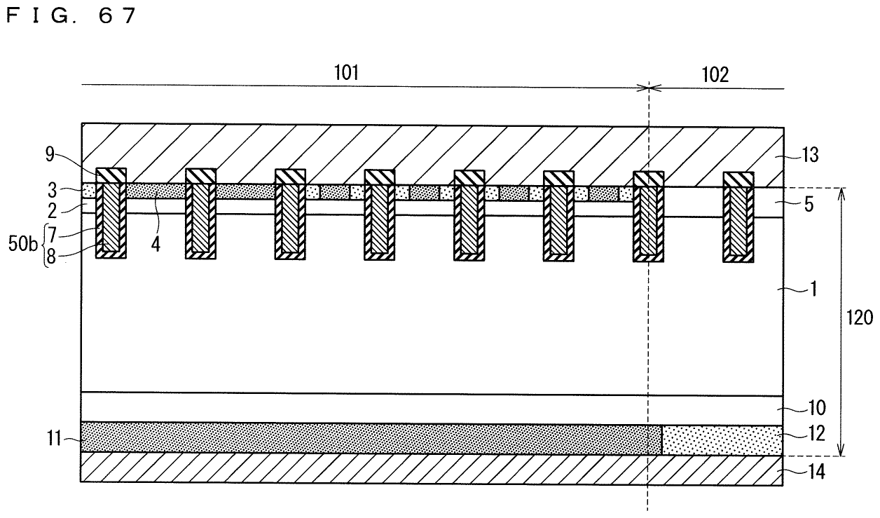

FIG. 66 is a sectional view of the semiconductor device 200l or the semiconductor device 201l taken along a line M-M shown in FIG. 65. FIG. 67 is a sectional view of the semiconductor device 200l or the semiconductor device 201l taken along a line N-N shown in FIG. 65.

In the present preferred embodiment, dummy trench gates 50b are provided in the IGBT region 101. Although the interlayer insulation films 9 are provided on the dummy trench gates 50b in the cross sections shown in FIGS. 66 and 67, the dummy trench gates 50b are electrically connected to the emitter electrode 13 in another cross section. The interlayer insulation films 9 need not be provided on the dummy trench gates 50b. As shown in FIGS. 65, 66, and 67, the p⁺ type contact layers 4 are provided on the first main surface side in regions sandwiched between the dummy trench gates 50b. The structure of the diode region 102 in the present preferred embodiment is similar to that of the diode region 102 in the first preferred embodiment. In the present preferred embodiment, the trade-off relationship between the recovery losses and the forward voltage drop during the diode operation is also improved by the defect regions 15.

### M. Thirteenth Preferred Embodiment

A plan view of a semiconductor device 200m that is a stripe type RC-IGBT according to a thirteenth preferred embodiment is shown in FIG. 1. A plan view of a semiconductor device 201m that is an island type RC-IGBT according to the thirteenth preferred embodiment is shown in FIG. 2. An enlarged plan view showing a region enclosed by the broken lines 82 in the semiconductor device 200m of FIG. 1 or the semiconductor device 201m of FIG. 2 on an enlarged scale is shown in FIG. 3.

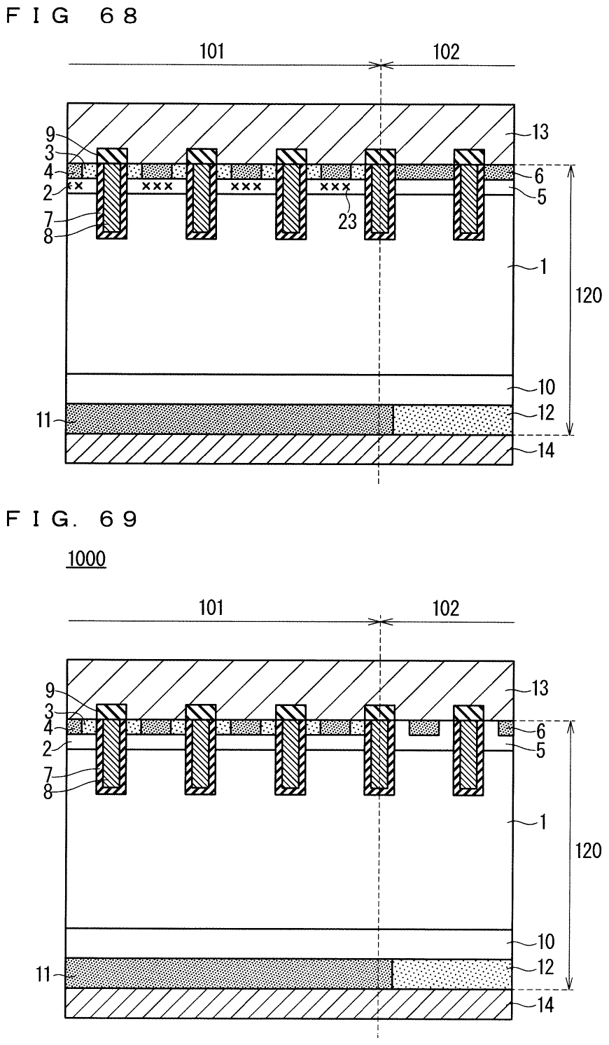

FIG. 68 is a sectional view of the semiconductor device 200m or the semiconductor device 201m taken along the line A-A of FIG. 3. A sectional view of the semiconductor device 200m or the semiconductor device 201m taken along the line B-B of FIG. 3 is shown in FIG. 5.

The present preferred embodiment differs from the fourth preferred embodiment in that the defect regions 15 are not formed in the diode region 102. Other parts of the present preferred embodiment are similar to those of the fourth preferred embodiment. In the present preferred embodiment, the defect regions 23 shown in FIG. 68 also reduce the recovery losses of the parasitic diode to reduce the recovery losses of the entire semiconductor device 200m or the entire semiconductor device 201m during the diode operation in a comprehensive manner, thereby improving the trade-off relationship between the recovery losses and the forward voltage drop during the diode operation, as described in the fourth preferred embodiment. To suppress the recovery losses resulting from the parasitic diode more efficiently, it is desirable that the defect regions 23 are formed so as to include regions in contact with the diode region 102. For example, it is desirable that the defect regions 23 are formed in regions where the distance from the diode region 102 as seen in plan view is less than the thickness of the semiconductor base body.

### N. Fourteenth Preferred Embodiment

If the defect regions 15, the defect regions 21, or both of the defect regions 15 and 21 are recombination regions (a first recombination region) in which holes have a high degree of recombination in the first, and third to twelfth preferred embodiments, effects similar to those described in each of the preferred embodiments are produced. Also, the n type semiconductor layers 19 in the second preferred embodiment may be regarded as the recombination regions. The second preferred embodiment may be combined with any one of the sixth to ninth preferred embodiments, so that the defect regions 15 in any one of the sixth to ninth preferred embodiments are replaced with the n type semiconductor layers 19.

If the defect regions 23 are recombination regions (a second recombination region) in which holes have a high degree of recombination in the fourth to eighth, and thirteenth preferred embodiments, effects similar to those described in each of the preferred embodiments are produced. In place of the defect regions 23, n type semiconductor layers 28 (an eleventh semiconductor layer) may be provided between the p type channel dope layers 2 and the second main surface side of the p⁺ type contact layers 4. Regions where the n type semiconductor layers 28 are to be provided are, for example, partial regions of the p⁺ type contact layers 4 as seen in plan view. The n type semiconductor layers 28 are provided in partial regions at the boundary between the p type channel dope layers 2 and the p⁺ type contact layers 4. This also reduces the number of holes flowing from the p⁺ type contact layers 4 into the n⁻ type drift layer 1 to reduce the recovery losses of the parasitic diode, thereby reducing the entire semiconductor device during the diode operation.

Although the RC-IGBTs are described in the aforementioned preferred embodiments, the preferred embodiments may be combined with MOSFETs and the like.

Although the manufacturing method using a Si substrate is described as an example of the manufacturing methods, a semiconductor substrate made of a different material such as SiC may be used.

The stripe-shaped cell structure in which the trench gates 50 extend in one direction is illustrated as the cell structure near the emitter electrode 13 in the IGBT region 101. However, a combination may be made with a cell structure known as a mesh type in which trench gates extend in vertical and horizontal directions or with a cell structure other than the trench type (a structure known as a planar type).

The preferred embodiments may be freely combined or the preferred embodiments may be changed and dispensed with, as appropriate.

While the disclosure has been shown and described in detail, the foregoing description is in all aspects illustrative and not restrictive. It is therefore understood that numerous modifications and variations can be devised.

What is claimed is:

1. A semiconductor device comprising a transistor and a diode both formed in a common semiconductor base body,
the semiconductor base body including
a first main surface and a second main surface as one main surface and the other main surface, respectively,
a transistor region in which the transistor is formed, and
a diode region in which the diode is formed,
the transistor region including
a first semiconductor layer of a first conductivity type formed on the second main surface side of the semiconductor base body,
a second semiconductor layer of a second conductivity type provided on the first semiconductor layer,
a third semiconductor layer of the first conductivity type provided closer to the first main surface of the semiconductor base body than the second semiconductor layer,
a fourth semiconductor layer of the second conductivity type provided on the third semiconductor layer,
a second electrode electrically connected to the fourth semiconductor layer, and
a first electrode electrically connected to the first semiconductor layer,
the diode region including
a fifth semiconductor layer of the second conductivity type provided on the second main surface side of the semiconductor base body,
the second semiconductor layer provided on the fifth semiconductor layer,
a sixth semiconductor layer of the first conductivity type provided closer to the first main surface of the semiconductor base body than the second semiconductor layer,
a seventh semiconductor layer of the first conductivity type provided on the sixth semiconductor layer and having a first conductivity type impurity concentration higher than that of the sixth semiconductor layer,
the second electrode electrically connected to the seventh semiconductor layer, and
the first electrode electrically connected to the fifth semiconductor layer,
wherein a first recombination region is provided at least in a region of the sixth semiconductor layer which is at the second main surface side of the seventh semiconductor layer and which overlaps the seventh semiconductor layer as seen in plan view.

2. The semiconductor device according to claim 1,
wherein the first recombination region is provided at least in a region of the sixth semiconductor layer which is in contact with a surface of the seventh semiconductor layer on the second main surface side.

3. The semiconductor device according to claim 1,
wherein the first recombination region is provided so as to extend from the sixth semiconductor layer to the seventh semiconductor layer, including a surface of the seventh semiconductor layer on the second main surface side which is in contact with the sixth semiconductor layer.

4. The semiconductor device according to claim 1,
wherein the first recombination region is formed at least in a region of the diode region where a distance from the transistor region as seen in plan view is less than the thickness of the semiconductor base body.

5. The semiconductor device according to claim 1,
wherein the first recombination region is formed only in a region overlapping the seventh semiconductor layer as seen in plan view.

6. The semiconductor device according to claim 1,
wherein the first recombination region and the seventh semiconductor layer are formed in the same region as seen in plan view.

7. The semiconductor device according to claim 1,
wherein the area of the first recombination region as seen in plan view is not less than 20% of the area of a combination of the sixth semiconductor layer and the seventh semiconductor layer as seen in plan view.

8. The semiconductor device according to claim 1,
wherein the first recombination region is not formed in a region of the sixth semiconductor layer which has a first conductivity type impurity concentration of not more than 1.0E+16/cm³.

9. The semiconductor device according to claim 1,
wherein the diode region is divided into a plurality of unit cell regions by a trench gate extending from a surface of the semiconductor base body on the first main surface side to the second semiconductor layer, and
wherein the ratio of the area of the first recombination region as seen in plan view to the area of a combination of the sixth semiconductor layer and the seventh semiconductor layer as seen in plan view in the unit cell region which is adjacent to the transistor region in the diode region is higher than the ratio of the area of the first recombination region as seen in plan view to the area of a combination of the sixth semiconductor layer and the seventh semiconductor layer as seen in plan view in the unit cell region which is not adjacent to the transistor region in the diode region.

10. A semiconductor device comprising a transistor and a diode both formed in a common semiconductor base body,
the semiconductor base body including
a first main surface and a second main surface as one main surface and the other main surface, respectively,
a transistor region in which the transistor is formed, and
a diode region in which the diode is formed,
the transistor region including
a first semiconductor layer of a first conductivity type formed on the second main surface side of the semiconductor base body,
a second semiconductor layer of a second conductivity type provided on the first semiconductor layer,
a third semiconductor layer of the first conductivity type provided closer to the first main surface of the semiconductor base body than the second semiconductor layer,
a fourth semiconductor layer of the second conductivity type provided on the third semiconductor layer,
a second electrode electrically connected to the fourth semiconductor layer, and
a first electrode electrically connected to the first semiconductor layer,
the diode region including
a fifth semiconductor layer of the second conductivity type provided on the second main surface side of the semiconductor base body,
the second semiconductor layer provided on the fifth semiconductor layer,
a sixth semiconductor layer of the first conductivity type provided closer to the first main surface of the semiconductor base body than the second semiconductor layer,
a seventh semiconductor layer of the first conductivity type provided on the sixth semiconductor layer and having a first conductivity type impurity concentration higher than that of the sixth semiconductor layer,
the second electrode electrically connected to the seventh semiconductor layer, and
the first electrode electrically connected to the fifth semiconductor layer,
wherein a first crystal defect region is provided at least in a region of the sixth semiconductor layer which is at the second main surface side of the seventh semiconductor layer and which overlaps the seventh semiconductor layer as seen in plan view.

11. The semiconductor device according to claim 10,
wherein the first crystal defect region is provided at least in a region of the sixth semiconductor layer which is in contact with a surface of the seventh semiconductor layer on the second main surface side.

12. The semiconductor device according to claim 10,
wherein the first crystal defect region is provided so as to extend from the sixth semiconductor layer to the seventh semiconductor layer, including a surface of the seventh semiconductor layer on the second main surface side which is in contact with the sixth semiconductor layer.

13. The semiconductor device according to claim 10,
wherein the first crystal defect region contains Ar (argon).

14. The semiconductor device according to claim 10,
wherein the first crystal defect region contains N (nitrogen).

15. The semiconductor device according to claim 10,
wherein the first crystal defect region contains He (helium).

16. The semiconductor device according to claim 10,
wherein the first crystal defect region contains H (hydrogen).

17. The semiconductor device according to claim 10,
wherein the first crystal defect region is formed at least in a region of the diode region where a distance from the transistor region as seen in plan view is less than the thickness of the semiconductor base body.

18. The semiconductor device according to claim 10,
wherein the first crystal defect region is formed only in a region overlapping the seventh semiconductor layer as seen in plan view.

19. The semiconductor device according to claim 10,
wherein the first crystal defect region and the seventh semiconductor layer are formed in the same region as seen in plan view.

20. The semiconductor device according to claim 10,
wherein the area of the first crystal defect region as seen in plan view is not less than 20% of the area of a combination of the sixth semiconductor layer and the seventh semiconductor layer as seen in plan view.

21. The semiconductor device according to claim 10,
wherein the first crystal defect region is not formed in a region of the sixth semiconductor layer which has a first conductivity type impurity concentration of not more than 1.0E+16/cm³.

22. The semiconductor device according to claim 10,
wherein the diode region is divided into a plurality of unit cell regions by a trench gate extending from a surface of the semiconductor base body on the first main surface side to the second semiconductor layer, and
wherein the ratio of the area of the first crystal defect region as seen in plan view to the area of a combination of the sixth semiconductor layer and the seventh semiconductor layer as seen in plan view in the unit cell region which is adjacent to the transistor region in the diode region is higher than the ratio of the area of the first crystal defect region as seen in plan view to the area of a combination of the sixth semiconductor layer and the seventh semiconductor layer as seen in plan view in the unit cell region which is not adjacent to the transistor region in the diode region.

23. A semiconductor device comprising a transistor and a diode both formed in a common semiconductor base body,
the semiconductor base body including
a first main surface and a second main surface as one main surface and the other main surface, respectively,
a transistor region in which the transistor is formed, and
a diode region in which the diode is formed,
the transistor region including
a first semiconductor layer of a first conductivity type formed on the second main surface side of the semiconductor base body,
a second semiconductor layer of a second conductivity type provided on the first semiconductor layer,
a third semiconductor layer of the first conductivity type provided closer to the first main surface of the semiconductor base body than the second semiconductor layer,
a fourth semiconductor layer of the second conductivity type provided on the third semiconductor layer,
a second electrode electrically connected to the fourth semiconductor layer, and
a first electrode electrically connected to the first semiconductor layer,
the diode region including
a fifth semiconductor layer of the second conductivity type provided on the second main surface side of the semiconductor base body,
the second semiconductor layer provided on the fifth semiconductor layer,
a sixth semiconductor layer of the first conductivity type provided closer to the first main surface of the semiconductor base body than the second semiconductor layer,
an eighth semiconductor layer of the second conductivity type provided on the sixth semiconductor layer,
a seventh semiconductor layer of the first conductivity type provided on the eighth semiconductor layer and having a first conductivity type impurity concentration higher than that of the sixth semiconductor layer,
the second electrode electrically connected to the seventh semiconductor layer, and
the first electrode electrically connected to the fifth semiconductor layer.

24. The semiconductor device according to claim 23,
wherein the eighth semiconductor layer contains As (arsenic) or P (phosphorus).

25. The semiconductor device according to claim 23,
wherein the eighth semiconductor layer is formed at least in a region of the diode region where a distance from the transistor region as seen in plan view is less than the thickness of the semiconductor base body.

26. The semiconductor device according to claim 23,
wherein the eighth semiconductor layer is formed only in a region overlapping the seventh semiconductor layer as seen in plan view.

27. The semiconductor device according to claim 23,
wherein the eighth semiconductor layer and the seventh semiconductor layer are formed in the same region as seen in plan view.

28. The semiconductor device according to claim 23,
wherein the area of the eighth semiconductor layer as seen in plan view is not less than 20% of the area of a combination of the sixth semiconductor layer and the seventh semiconductor layer as seen in plan view.

29. The semiconductor device according to claim 23,
wherein the eighth semiconductor layer is not formed in a region of the sixth semiconductor layer which has a first conductivity type impurity concentration of not more than 1.0E+16/cm³.

30. The semiconductor device according to claim 23,
wherein the diode region is divided into a plurality of unit cell regions by a trench gate extending from a surface of the semiconductor base body on the first main surface side to the second semiconductor layer, and
wherein the ratio of the area of the eighth semiconductor layer as seen in plan view to the area of a combination of the sixth semiconductor layer and the seventh semiconductor layer as seen in plan view in the unit cell region which is adjacent to the transistor region in the diode region is higher than the ratio of the area of the eighth semiconductor layer as seen in plan view to the area of a combination of the sixth semiconductor layer and the seventh semiconductor layer as seen in plan view in the unit cell region which is not adjacent to the transistor region in the diode region.

31. A semiconductor device comprising a transistor and a diode both formed in a common semiconductor base body,
the semiconductor base body including
a first main surface and a second main surface as one main surface and the other main surface, respectively,
a transistor region in which the transistor is formed, and
a diode region in which the diode is formed,
the transistor region including
a first semiconductor layer of a first conductivity type formed on the second main surface side of the semiconductor base body,
a second semiconductor layer of a second conductivity type provided on the first semiconductor layer,
a third semiconductor layer of the first conductivity type provided closer to the first main surface of the semiconductor base body than the second semiconductor layer,
a fourth semiconductor layer of the second conductivity type provided on the third semiconductor layer,
a ninth semiconductor layer of the first conductivity type provided on the third semiconductor layer and having a first conductivity type impurity concentration higher than that of the third semiconductor layer,
a second electrode electrically connected to the fourth semiconductor layer and the ninth semiconductor layer, and
a first electrode electrically connected to the first semiconductor layer,
the diode region including
a fifth semiconductor layer of the second conductivity type provided on the second main surface side of the semiconductor base body,
the second semiconductor layer provided on the fifth semiconductor layer,
a tenth semiconductor layer provided closer to the first main surface of the semiconductor base body than the second semiconductor layer and containing an impurity of the first conductivity type,
the second electrode electrically connected to the tenth semiconductor layer, and
the first electrode electrically connected to the fifth semiconductor layer,
wherein a second recombination region is provided at least in a region of the third semiconductor layer which is at the second main surface side of the ninth semiconductor layer and which overlaps the ninth semiconductor layer as seen in plan view.

32. The semiconductor device according to claim 31,
wherein the second recombination region is provided at least in a region of the third semiconductor layer which is in contact with a surface of the ninth semiconductor layer on the second main surface side.

33. The semiconductor device according to claim 31,
wherein the second recombination region is provided so as to extend from the third semiconductor layer to the ninth semiconductor layer, including a surface of the ninth semiconductor layer on the second main surface side which is in contact with the third semiconductor layer.

34. The semiconductor device according to claim 31,
wherein the second recombination region is formed at least in a region of the transistor region where a distance from the diode region as seen in plan view is less than the thickness of the semiconductor base body.

35. The semiconductor device according to claim 31,
wherein the second recombination region is formed only in a region overlapping the ninth semiconductor layer as seen in plan view.

36. The semiconductor device according to claim 31,
wherein the transistor region is divided into a plurality of unit cell regions by a trench gate extending from a surface of the semiconductor base body on the first main surface side to the second semiconductor layer, and
wherein the ratio of the area of the second recombination region as seen in plan view to the area of a combination of the third semiconductor layer, the fourth semiconductor layer, and the ninth semiconductor layer as seen in plan view in the unit cell region which is adjacent to the diode region in the transistor region is higher than the ratio of the area of the second recombination region as seen in plan view to the area of a combination of the third semiconductor layer, the fourth semiconductor layer, and the ninth semiconductor layer as seen in plan view in the unit cell region which is not adjacent to the diode region in the transistor region.

37. A semiconductor device comprising a transistor and a diode both formed in a common semiconductor base body,
the semiconductor base body including
a first main surface and a second main surface as one main surface and the other main surface, respectively,
a transistor region in which the transistor is formed, and
a diode region in which the diode is formed,
the transistor region including
a first semiconductor layer of a first conductivity type formed on the second main surface side of the semiconductor base body,
a second semiconductor layer of a second conductivity type provided on the first semiconductor layer,
a third semiconductor layer of the first conductivity type provided closer to the first main surface of the semiconductor base body than the second semiconductor layer,
a fourth semiconductor layer of the second conductivity type provided on the third semiconductor layer,
a ninth semiconductor layer of the first conductivity type provided on the third semiconductor layer and having a first conductivity type impurity concentration higher than that of the third semiconductor layer,
a second electrode electrically connected to the fourth semiconductor layer and the ninth semiconductor layer, and
a first electrode electrically connected to the first semiconductor layer,
the diode region including
a fifth semiconductor layer of the second conductivity type provided on the second main surface side of the semiconductor base body,
the second semiconductor layer provided on the fifth semiconductor layer,
a tenth semiconductor layer provided closer to the first main surface of the semiconductor base body than the second semiconductor layer and containing an impurity of the first conductivity type,
the second electrode electrically connected to the tenth semiconductor layer, and
the first electrode electrically connected to the fifth semiconductor layer,
wherein a second crystal defect region is provided at least in a region of the third semiconductor layer which is at the second main surface side of the ninth semiconductor layer and which overlaps the ninth semiconductor layer as seen in plan view.

38. The semiconductor device according to claim 37,
wherein the second crystal defect region is provided at least in a region of the third semiconductor layer which is in contact with a surface of the ninth semiconductor layer on the second main surface side.

39. The semiconductor device according to claim 37,
wherein the second crystal defect region is provided so as to extend from the third semiconductor layer to the ninth semiconductor layer, including a surface of the ninth semiconductor layer on the second main surface side which is in contact with the third semiconductor layer.

40. The semiconductor device according to claim 37,
wherein the second crystal defect region is formed at least in a region of the transistor region where a distance from the diode region as seen in plan view is less than the thickness of the semiconductor base body.

41. The semiconductor device according to claim 37,
wherein the second crystal defect region is formed only in a region overlapping the ninth semiconductor layer as seen in plan view.

42. The semiconductor device according to claim 37,
wherein the transistor region is divided into a plurality of unit cell regions by a trench gate extending from a surface of the semiconductor base body on the first main surface side to the second semiconductor layer, and
wherein the ratio of the area of the second crystal defect region as seen in plan view to the area of a combination of the third semiconductor layer, the fourth semiconductor layer, and the ninth semiconductor layer as seen in plan view in the unit cell region which is adjacent to the diode region in the transistor region is higher than the ratio of the area of the second crystal defect region as seen in plan view to the area of a combination of the third semiconductor layer, the fourth semiconductor layer, and the ninth semiconductor layer as seen in plan view in the unit cell region which is not adjacent to the diode region in the transistor region.

43. A semiconductor device comprising a transistor and a diode both formed in a common semiconductor base body,
the semiconductor base body including
a first main surface and a second main surface as one main surface and the other main surface, respectively,
a transistor region in which the transistor is formed, and
a diode region in which the diode is formed,
the transistor region including
a first semiconductor layer of a first conductivity type formed on the second main surface side of the semiconductor base body,
a second semiconductor layer of a second conductivity type provided on the first semiconductor layer,
a third semiconductor layer of the first conductivity type provided closer to the first main surface of the semiconductor base body than the second semiconductor layer,
a fourth semiconductor layer of the second conductivity type provided on the third semiconductor layer,
an eleventh semiconductor layer of the second conductivity type provided on the third semiconductor layer,
a ninth semiconductor layer of the first conductivity type provided on the eleventh semiconductor layer and having a first conductivity type impurity concentration higher than that of the third semiconductor layer,
a second electrode electrically connected to the fourth semiconductor layer and the ninth semiconductor layer, and
a first electrode electrically connected to the first semiconductor layer,
the diode region including
a fifth semiconductor layer of the second conductivity type provided on the second main surface side of the semiconductor base body,
the second semiconductor layer provided on the fifth semiconductor layer,
a tenth semiconductor layer provided closer to the first main surface of the semiconductor base body than the second semiconductor layer and containing an impurity of the first conductivity type,
the second electrode electrically connected to the tenth semiconductor layer, and
the first electrode electrically connected to the fifth semiconductor layer.

44. The semiconductor device according to claim 43,
wherein the eleventh semiconductor layer is formed at least in a region of the transistor region where a distance from the diode region as seen in plan view is less than the thickness of the semiconductor base body.

45. The semiconductor device according to claim 43,
wherein the eleventh semiconductor layer is formed only in a region overlapping the ninth semiconductor layer as seen in plan view.

46. The semiconductor device according to claim 43,
wherein the transistor region is divided into a plurality of unit cell regions by a trench gate extending from a surface of the semiconductor base body on the first main surface side to the second semiconductor layer, and
wherein the ratio of the area of the eleventh semiconductor layer as seen in plan view to the area of a combination of the third semiconductor layer, the fourth semiconductor layer, and the ninth semiconductor layer as seen in plan view in the unit cell region which is adjacent to the diode region in the transistor region is higher than the ratio of the area of the eleventh semiconductor layer as seen in plan view to the area of a combination of the third semiconductor layer, the fourth semiconductor layer, and the ninth semiconductor layer as seen in plan view in the unit cell region which is not adjacent to the diode region in the transistor region.

47. The semiconductor device according to claim 1,
wherein the transistor region further includes
a ninth semiconductor layer of the first conductivity type provided on the third semiconductor layer and having a first conductivity type impurity concentration higher than that of the third semiconductor layer,
wherein the second electrode is electrically connected to the ninth semiconductor layer, and
wherein a second recombination region is provided at least in a region of the third semiconductor layer which is at the second main surface side of the ninth semiconductor layer and which overlaps the ninth semiconductor layer as seen in plan view.

48. The semiconductor device according to claim 10,
wherein the transistor region further includes
a ninth semiconductor layer of the first conductivity type provided on the third semiconductor layer and having a first conductivity type impurity concentration higher than that of the third semiconductor layer,
wherein the second electrode is electrically connected to the ninth semiconductor layer, and
wherein a second recombination region is provided at least in a region of the third semiconductor layer which is at the second main surface side of the ninth semiconductor layer and which overlaps the ninth semiconductor layer as seen in plan view.

49. The semiconductor device according to claim 23,
wherein the transistor region further includes
a ninth semiconductor layer of the first conductivity type provided on the third semiconductor layer and having a first conductivity type impurity concentration higher than that of the third semiconductor layer,
wherein the second electrode is electrically connected to the ninth semiconductor layer, and
wherein a second recombination region is provided at least in a region of the third semiconductor layer which is at the second main surface side of the ninth semiconductor layer and which overlaps the ninth semiconductor layer as seen in plan view.

50. The semiconductor device according to claim 1,
wherein the transistor region further includes
a ninth semiconductor layer of the first conductivity type provided on the third semiconductor layer and having a first conductivity type impurity concentration higher than that of the third semiconductor layer,
wherein the second electrode is electrically connected to the ninth semiconductor layer, and
wherein a second crystal defect region is provided at least in a region of the third semiconductor layer which is at the second main surface side of the ninth semiconductor layer and which overlaps the ninth semiconductor layer as seen in plan view.

51. The semiconductor device according to claim 10,
wherein the transistor region further includes
a ninth semiconductor layer of the first conductivity type provided on the third semiconductor layer and having a first conductivity type impurity concentration higher than that of the third semiconductor layer,
wherein the second electrode is electrically connected to the ninth semiconductor layer, and
wherein a second crystal defect region is provided at least in a region of the third semiconductor layer which is at the second main surface side of the ninth semiconductor layer and which overlaps the ninth semiconductor layer as seen in plan view.

52. The semiconductor device according to claim 23,
wherein the transistor region further includes
a ninth semiconductor layer of the first conductivity type provided on the third semiconductor layer and having a first conductivity type impurity concentration higher than that of the third semiconductor layer,
wherein the second electrode is electrically connected to the ninth semiconductor layer, and
wherein a second crystal defect region is provided at least in a region of the third semiconductor layer which is at the second main surface side of the ninth semiconductor layer and which overlaps the ninth semiconductor layer as seen in plan view.

53. The semiconductor device according to claim 1,
wherein the transistor region further includes
an eleventh semiconductor layer of the second conductivity type provided on the third semiconductor layer, and
a ninth semiconductor layer of the first conductivity type provided on the eleventh semiconductor layer and having a first conductivity type impurity concentration higher than that of the third semiconductor layer, and
wherein the second electrode is electrically connected to the ninth semiconductor layer.

54. The semiconductor device according to claim 10,
wherein the transistor region further includes
an eleventh semiconductor layer of the second conductivity type provided on the third semiconductor layer, and
a ninth semiconductor layer of the first conductivity type provided on the eleventh semiconductor layer and having a first conductivity type impurity concentration higher than that of the third semiconductor layer, and
wherein the second electrode is electrically connected to the ninth semiconductor layer.

55. The semiconductor device according to claim 23,
wherein the transistor region further includes an eleventh semiconductor layer of the second conductivity type provided on the third semiconductor layer, and
a ninth semiconductor layer of the first conductivity type provided on the eleventh semiconductor layer and having a first conductivity type impurity concentration higher than that of the third semiconductor layer, and
wherein the second electrode is electrically connected to the ninth semiconductor layer.

56. A method of manufacturing a semiconductor device as recited in claim 1, the method comprising:
forming the first recombination region through a first ion implantation; and
forming the seventh semiconductor layer through a second ion implantation,
wherein the same mask is used in the first and second ion implantation.

57. A method of manufacturing a semiconductor device as recited in claim 10, the method comprising
forming the first crystal defect region through a first ion implantation.

58. The method according to claim 57, further comprising
forming the seventh semiconductor layer through a second ion implantation,
wherein the same mask is used in the first and second ion implantation.

59. The method according to claim 57,
wherein Ar (argon) ions are implanted in the first ion implantation.

60. The method according to claim 57,
wherein N (nitrogen) ions are implanted in the first ion implantation.

61. The method according to claim 57,
wherein He (helium) ions are implanted in the first ion implantation.

62. The method according to claim 57,
wherein H (hydrogen) ions are implanted in the first ion implantation.

63. A method of manufacturing a semiconductor device as recited in claim 23, the method comprising
forming the eighth semiconductor layer through a first ion implantation.

64. The method according to claim 63, further comprising
forming the seventh semiconductor layer through a second ion implantation,
wherein the same mask is used in the first and second ion implantation.

65. The method according to claim 63,
wherein As (arsenic) or P (phosphorus) ions are implanted in the first ion implantation.
